(19) United States
(12) Patent Application Publication
(10) Pub. No.: US 2024/0332081 A1
(43) Pub. Date: Oct. 3, 2024

(54) SEMICONDUCTOR SUBSTRATE AND METHOD FOR MANUFACTURING THE SAME

(71) Applicant: ROHM CO., LTD., Kyoto-shi (JP)

(72) Inventors: Makoto TAKAMURA, Kyoto-shi (JP); Takuji MAEKAWA, Kyoto-shi (JP); Mitsuru MORIMOTO, Kyoto-shi (JP)

(73) Assignee: ROHM CO., LTD., Kyoto-shi (JP)

(21) Appl. No.: 18/621,719

(22) Filed: Mar. 29, 2024

(30) Foreign Application Priority Data
Mar. 30, 2023 (JP) 2023-056394
Mar. 30, 2023 (JP) 2023-056407
Feb. 8, 2024 (JP) 2024-018156

(51) Int. Cl. H01L 21/78; H01L 21/02; H01L 21/304; H01L 21/3115; H01L 21/449; H01L 29/04; H01L 29/16

(52) U.S. Cl. CPC H01L 21/7813; H01L 21/02115; H01L 21/02378; H01L 21/02444; H01L 21/02529; H01L 21/02595; H01L 21/304; H01L 21/31155; H01L 21/449; H01L 29/04; H01L 29/1608

(57) ABSTRACT

Provided is a method for manufacturing a semiconductor substrate, including: a step of forming a graphene layer on a Si surface of a SiC single crystal substrate; a step of forming a SiC-epitaxial growth layer on the graphene layer; a step of forming a stress layer on the SiC-epitaxial growth layer; a step of attaching a graphite substrate on the stress layer; a step of detaching the graphene layer and the SiC-epitaxial growth layer; a step of forming a SiC polycrystalline growth layer on a C surface of the SiC-epitaxial growth layer from which the graphene layer is detached; and a step of removing the graphite substrate, in which the stress layer generates a stress that facilitates detachment between the graphene layer and the SiC-epitaxial growth layer.

### CROSS-REFERENCE TO RELATED APPLICATIONS

This application claims priority to Japanese Patent Application No. 2023-056394, filed on Mar. 30, 2023, No. 2023-056407, filed on Mar. 30, 2023, and No. 2024-018156, filed on Feb. 8, 2024, the contents of each are incorporated here by reference in their entirety.

### TECHNICAL FIELD

The present disclosure relates to a semiconductor substrate and a method for manufacturing the same.

### BACKGROUND ART

In the past, for a usage application of power control, a SiC device has been provided such as a Schottky barrier diode (SBD), a metal-oxide-semiconductor field effect transistor (MOSFET), or an insulated gate bipolar transistor (IGBT). A SiC semiconductor substrate in which this kind of SiC device is formed is sometimes fabricated by attaching a SiC single crystal semiconductor substrate to a SiC polycrystalline semiconductor substrate in order to reduce the manufacturing cost or provide desired physical properties. Patent Literature 1 discloses a technique of attaching a SiC single crystal semiconductor substrate to a SiC polycrystalline semiconductor substrate without causing defects in order to grow an epitaxial layer on the SiC single crystal semiconductor substrate attached to the SiC polycrystalline semiconductor substrate.

Silicon carbide (SiC) is one of semiconductor materials, which are currently attracting the most attention, and for a usage application of power control, a SiC power device is provided such as a Schottky barrier diode (SBD), a metal-oxide-semiconductor field effect transistor (MOSFET), or an insulated gate bipolar transistor (IGBT). Since the internal loss of a power device fabricated using a SiC wafer as a substrate can be drastically reduced compared with that of a current device using silicon as a substrate, various applications of the device are expected as an energy-saving power device that can effectively use limited energy.

The SiC single crystal semiconductor wafer in which this kind of device is formed is sometimes fabricated by attaching a SiC single crystal semiconductor layer to a SiC polycrystalline semiconductor substrate in order to reduce the manufacturing cost or provide desired physical properties. In addition, since a large current flows through the power device, a large Joule heat is generated due to an electrical resistance of a substrate. As a countermeasure, to reduce the electrical resistance and thermal resistance, it is necessary to reduce the thickness of the wafer to ⅓ of the thickness, that is to 100 μm or less by the back surface polishing.

### CITATION LIST

### Patent Literature

[Patent Literature 1] U.S. Pat. No. 8,916,451 B
[Patent Literature 2] WO 2022/158078 A1
[Patent Literature 3] WO 2022/158085 A1

### SUMMARY

However, polishing processing for ensuring the surface roughness necessary for attaching the SiC single crystal semiconductor substrate to the SiC polycrystalline semiconductor substrate by means of normal temperature bonding or diffusion bonding becomes high in cost, and a yield is sometimes reduced due to a defect occurred at a bonding interface. In addition, since SiC has the next highest hardness following the hardness of diamond, it is difficult to perform high-efficiency processing by means of a conventional mechanical processing method such as grinding and polishing, and a high processing cost is required for back surface thinning, which has become an obstacle to practical application.

The present disclosure is proposed in view of the above-described problems, and an object of the present disclosure is to provide a low-cost and high-quality semiconductor substrate and a method for manufacturing the same. Further, an object of the present disclosure is to provide a low-cost and high-quality SiC semiconductor substrate, a semiconductor device, and a method for manufacturing the same.

One aspect of the present disclosure provides a method for manufacturing a semiconductor substrate, including: a step of forming a graphene layer on a Si surface of a SiC single crystal substrate; a step of forming a SiC-epitaxial growth layer on the graphene layer; a step of forming a stress layer on the SiC-epitaxial growth layer; a step of attaching a temporary substrate on the stress layer; a step of detaching the graphene layer and the SiC-epitaxial growth layer; a step of forming a SiC polycrystalline growth layer on a C surface of the SiC-epitaxial growth layer from which the graphene layer is detached; and a step of removing the temporary substrate, in which the stress layer generates a stress that facilitates detachment between the graphene layer and the SiC-epitaxial growth layer.

Another aspect of the present disclosure provides a semiconductor substrate including: a SiC single crystal substrate; a graphene layer disposed on a Si surface of the SiC single crystal substrate; a SiC-epitaxial growth layer disposed on the SiC single crystal substrate with the graphene layer therebetween; and a stress layer disposed on a Si surface of the SiC-epitaxial growth layer, in which the stress layer generates a stress that facilitates detachment between the graphene layer and the SiC-epitaxial growth layer.

Another aspect of the present disclosure provides a method for manufacturing a semiconductor substrate, including: a step of forming a SiC-epitaxial growth layer on a Si surface of a SiC single crystal substrate; a step of attaching a temporary substrate on a Si surface of the SiC-epitaxial growth layer; a step of removing the SiC-epitaxial growth layer from the SiC single crystal substrate; a step of forming a first SiC polycrystalline growth layer on a C surface of the SiC-epitaxial growth layer to which the temporary substrate is attached; a step of forming a graphene layer on the first SiC polycrystalline growth layer; a step of forming a second SiC polycrystalline growth layer on the graphene layer; and a step of removing the temporary substrate.

Another aspect of the present disclosure provides a semiconductor substrate including: a SiC-epitaxial growth layer; a first SiC polycrystalline growth layer disposed on a Si surface of the SiC-epitaxial growth layer; a graphene layer disposed on the first SiC polycrystalline growth layer; and a second SiC polycrystalline growth layer disposed on the graphene layer.

According to the present disclosure, it is possible to provide a low-cost and high-quality semiconductor substrate and a method for manufacturing the same. Further, it is possible to provide a low-cost and high-quality SiC semiconductor substrate.

### BRIEF DESCRIPTION OF THE DRAWINGS

FIG. 1 shows a cross-sectional view of a SiC single crystal substrate.

FIG. 2A shows a plan view for explaining a crystal plane of a SiC wafer.

FIG. 2B shows a side view for explaining a crystal plane of a SiC wafer.

FIG. 3A shows a bird's eye view of a unit cell of a 4H—SiC crystal.

FIG. 3B shows a structure diagram of a two-layer portion of a 4H—SiC crystal.

FIG. 3C shows a structure diagram of a four-layer portion of a 4H—SiC crystal.

FIG. 4 shows a structure diagram of the unit cell of the 4H—SiC crystal shown in FIG. 3A viewed from directly above a (0001) surface.

FIG. 5 shows a cross-sectional view of a structure in which a graphene layer is formed on a SiC single crystal substrate.

FIG. 6 shows a bird's eye view of an example of a graphene layer constituted by a plurality of layers which are stacked.

FIG. 7 shows a cross-sectional view of a structure in which a SiC-epitaxial growth layer is formed on a graphene layer.

FIG. 8 shows a cross-sectional view of a structure in which a stress layer is formed on a SiC-epitaxial growth layer.

FIG. 9A is an explanatory diagram for describing a mechanism by which stress is generated, and is an explanatory diagram for describing a delamination mode in a cross-sectional structure in which a stress layer is formed.

FIG. 9B is an explanatory diagram for describing a mechanism by which stress is generated, and is an explanatory diagram for describing another delamination mode in a cross-sectional structure in which a stress layer is formed.

FIG. 9C is an explanatory diagram for describing a mechanism by which stress is generated, and is an explanatory diagram for describing a detachment mode or a breakage mode in a cross-sectional structure in which a stress layer is formed.

FIG. 10 is an explanatory diagram for describing a mechanism by which stress is generated and shows the relationship between stress and a distances from a surface of a part that is detached or broken.

FIG. 11 shows a cross-sectional view of a structure in which a graphite substrate is attached on a stress layer with an adhesive layer therebetween.

FIG. 12A shows a cross-sectional view of a structure on a SiC-epitaxial growth layer side of structures which are obtained by detaching the structure shown in FIG. 11 at an interface between a graphene layer and a SiC-epitaxial growth layer.

FIG. 12B shows a cross-sectional view of a structure on a graphene layer side of the structures which are obtained by detaching the structure shown in FIG. 11 at the interface between the graphene layer and the SiC-epitaxial growth layer.

FIG. 13 shows a cross-sectional view of a structure in which the detachment structure shown in FIG. 12A is attached on both sides of a graphite substrate and an adhesive layer is carbonized by means of annealing.

FIG. 14 shows a cross-sectional view of a structure in which a SiC polycrystalline growth layer is formed by means of a CVD method.

FIG. 15 shows a cross-sectional view of a structure in which a part of an outer periphery of a SiC polycrystalline growth layer is ground.

FIG. 16 shows a cross-sectional view of a structure in which a graphite substrate and a carbonized adhesive layer are removed by means of annealing.

FIG. 17 shows a cross-sectional view in which the temporary substrate in the structure of FIG. 14 is cut into two pieces at a plane shown in line A-A in FIG. 14 and separated vertically.

FIG. 18 shows a cross-sectional view of a structure in which a SiC polycrystalline growth layer at an outer periphery and a stress layer are removed.

FIG. 19 shows a cross-sectional view of a SiC composite substrate.

FIG. 20 shows a bird's eye view of a SiC composite substrate (wafer).

FIG. 21 shows a cross-sectional view of a structure having a highly doped layer at an interface with a SiC polycrystalline growth layer in a SiC-epitaxial growth layer.

FIG. 22 shows a cross-sectional view of a Schottky barrier diode.

FIG. 23 shows a cross-sectional view of a trench gate TMOSFET.

FIG. 24 shows a cross-sectional view of a planar gate MOSFET.

FIG. 25 shows a cross-sectional view of a SiC single crystal substrate.

FIG. 26A shows a plan view for explaining a crystal plane of a SiC wafer.

FIG. 26B shows a side view for explaining a crystal plane of a SiC wafer.

FIG. 27A shows a bird's eye view of a unit cell of a 4H—SiC crystal.

FIG. 27B shows a structure diagram of a two-layer portion of a 4H—SiC crystal.

FIG. 27C shows a structure diagram of a four-layer portion of a 4H—SiC crystal.

FIG. 28 shows a structure diagram of the unit cell of the 4H—SiC crystal shown in FIG. 27A viewed from directly above a (0001) surface.

FIG. 29 shows a cross-sectional view of a structure in which a first graphene layer is formed on a SiC single crystal substrate.

FIG. 30 shows a bird's eye view of an example of a graphene layer constituted by a plurality of layers which are stacked.

FIG. 31 shows a cross-sectional view of a structure in which a SiC-epitaxial growth layer is formed on a first graphene layer.

FIG. 32 shows a cross-sectional view of a structure in which a stress layer is formed on a SiC-epitaxial growth layer.

FIG. 33A is an explanatory diagram for describing a mechanism by which stress is generated, and is an explanatory diagram for describing a delamination mode in a cross-sectional structure in which a stress layer is formed.

FIG. 33B is an explanatory diagram for describing a mechanism by which stress is generated, and is an explanatory diagram for describing another delamination mode in a cross-sectional structure in which a stress layer is formed.

FIG. 33C is an explanatory diagram for describing a mechanism by which stress is generated, and is an explanatory diagram for describing a detachment mode or a breakage mode in a cross-sectional structure in which a stress layer is formed.

FIG. 34 a cross-sectional view of a structure in which a graphite substrate is attached on a stress layer with an adhesive layer therebetween.

FIG. 35A shows a cross-sectional view of a structure on a SiC-epitaxial growth layer side of structures which are obtained by detaching the structure in which the graphite substrate is attached on the stress layer with the adhesive layer therebetween, at an interface between a first graphene layer and the SiC-epitaxial growth layer.

FIG. 35B shows a cross-sectional view of a structure on a first graphene layer side of structures which are obtained by detaching the structure in which the graphite substrate is attached on the stress layer with the adhesive layer therebetween, at an interface between the first graphene layer and a SiC-epitaxial growth layer.

FIG. 36 shows a cross-sectional view of a structure in which the detachment structure shown in FIG. 11A is attached on both sides of a graphite substrate and an adhesive layer is carbonized by means of annealing.

FIG. 37 shows a cross-sectional view of a structure in which a first SiC polycrystalline growth layer is formed by means of a CVD method.

FIG. 38 shows a cross-sectional view of a structure in which a second graphene layer is formed.

FIG. 39 shows a cross-sectional view of a structure in which a second SiC polycrystalline growth layer is formed by means of a CVD method.

FIG. 40 shows a cross-sectional view of a structure in which parts of an outer periphery of a second SiC polycrystalline growth layer, a second graphene layer, and a first SiC polycrystalline growth layer are ground.

FIG. 41 shows a cross-sectional view of a structure in which a graphite substrate and a carbonized adhesive layer are removed by means of combustion.

FIG. 42 shows a cross-sectional view in which the temporary substrate in the structure of FIG. 39 is cut into two pieces at a plane shown in line A-A in FIG. 39 and separated vertically.

FIG. 43 shows a cross-sectional view of a structure in which a second SiC polycrystalline growth layer, second graphene layer, and first SiC polycrystalline growth layer at an outer periphery, and a stress layer are removed to form a SiC composite substrate.

FIG. 44 shows a cross-sectional view of a structure in which a stress layer is attached on a bottom surface of a spot facing hole formed in a graphite substrate with an adhesive layer therebetween.

FIG. 45 shows a cross-sectional view of a structure after a SiC single crystal substrate and a first graphene layer are detached.

FIG. 46 shows a cross-sectional view of a structure in which a first SiC polycrystalline growth layer is formed by means of a CVD method.

FIG. 47 shows a cross-sectional view of a structure in which a second graphene layer is formed.

FIG. 48 shows a cross-sectional view of a structure in which a second SiC polycrystalline growth layer is formed by means of a CVD method.

FIG. 49 shows a cross-sectional view of a structure in which a second SiC polycrystalline growth layer, a second graphene layer, and a first SiC polycrystalline growth layer at an outer periphery are ground.

FIG. 50 shows a cross-sectional view of a SiC composite substrate.

FIG. 51 shows a bird's eye view of a SiC composite substrate (wafer).

FIG. 52 shows a cross-sectional view of a structure having a highly doped layer at an interface with a first SiC polycrystalline growth layer in a SiC-epitaxial growth layer.

FIG. 53 shows a cross-sectional view of a semiconductor device constituting a part of a Schottky barrier diode.

FIG. 54 shows a cross-sectional view of a semiconductor device constituting a part of a trench gate MOSFET.

FIG. 55 shows a cross-sectional view of a semiconductor device constituting a part of a planar gate MOSFET.

FIG. 56 is a cross-sectional view of a state where a second graphene layer and a second SiC polycrystalline growth layer are detached.

FIG. 57 is a cross-sectional view showing a method for forming a starting point of a crack between a second graphene layer and a second SiC polycrystalline growth layer.

FIG. 58 is a cross-sectional view showing another method for forming a starting point of a crack between a second graphene layer and a second SiC polycrystalline growth layer.

FIG. 59 is a cross-sectional view showing a method for developing a crack between a second graphene layer and a second SiC polycrystalline growth layer.

FIG. 60 is a cross-sectional view showing another method for developing a crack between a second graphene layer and a second SiC polycrystalline growth layer.

FIG. 61 shows a cross-sectional view of a Schottky barrier diode.

FIG. 62 shows a cross-sectional view of a trench gate MOSFET.

FIG. 63 shows a cross-sectional view of a planar gate MOSFET.

FIG. 64 shows a cross-sectional view of a structure in which a hydrogen ion implantation layer is formed on a Si surface of a SiC single crystal substrate.

FIG. 65 shows a cross-sectional view of a structure in which after a hydrogen ion implantation layer is embrittled by annealing the hydrogen ion implantation layer, and a thinned SiC single crystal layer is formed, a SiC-epitaxial growth layer is formed on a Si surface of the thinned SiC single crystal layer.

FIG. 66 shows a cross-sectional view of a structure in which a graphite substrate is attached on a Si surface of a SiC-epitaxial growth layer with an adhesive layer therebetween.

FIG. 67 shows a cross-sectional view of a structure detached and separated from a SiC single crystal substrate through a thinned SiC single crystal layer formed by performing embrittlement and annealing.

FIG. 68 shows a cross-sectional view of a structure in which a detachment surface of a thinned SiC single crystal layer is smoothed.

FIG. 69 shows a cross-sectional view of a structure in which a first SiC polycrystalline growth layer is formed by means of a CVD method.

FIG. 70 shows a cross-sectional view of a structure in which a second graphene layer is formed.

FIG. 71 shows a cross-sectional view of a structure in which a second SiC polycrystalline growth layer is formed by means of a CVD method.

FIG. 72 shows a cross-sectional view of a structure in which a second SiC polycrystalline growth layer, a second graphene layer, and a first SiC polycrystalline growth layer at an outer periphery are ground.

FIG. 73 shows a cross-sectional view of a SiC composite substrate obtained by removing an adhesive layer and a graphite substrate.

### DETAILED DESCRIPTION

Next, embodiments will be described with reference to the drawings. In the description of the drawings below, the same or similar parts are denoted with the same or similar reference numerals. The drawings are schematically shown. In addition, the embodiments describe below exemplify devices and methods for embodying technical ideas, and do not specify materials, shapes, structures, arrangements, and the like of components. Various modifications may be made to the embodiments.

### First Embodiment

First, a first embodiment will be described. In the first embodiment, a stress layer is stacked on a SiC-epitaxial growth layer formed on a SiC single crystal substrate with a graphene layer therebetween, and the stress layer generates a stress that facilitates detachment between the graphene layer and the SiC-epitaxial growth layer.

### Method for Manufacturing Semiconductor Substrate

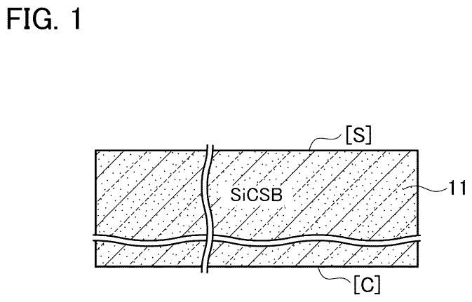

A method for manufacturing a semiconductor substrate according to the first embodiment will be described. FIG. 1 is a cross-sectional view of a SiC single crystal substrate (SiCSB) 11 serving as a seed substrate. The SiC single crystal substrate 11 is a 4H—SiC substrate, for example, and a thickness thereof is about 300 μm to 600 μm, for example. In FIG. 1, [C] indicates a C surface of the SiC, and [S] indicates a Si surface of the SiC. The same applies in the diagrams described below.

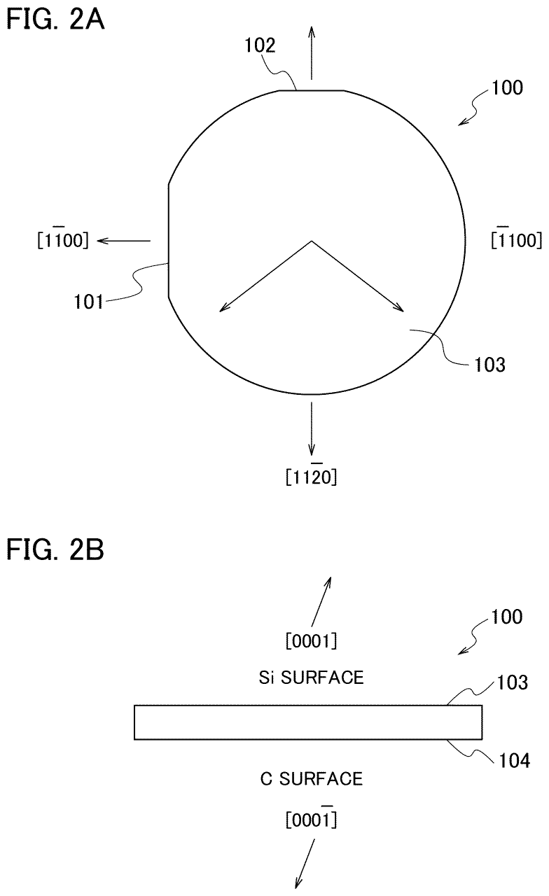

FIG. 2 is a diagram for explaining a crystal plane of a SiC wafer 100 applicable as the SiC single crystal substrate 11. FIG. 2A is a plan view showing a Si surface 103 of the SiC wafer 100 to which a primary orientation flat 101 and a secondary orientation flat 102 are formed. In a side view viewed from an orientation of [−1100] of FIG. 2B, the Si surface 103 with an orientation of is formed on an upper surface, and a C surface 104 with an orientation of [000-1] is formed on a lower surface.

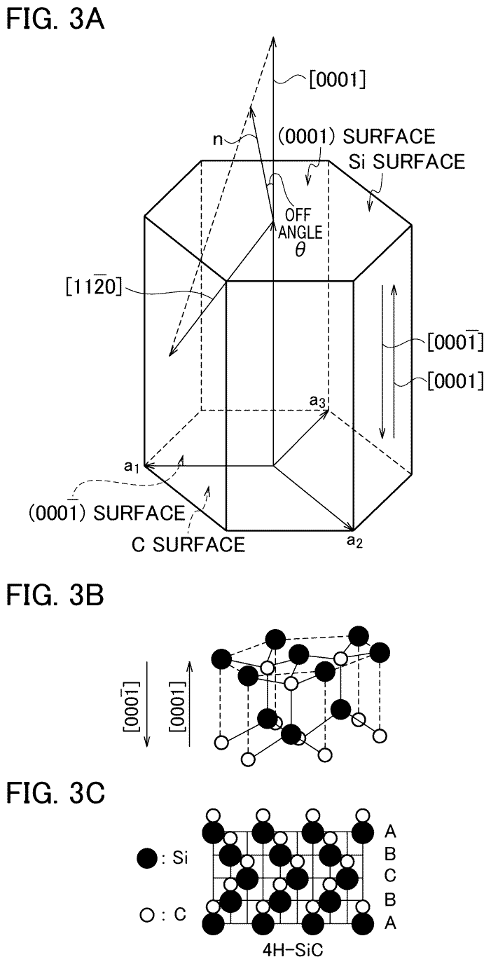

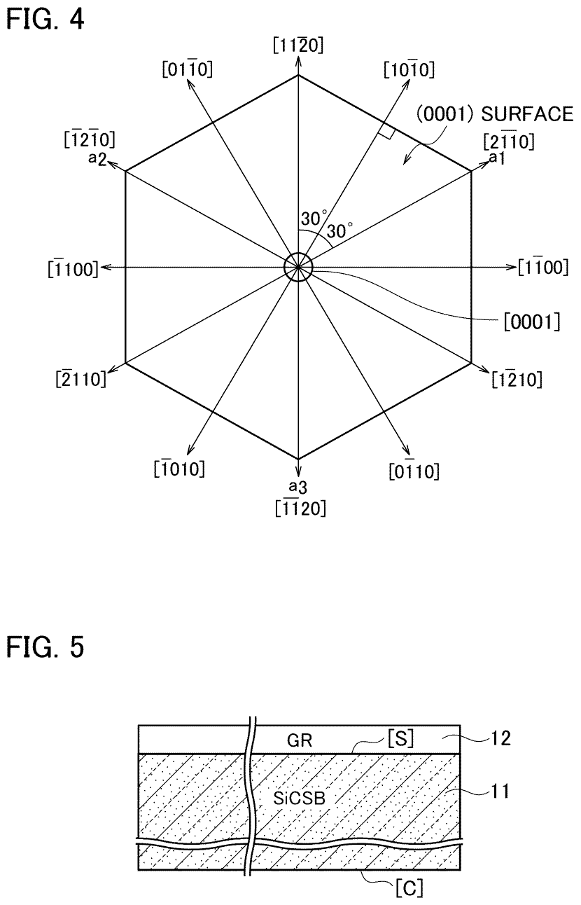

A schematic bird's eye view structure of a unit cell of a 4H—SiC crystal applicable in the first embodiment is represented as shown in FIG. 3A, a schematic structure of a two-layer portion of the 4H—SiC crystal is represented as shown in FIG. 3B, and a schematic structure of a four-layer portion of the 4H—SiC crystal is represented as shown in FIG. 3C. Further, a schematic structure of the unit cell of a 4H—SiC crystal structure shown in FIG. 3A viewed from directly above a (0001) surface is represented as shown in FIG. 4.

As shown in FIGS. 3A to 3C, the crystal structure of the 4H—SiC can be approximated with a hexagonal system, and four C atoms are bonded to one Si atom. The four C atoms are positioned at four vertices of a regular tetrahedron with the Si atom disposed at a center thereof. Regarding the four C atoms, one Si atom is positioned on a axial direction relative to the C atom, and other three C atoms are positioned on a [000-1] axis side relative to the Si atom. In FIG. 3A, an off angle θ is about 4 degrees or less, for example.

The [0001] axis and [000-1] axis are along an axial direction of a hexagonal prism, and a surface (top surface of hexagonal prism) of which normal line is the axis is the (0001) surface (Si surface). Meanwhile, a surface (bottom surface of hexagonal prism) of which normal line is the [000-1] axis is the (000-1) surface (C surface). Directions perpendicular to the [0001] axis and passing non-adjacent vertices of the hexagonal prism when viewed from directly above the (0001) surface are an a1 axis [2-1-10], an a2 axis [−12-10], and an a3 axis [−1-120].

As shown in FIG. 4, a direction passing through a vertex between the a1 and a2 axes is a [11-20] axis, a direction passing through a vertex between the a2 and a3 axes is a [−2110] axis, and a direction passing through a vertex between the a3 and a1 axes is a [1-210] axis. Axes each of which is positioned between two of the above six axes passing through each vertex of the hexagonal prism, is inclined at an angle of 30 degrees relative to the two axes on both sides, and serves as a normal line of each side surface of the hexagonal prism are, a [10-10] axis, a [1-100] axis, a [0-110] axis, a [−1010] axis, a [−1100] axis, and a [01-10] axis, in a clockwise direction sequentially from between the a1 and [11-20] axes. Each surface of which normal lines are these axes (side surface of hexagonal prism) is a crystal plane perpendicular to the (0001) surface and (000-1) surface.

Next, as shown in FIG. 5, a graphene layer (GR) 12 up to several molecular layers is formed on a (0001) Si surface of the SiC single crystal substrate 11. The graphene layer 12 can be formed on the Si surface of the SiC single crystal substrate 11 by means of thermal decomposition by annealing the SiC single crystal substrate 11 at about 1700° C. in an atmospheric pressure argon gas atmosphere, for example. Further, the graphene layer 12 may be stacked on the SiC single crystal substrate 11 by means of CVD.

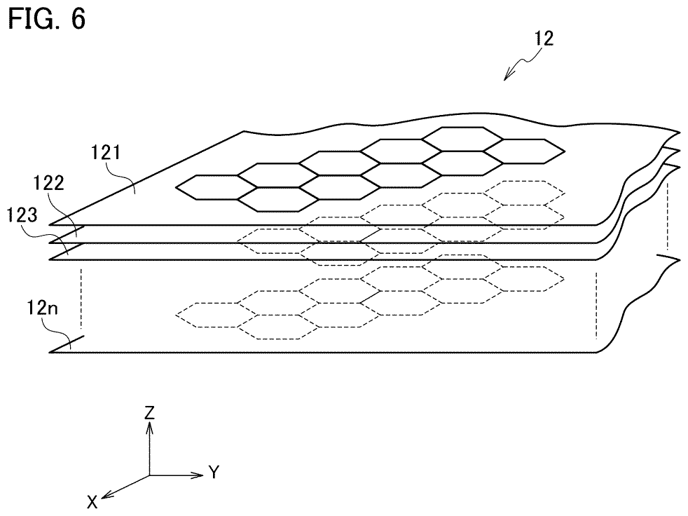

The graphene layer 12 applicable to the first embodiment is represented as shown in FIG. 6. The graphene layer 12 has a stacked structure of graphite sheets 121, 122, 123, . . . 12n. The n-layered graphite sheets 121, 122, 123, . . . 12n on each surface have covalent bonds of many hexagonal system carbons (C) in one stacked crystal structure, and the graphite sheets 121, 122, 123, . . . 12n on each surface are bonded by means of van der Waals force. In the first embodiment, the graphene layer 12 may be a zeroth layer as a buffer layer or may have a single layer structure.

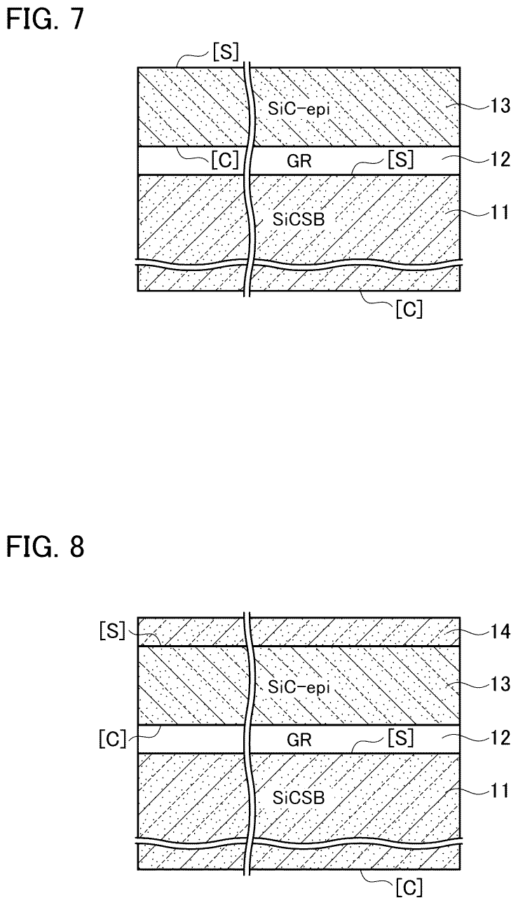

As shown in FIG. 7, a SiC-epitaxial growth layer (SiC-epi) 13 is formed on the graphene layer 12. The SiC-epitaxial growth layer 13 is formed on the graphene layer 12 which has been formed on the Si surface of the SiC single crystal substrate 11 by means of a method for remote epitaxial growth. The SiC-epitaxial growth layer 13 is a single crystal SiC thin film. A surface of the SiC-epitaxial growth layer 13 in contact with the graphene layer 12 becomes the C surface, and the remaining surface of the SiC-epitaxial growth layer 13 becomes the Si surface.

As shown in FIG. 8, a stress layer 14 is formed on the SiC-epitaxial growth layer 13. The stress layer 14 generates a stress between the graphene layer 12 and the SiC-epitaxial growth layer 13 to facilitate detachment between the graphene layer 12 and the SiC-epitaxial growth layer 13.

The stress layer 14 of the first embodiment is constituted by a carbon film or a silicon nitride film. The carbon film is constituted by a polycrystalline diamond film or a diamond-like carbon film. If the carbon film is the polycrystalline diamond film, the film is obtained by using a microwave chemical vapor deposition (CVD) apparatus or the like, and if the carbon film is the diamond-like carbon film, the film is obtained by using an RF plasma chemical vapor deposition (CVD) apparatus or the like. In addition, during formation of both films, a negative potential is applied on a film forming substrate side at an initial stage of the film formation to form a film while ion bombardment is applied thereto, and accordingly the required film adhesion can be obtained.

Table 1 below shows representative physical properties of the carbon film or silicon nitride film of the stress layer 14, the SiC single crystal substrate 11, and other layers. Since materials of the stress layer 14 used in the first embodiment are subjected to a step of forming a SiC polycrystalline growth layer 16 in a later step, the materials are required to have a heat resistance of 1500° C. or higher.

TABLE 1

| | | | | Linear | |
|---|---|---|---|---|---|
| | | | | coefficient | Film formation |
| | | Young's | | of expansion | temperature |
| Material name of | | modulus | Poisson | [ppm/° C. | (Film formation |
| substrate and each layer | | [MPa] | ratio | @300K] | equipment) |
| Carbon | Polycrystalline | 1141000 | 0.07 | 1.0 | 750° C. (μ- |
| film | diamond film | | | | wave CVD) |
| | Diamond-like | Depend | ← | 1.0 | to 200° C. |
| | carbon film | on film | | | (PE-CVD) |
| | | quality | | | |

| | | | | |
|---|---|---|---|---|
| Silicon nitride film | 280000 | 0.27 | 2.5 | 780° C. |
| | | | | (LP-CVD) |
| SiC single crystal exitaxial | 390000 | 0.17 | 3.9 | 1600° C. |
| growth layer | | | | (HT-CVD) |
| Graphene layer | 4000 | 0.3 | 3.9 | 1600° C. |
| | | | | (SiC thermal |
| | | | | decomposition) |
| SiC single crystal substrate | 390000 | 0.17 | 3.9 | 1600° C. |
| | | | | (SiC thermal |
| | | | | decomposition) |

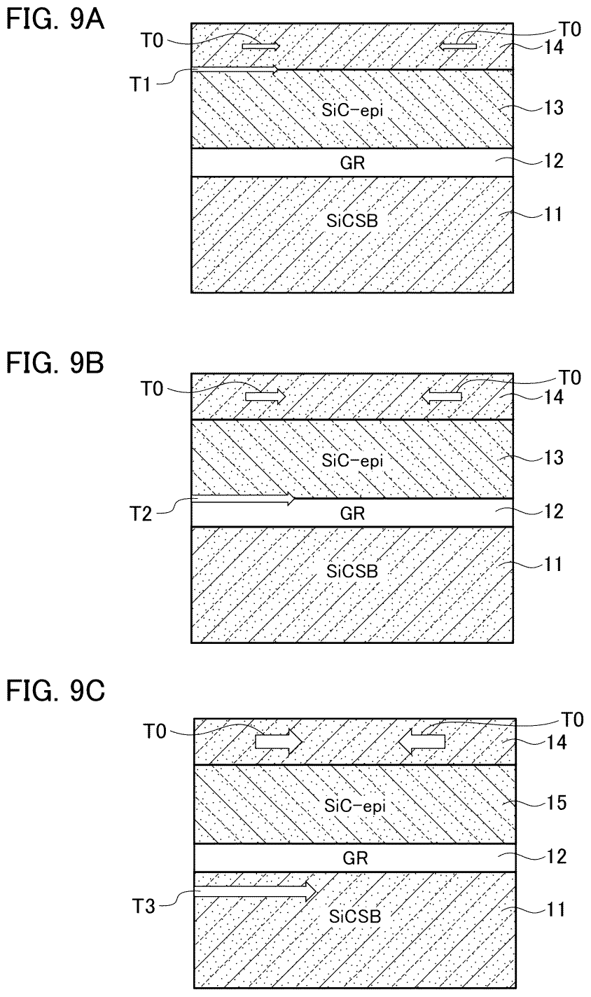

A mechanism by which the stress layer 14 generates a stress will be described with reference to FIGS. 9A to 9C. In examples shown in FIGS. 9A to 9C, an internal stress TO of the stress layer is a tensile stress, and the magnitude of the internal stress TO gradually increases as the process proceeds from FIG. 9A, FIG. 9B, FIG. 9C in this order. In the first embodiment, the internal stress TO generated by the stress layer 14 includes three kinds of components: a true stress generated by characteristics of each material during film formation, a thermal stress generated by a difference in a thermal expansion coefficient between the SiC single crystal substrate 11 and the stress layer 14, and a stress generated by a film quality change of the stress layer 14 such as a film density change due to hydrogen desorption in the film during a heat treatment after film formation. Whether the internal stress TO of the stress layer 14 is the compressive stress or tensile stress and how large the magnitude thereof is are based on these three kinds of components.

The true stress depends on a film thickness and temperature at the time of film formation. Further, due to the liberation of hydrogen in the film by a heat treatment after film formation of the stress layer 14, the film density changes, the compressive stress relaxes, and the tensile stress increases. Still further, the stress generated by the stress layer depends on a stacked structure of the SiC single crystal substrate 11, the graphene layer 12, the SiC-epitaxial growth layer 13, the stress layer 14, and an adhesive layer 15 and a graphite substrate 19 which will be described later.

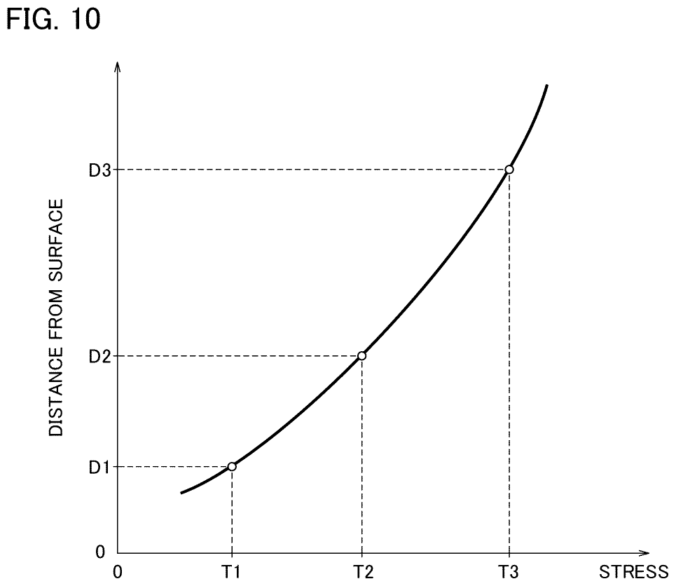

FIG. 10 is an explanatory diagram of the mechanism by which the stress layer 14 generates a stress, and shows the relationship between a stress and distances from a surface of a part that can be detached or broken. A horizontal axis in FIG. 10 indicates the magnitudes of stresses T1, T2, and T3 shown in FIGS. 9A, 9B, and 9C, respectively at a position where the SiC-epitaxial growth layer 13, the graphene layer 12, or the SiC single crystal substrate 11 may be detached or broken, and D1, D2, and D3 of a vertical axes indicate distances from the surface of the detached or broken part. The stresses T1, T2, and T3 are the tensile stresses generated by the internal stress TO of the stress layer 14, and increase in accordance with the internal stress TO that increase as the process proceeds from FIG. 9A, FIG. 9B, FIG. 9C in this order. In addition, an aspect of detachment or breakage becomes increasingly intense from a delamination mode at an interface between the stress layer 14 and the SiC-epitaxial growth layer 13 and another delamination mode at an interface between the SiC-epitaxial growth layer 13 and the graphene layer 12, toward a detachment mode or breakage mode in the SiC single crystal substrate 11.

In the first embodiment, the stress generated by the internal stress TO of the stress layer 14 is adjusted to approximate the adhesion energy between the graphene layer 12 and the SiC-epitaxial growth layer 13. As shown in FIG. 9B, a stress T2 for facilitating detachment between the graphene layer 12 and the SiC-epitaxial growth layer 13 is generated at an interface thereof. Therefore, the stress layer 14 is formed of a specific material such as a silicon nitride film or a carbon film constituted by a polycrystalline diamond film or a diamond carbon film, and film formation conditions such as a film thickness and film formation temperature are adjusted to appropriately set the internal stress TO in the stress layer 14. In this way, in the first embodiment, the stress generated by the stress layer 14 is set so as to approximate the adhesion energy between the graphene layer 12 and the SiC-epitaxial growth layer 13, and accordingly detachment between the graphene layer 12 and the SiC-epitaxial growth layer 13 is facilitated.

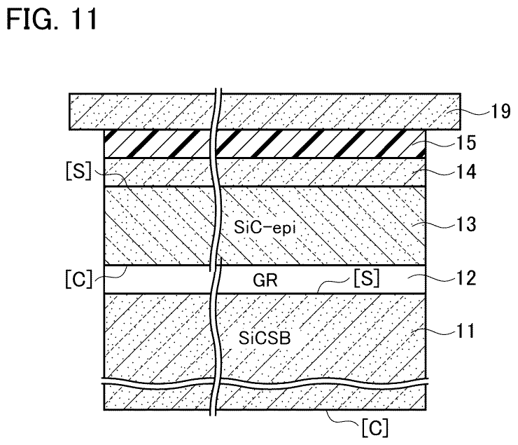

Next, as shown in FIG. 11, the adhesive layer 15 is formed on the stress layer 14, a coated surface of the adhesive layer 15 is stacked and attached on one or both sides of the graphite substrate 19 as a temporary substrate of which external size is one size larger than that of the SiC single crystal substrate 11, and a first composite (11 (SiCSB), 12 (GR), 13 (SiC-epi), 14, 15, and 19) is formed. A carbon adhesive may be used for the adhesive layer 15, for example. The carbon adhesive contains phenolic resin, and can maintain bonding force thereof even at a high temperature due to the adhesive itself being carbonized. If a diameter of the SiC single crystal substrate 11 is about 10 cm, as the temporary substrate of which external size is one size larger, the graphite substrate 19 having a diameter of about 11 cm, of which external size is about 10 mm larger than that of the SiC single crystal substrate 11 is used, for example. If a diameter of the SiC single crystal substrate 11 is about 15 cm, the graphite substrate 19 of which external size has a diameter of about 16 cm is used, for example. The temporary substrate (graphite substrate 19) which is one size larger than the SiC single crystal substrate 11 has the advantage of setting strut marks on a wafer boat outside a substrate effective area when inserted into a wafer boat groove in a vertical batch CVD furnace and aligned.

Then, the first composite is heated in a vacuum annealing furnace or the like to dry and cure the adhesive layer 15. The graphite substrate 19 may have a glassy carbon film on a surface thereof. Since adhesion force between the glassy carbon film and the carbon adhesive is strong, the SiC-epitaxial growth layer 13 can be easily detached from the graphene layer 12 and the SiC single crystal substrate 11, and a yield can be enhanced. Although FIG. 11 shows an example in which the first composite is formed by attaching the adhesive layer 15 to one side of the graphite substrate 19, the first composite may be formed by attaching the adhesive layer 15 to both sides of the graphite substrate 19.

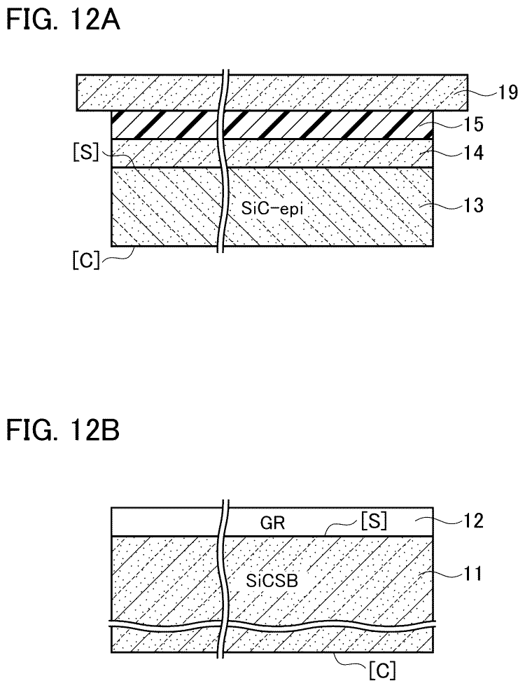

As shown in FIG. 12, after curing the first composite shown in FIG. 11, the SiC-epitaxial growth layer 13 is physically detached and separated from the graphene layer 12 at an interface thereof on one or both sides of the first composite by using an adhesive detaching tape, debonder equipment, or the like. FIG. 12A is a cross-sectional view of a structure detached on the SiC-epitaxial growth layer 13 side from the first composite shown in FIG. 11, and FIG. 12B is a cross-sectional view of a structure detached on the graphene layer 12 side. The structure detached on the SiC-epitaxial growth layer 13 side shown in FIG. 12A forms a second composite (13 (SiC-epi), 14, 15, and 19). In the first embodiment, the graphene layer 12 is bonded by means of van der Waals force and the stress generated by the stress layer 14 is adjusted to approximate the adhesion energy between the graphene layer 12 and the SiC-epitaxial growth layer 13 in magnitude, and therefore the graphene layers 12 and the SiC-epitaxial growth layer 13 can be easily detached at the interface thereof by applying force in a shear direction.

In the structure detached on the graphene layer 12 side shown in FIG. 12B, the graphene layer 12 on the SiC single crystal substrate 11 is removed by means of etching or polishing. In a step of etching the graphene layer 12, a plasma usher with oxygen plasma can be applied, for example. The Si surface of the SiC single crystal substrate 11 with the graphene layer 12 thereon being etched with oxygen plasma, is subjected to wet etching with hydrogen fluoride (HF), because a surface thereof is oxidized. Further, in a step of polishing the graphene layer 12, the graphene layer 12 is removed by means of Chemical Mechanical Polishing (CMP), for example. An average surface roughness Ra of the Si surface of the SiC single crystal substrate 11 by the wet etching step described above is, for example, about 1 nm or less. As a result, the SiC single crystal substrate 11 can be reused.

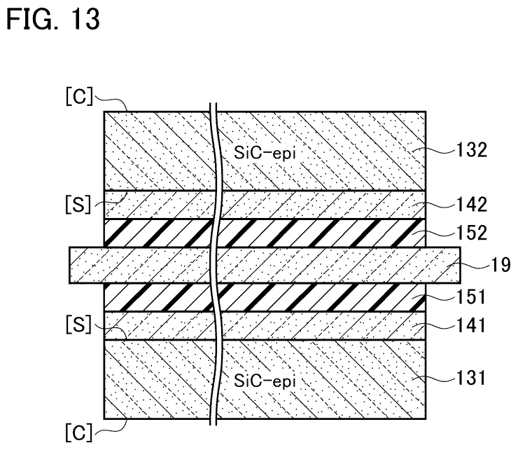

FIG. 13 shows an example in which detachment structure of FIG. 12A is attached on both sides of the graphite substrate 19 and SiC-epitaxial growth layers 131 and 132 are formed on both sides. In this case, the second composite (131 (SiC-epi), 141, 151, 19, 152, 142, and 132 (SiC-epi)) is heated in a vacuum thermal annealing furnace to form carbonized adhesive layers 151 and 152.

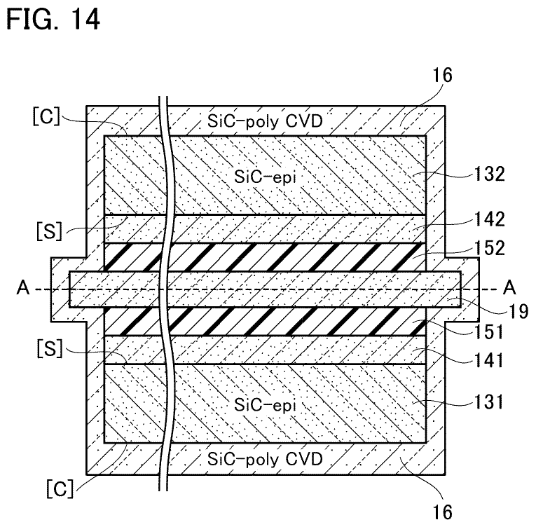

As shown in FIG. 14, the SiC polycrystalline growth layers 16 are formed on (000-1) C surfaces of the SiC-epitaxial growth layers 131 and 132 formed on one or both sides of the second composite. Each SiC polycrystalline growth layer 16 can be formed by means of a CVD technique. Each SiC polycrystalline growth layer 16 has a 3C (cubic) structure. Substrate layers of a device wafer structure are formed by forming the SiC polycrystalline growth layers 16 on the C surfaces of the SiC-epitaxial growth layers 131 and 132. Since the C surfaces of the SiC-epitaxial growth layers 131 and 132 are back surfaces of the device wafer structure, the surfaces are less required to have surface flatness. Therefore, the SiC polycrystalline growth layers 16 can be formed by performing a simple polishing process.

The SiC polycrystalline growth layer 16 is deposited until a thickness thereof is sufficient to obtain the necessary mechanical strength as a substrate of a SiC-based semiconductor element, and a third composite (16 (SiC-poly CVD), 131 (SiC-epi), 141, 151, 19, 152, 142, 132 (SiC-epi), and 16 (SiC-poly CVD)) is formed. A thickness of the SiC polycrystalline growth layer 16 is preferably about 150 μm to 500 μm, and an adjustment is made such that a thickness of a final SiC composite substrate (SiC polycrystalline growth layer 16+SiC-epitaxial growth layers 131 and 132) is about 150 μm to 500 μm as necessary. The thermal conductivity is enhanced by reducing a thickness of the SiC polycrystalline growth layer 16. Further, a deposition temperature of the SiC polycrystalline growth layer 16 is preferably in a range from 1300° C. to 1600° C.

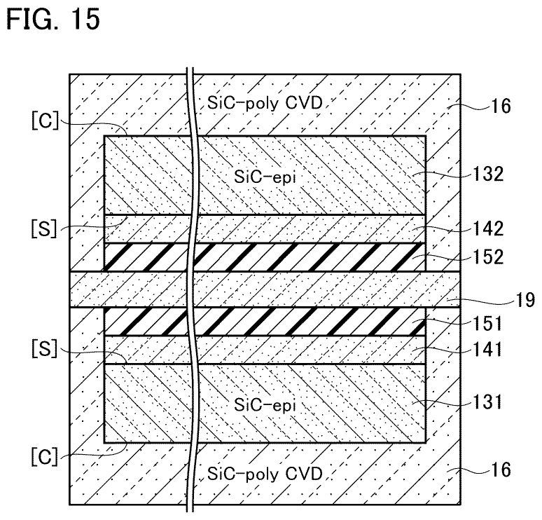

Unnecessary portions of the SiC polycrystalline growth layer 16 and the graphite substrate 19 as the temporary substrate, protruding from an outer periphery of the third composite are removed by grinding performed by an outer periphery grinding machine to expose the temporary substrate (graphite substrate 19) as shown in FIG. 15.

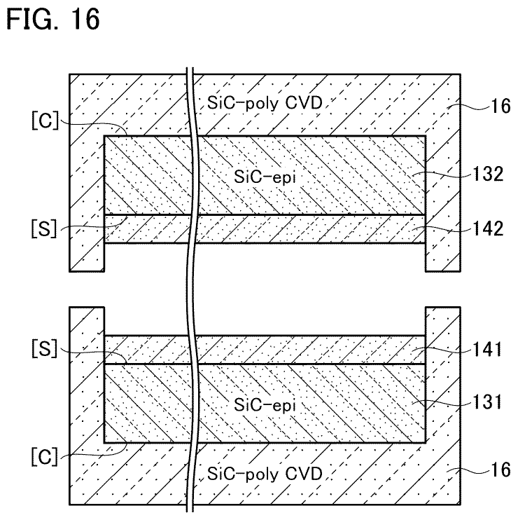

The graphite substrate 19 and the carbonized adhesive layers 151 and 152 inside the third composite of which outer periphery is ground shown in FIG. 15 are removed by means of oxidation combustion in a thermal annealing furnace of air or oxygen atmosphere as shown in FIG. 16. If stress layers 141 and 142 are constituted by a carbon film such as a polycrystalline diamond film or a diamond-like carbon film, the stress layers 141 and 142 are also removed together by means of oxidation combustion, and taken out as fourth composites (16 (SiC-poly CVD), 131 (SiC-epi), 132 (SiC-epi), and 16 (SiC-poly CVD)). FIG. 16 shows the fourth composites in which the stress layers 141 and 142 constituted by the carbon films are removed.

If the stress layers 141 and 142 are composed of silicon nitride, the stress layers 141 and 142 remain after removing the graphite substrate 19 and carbonized adhesive layers 151 and 152. Therefore, the stress layers are taken out as the fourth composites (16 (SiC-poly CVD), 131 (SiC-epi), 141, 142, 132 (SiC-epi), and 16 (SiC-poly CVD)).

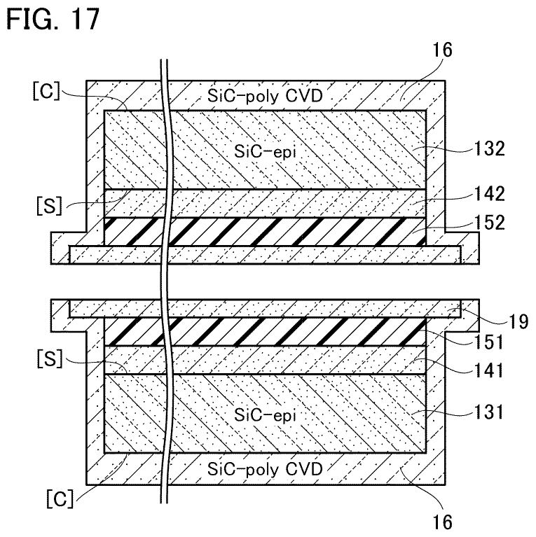

Instead of removing unnecessary portions of the SiC polycrystalline growth layer 16 and the graphite substrate 19, protruding from an outer periphery of the third composite using an outer periphery grinding machine, the temporary substrate (graphite substrate 19) may be cut into two pieces at a plane parallel to a main plane shown in line A-A in FIG. 15, the third composite may be separated vertically, and cut surfaces of the temporary substrate (graphite substrate 19) may be exposed as shown in FIG. 17. A wire saw or a diamond wire saw may be used as the separation technique, for example. In this case also, the graphite substrate 19 and the carbonized adhesive layers 151 and 152 inside the third composite can be removed by means of oxidation combustion and taken out as the fourth composites as shown in FIG. 16.

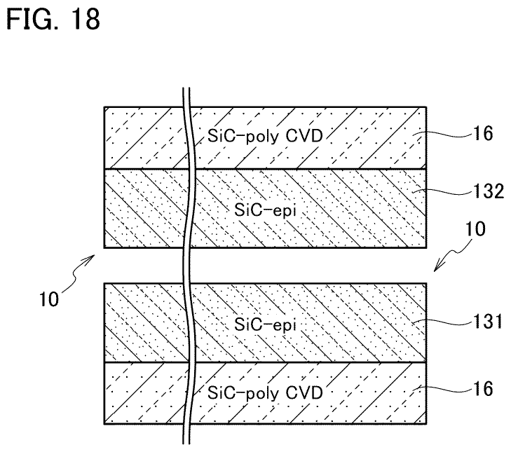

The SiC polycrystalline growth layer 16 at the outer periphery of the fourth composite is removed by grinding and polishing as shown in FIG. 18. If the stress layers 141 and 142 composed of silicon nitride shown in FIG. 16 remain in the fourth composite, the layers are removed by means of dry etching with a fluorocarbon gas plasma or by means of wet etching with a hot phosphoric acid. Further, a SiC composite substrate 10 is processed to have the required size and surface state.

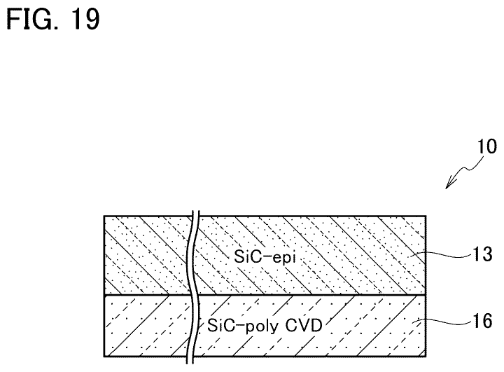

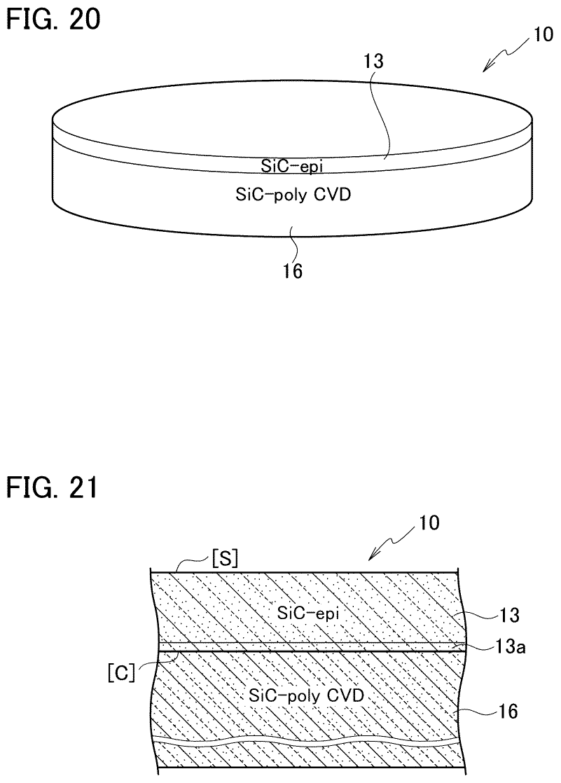

FIG. 19 shows a cross-sectional view of the SiC composite substrate 10. The SiC composite substrate 10 is obtained as upper and lower blocks in which the fourth composite is processed as shown in FIG. 18. FIG. 20 is a bird's eye view of the SiC composite substrate 10. The SiC composite substrate 10 includes the SiC-epitaxial growth layer 13 and the SiC polycrystalline growth layer 16 arranged on the C surface of the SiC-epitaxial growth layer 13.

A surface of the SiC-epitaxial growth layer 13 of the SiC composite substrate 10 is a Si surface of a [0001] orientation of the 4H—SiC, and a C surface is a surface of a [000-1] orientation of the 4H—SiC. A thickness of the SiC polycrystalline growth layer 16 is from about 150 μm to about 500 μm, for example, and a thickness of the SiC-epitaxial growth layer 13 is from about 4 μm to about 100 μm, for example.

In the SiC-epitaxial growth layer 13, a highly doped layer 13a may be formed toward the C surface of the SiC-epitaxial growth layer 13 in contact with the SiC polycrystalline growth layer 16 as shown in FIG. 21. By means of the highly doped layer 13a, it is possible to suppress the spread of a depletion layer in the SiC-epitaxial growth layer 13 and easily form an ohmic contact with the SiC polycrystalline growth layer 16 formed on the C surface of the SiC-epitaxial growth layer 13.

The highly doped layer 13a can be formed using a high dose ion implantation technique, for example. The highly doped layer 13a is formed by an ion implantation of phosphorus (P) at a high dose in a case of an n-type semiconductor, for example. If the layer is formed by P ion implantation, the crystallinity of the C surface implanted with P ions of the SiC-epitaxial growth layer 13 is affected, but the Si surface to be a device surface is already formed, and the crystallinity of the Si surface is preserved.

The highly doped layer 13a may be formed by forming a highly nitrogen (N) doped epitaxial growth layer at an initial stage when the SiC-epitaxial growth layer (SiC-epi) 13 shown in FIG. 7 is formed. In the highly nitrogen (N) doped epitaxial growth layer, although there is an influence on crystallinity due to mismatch of lattice constants, since the layer is formed by autodoping at an initial stage of epitaxial growth, steps are easy.

### Semiconductor Substrate

As shown in FIG. 8, the semiconductor substrate according to the first embodiment includes the SiC single crystal substrate (SiCSB) 11, the graphene layer (GR) 12 disposed on the Si surface of the SiC single crystal substrate 11, the SiC-epitaxial growth layer (SiC-epi) 13 disposed above the SiC single crystal substrate 11 with the graphene layer 12 therebetween, and the stress layer 14 disposed on the Si surface of the SiC-epitaxial growth layer 13. The stress layer 14 generates a stress between the graphene layer 12 and SiC-epitaxial growth layer 13 and facilitates detachment between the graphene layer 12 and SiC-epitaxial growth layer 13.

The stress layer 14 is constituted by a carbon film or a silicon nitride film. The carbon film is constituted by a polycrystalline diamond film or a diamond-like carbon film. The stress generated by the internal stress of the stress layer 14 is adjusted to approximate the adhesion energy between the graphene layer 12 and SiC-epitaxial growth layer 13. Further, the stress generated by the stress layer depends on a stacked structure of the SiC single crystal substrate 11, the graphene layer 12, the SiC-epitaxial growth layer 13, the stress layer 14, and the adhesive layer 15 and a temporary substrate 19 which will be described later. The stress layer 14 is formed of a specific material such as a silicon nitride film or a carbon film constituted by a polycrystalline diamond film or a diamond carbon film, and film formation conditions such as a film thickness and film formation temperature are adjusted to appropriately set the internal stress in the stress layer 14. This facilitates detachment between the graphene layer 12 and SiC-epitaxial growth layer 13.

The semiconductor substrate according to the first embodiment may further include the graphite substrate 19 as a temporary substrate disposed on the stress layer 14 as shown in FIG. 11. The graphite substrate 19 has an external size one size larger than that of the SiC single crystal substrate 11. The graphite substrate 19 is connected to the stress layer 14 with the adhesive layer 15 using the carbon adhesive therebetween. The carbon adhesive contains phenolic resin, and can maintain bonding force thereof even at a high temperature due to the adhesive itself being carbonized.

The graphite substrate 19 may have a glassy carbon film on a surface thereof. Since adhesion force between the glassy carbon film and the carbon adhesive is strong, the SiC-epitaxial growth layer 13 can be easily detached from the graphene layer 12 and SiC single crystal substrate 11. The semiconductor substrate according to the first embodiment may have a structure in which the semiconductor substrate shown in FIG. 12A is arranged on both sides of the graphite substrate 19 as shown in FIG. 13.

As shown in FIG. 14, the semiconductor substrate according to the first embodiment may have the SiC polycrystalline growth layers 16 formed on the C surfaces of the SiC-epitaxial growth layers 131 and 132. The SiC-epitaxial growth layers 131 and 132 are transferred to the SiC polycrystalline growth layers 16. Further, as shown in FIG. 19, in the SiC-epitaxial growth layer 13, the highly doped layer 13a may be formed toward the C surface of the SiC-epitaxial growth layer 13 in contact with the SiC polycrystalline growth layer 16. As shown in FIG. 6, the graphene layer 12 may have a stacked structure, may be a zeroth layer as a buffer layer, or may have a single layer structure.

### Semiconductor Element

The SiC composite substrate 10 is fabricated by performing the method for manufacturing a semiconductor substrate according to the first embodiment, or the SiC composite substrate 10 is fabricated from the semiconductor substrate according to the first embodiment, for example, and the SiC composite substrate 10 can be used for the manufacture of various kinds of SiC-based semiconductor elements. Examples thereof include a SiC-SBD, a SiC trench gate (T: Trench) TMOSFET, and a SiC planar gate MOSFET.

### SiC-SBD

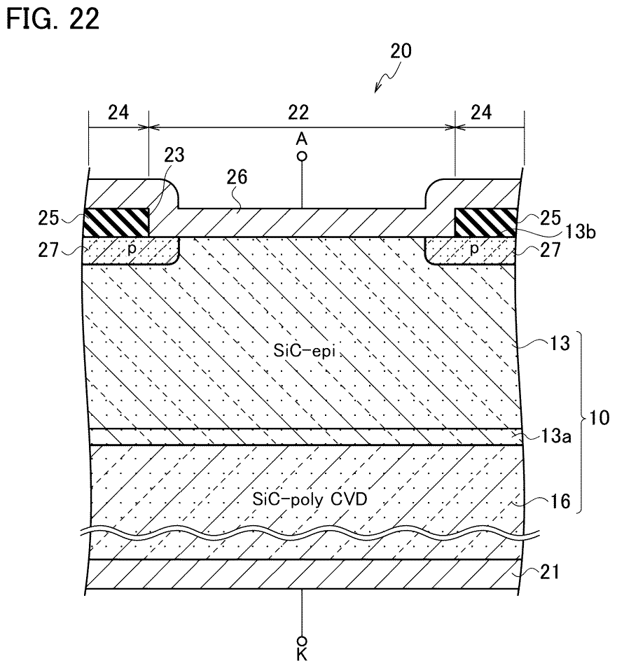

As the semiconductor device fabricated using the SiC composite substrate, a SiC-SBD 21 includes the SiC composite substrate 10 having the SiC polycrystalline growth layer (SiC-poly CVD) 16 and the SiC-epitaxial growth layer (SiC-epi) 13, as shown in FIG. 22. The highly doped layer 13a may be interposed between the SiC polycrystalline growth layer 16 and the SiC-epitaxial growth layer 13. By means of the highly doped layer 13a, it is possible to suppress the spread of a depletion layer in the SiC-epitaxial growth layer 13, and easily form an ohmic contact with the SiC polycrystalline growth layer 16 formed on the C surface of the SiC-epitaxial growth layer 13. The SiC-epitaxial growth layer 13 serves as a drift layer, the highly doped layer 13a serves as a buffer layer, and the SiC polycrystalline growth layer 16 serves as a substrate layer.

The SiC polycrystalline growth layer 16 is doped in an n+ type (impurity density is from about 1×10¹⁸ cm⁻³ to about 1×10²¹ cm⁻³, for example), and the SiC-epitaxial growth layer 13 is doped in an n-type (impurity density is from about 5× 10¹⁴ cm⁻³ to about 5×10¹⁶ cm⁻³, for example). The highly doped layer 13a is doped at a higher concentration than the SiC-epitaxial growth layer 13.

Further, the SiC-epitaxial growth layer 13 may have a crystal structure of any one of 4H—SiC, 6H—SiC, and 2H—SiC.

As an n-type doping impurity, N (nitrogen), P (phosphorus), As (arsenic), and the like may be applied, for example.

As a p-type doping impurity, B (boron), Al (aluminum), and the like may be applied.

A cathode electrode 21 is disposed on a back surface ((000-1) C surface) of the SiC polycrystalline growth layer 16 so as to cover the entire area thereof, and the cathode electrode 21 is connected to a cathode terminal K.

Further, a contact hole 23 is formed in a front surface 13b (for example, (0001) Si surface) of the SiC-epitaxial growth layer 13, the contact hole 23 being for exposing a part of the SiC-epitaxial growth layer 13 as an active region 22, and a field insulating film 25 is formed in a field region 24 surrounding the active region 22.

The field insulating film 25 is made of SiO₂ (silicon oxide), but may be made of other insulating material such as silicon nitride (SiN). An anode electrode 26 is formed on the field insulating film 25, and the anode electrode 26 is connected to an anode terminal A.

A p-type Junction Termination Extension (JTE) structure 27 is formed in the vicinity of the front surface 13b of the SiC-epitaxial growth layer 13 (surface layer) so as to be contacted with the anode electrode 26. The JTE structure 27 is formed along an outline of the contact hole 23 of the field insulating film 25 so as to extend from the outside to inside of the contact hole 23.

### SiC-TMOSFET

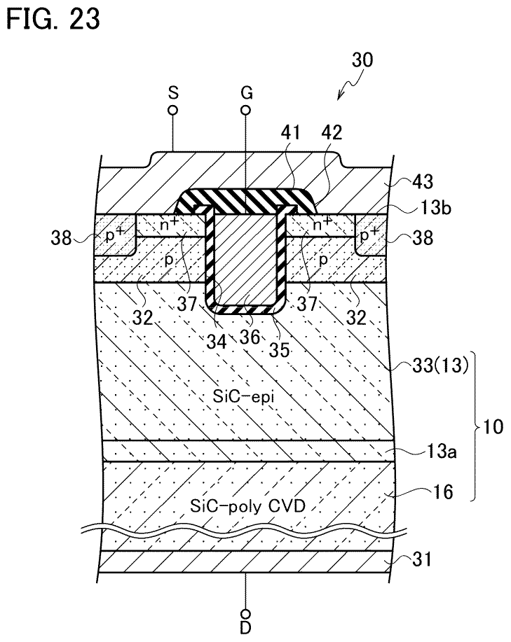

As a semiconductor device fabricated using the SiC composite substrate 10 according to the first embodiment, a trench gate TMOSFET 30 includes the SiC composite substrate 10 having the SiC polycrystalline growth layer 16 and SiC-epitaxial growth layer 13, as shown in FIG. 23. The highly doped layer 13a may be interposed between the SiC polycrystalline growth layer 16 and SiC-epitaxial growth layer 13. By means of the highly doped layer 13a, it is possible to suppress the spread of a depletion layer in the SiC-epitaxial growth layer 13, and easily form the ohmic contact with the SiC polycrystalline growth layer 16 formed on the C surface of the SiC-epitaxial growth layer 13. The SiC-epitaxial growth layer 13 serves as a drift layer, the highly doped layer 13a serves as a buffer layer, and the SiC polycrystalline growth layer 16 serves as a substrate layer.

The SiC polycrystalline growth layer 16 is doped in an n+ type (impurity density is from about 1×10¹⁸ cm⁻³ to about 1×10²¹ cm⁻³, for example), and the SiC-epitaxial growth layer 13 is doped in an n-type (impurity density is from about 5×10¹⁴ cm⁻³ to about 5×10¹⁶ cm⁻³, for example). The highly doped layer 13a is doped at a higher concentration than the SiC-epitaxial growth layer 13.

Further, the SiC-epitaxial growth layer 13 may have a crystal structure of any one of 4H—SiC, 6H—SiC, and 2H—SiC.

As an n-type doping impurity, N (nitrogen), P (phosphorus), As (arsenic), and the like may be applied, for example.

As a p-type doping impurity, B (boron), Al (aluminum), and the like may be applied, for example.

A drain electrode 31 is disposed on the back surface ((000-1) C surface) of the SiC polycrystalline growth layer 16 so as to cover the entire area thereof, and the drain electrode 31 is connected to a drain terminal D.

A p-type (impurity density is from about 1×10¹⁶ cm⁻³ to about 1×10¹⁹ cm⁻³, for example) body region 32 is formed in the vicinity of the front surface 13b ((0001) Si surface) of the SiC-epitaxial growth layer 13 (surface layer). A portion of the SiC-epitaxial growth layer 13 which is closer to the SiC polycrystalline growth layer 16 than the body region 32 is an n-type drain region 33 (13) in which a state of the SiC-epitaxial growth layer 13 is maintained without any changes.

A gate trench 34 is formed in the SiC-epitaxial growth layer 13. The gate trench 34 passes through the body region 32 from the front surface 13b of the SiC-epitaxial growth layer 13, and a deepest part thereof reaches the drain region 33 (13).

A gate insulating film 35 is formed on an inner surface of the gate trench 34 and the front surface 13b of the SiC-epitaxial growth layer 13 so as to cover the entire area of the inner surface of the gate trench 34. A gate electrode 36 is buried in the gate trench 34 by filling the inner side of the gate insulating film 35 with polysilicon, for example. A gate terminal G is connected to the gate electrode 36.

An n+ type source region 37 forming a part of a side surface of the gate trench 34 is formed at the surface layer of the body region 32.

Further, a p+ type (impurity density is from about 1×10¹⁸ cm⁻³ to about 1×10²¹ cm⁻³, for example) body contact region 38 is formed in the SiC-epitaxial growth layer 13, the body contact region 38 passing through the source region 37 from the front surface 13b and being connected to the body region 32.

An interlayer insulating film 41 made of SiO₂ is formed at the SiC-epitaxial growth layer 13. A source electrode 43 is connected to the source region 37 and body contact region 38 through a contact hole 42 formed in the interlayer insulating film 41. A source terminal S is connected to the source electrode 43.

By applying a prescribed voltage (voltage equal to or greater than gate threshold voltage) to the gate electrode 36 while a prescribed potential difference is generated between the source electrode 43 and drain electrode 31 (between source and drain), a channel can be formed in the vicinity of an interface with the gate insulating film 35 in the body region 32 by an electric field from the gate electrode 36. As a result, a current can flow between the source electrode 43 and the drain electrode 31, and a SiC-TMOSFET 31 can be turned on.

### SiC Planar Gate MOSFET

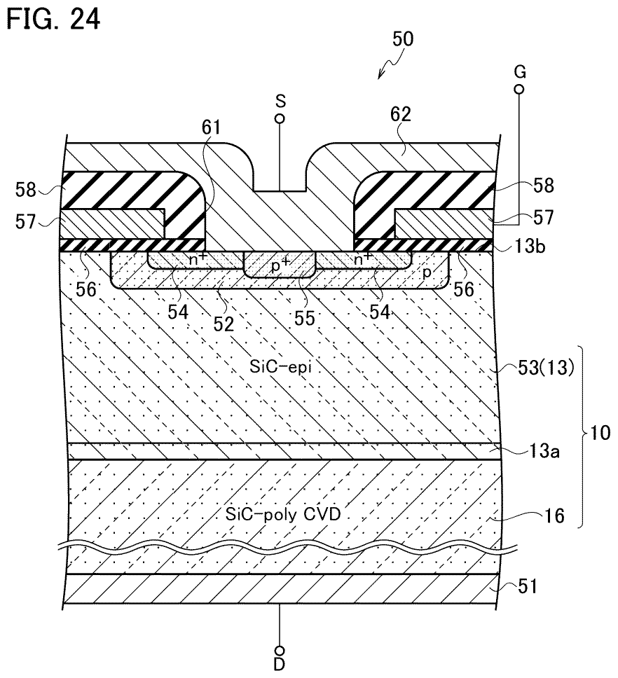

As a semiconductor device fabricated using the SiC composite substrate 10, a planar gate MOSFET 50 includes the SiC composite substrate 10 having the SiC polycrystalline growth layer 16 and SiC-epitaxial growth layer 13, as shown in FIG. 24. The highly doped layer 13a may be interposed between the SiC polycrystalline growth layer 16 and SiC-epitaxial growth layer 13. By means of the highly doped layer 13a, it is possible to suppress the spread of a depletion layer in the SiC-epitaxial growth layer 13, and easily form an ohmic contact with the SiC polycrystalline growth layer 16 formed on the C surface of the SiC-epitaxial growth layer 13. The SiC-epitaxial growth layer 13 serves as a drift layer, the highly doped layer 13a serves as a buffer layer, and the SiC polycrystalline growth layer 16 serves as a substrate layer.

The SiC polycrystalline growth layer 16 is doped in an n+ type (impurity density is from about 1×10¹⁸ cm⁻³ to about 1×10²¹ cm⁻³, for example), and the SiC-epitaxial growth layer 13 is doped in an n-type (impurity density is from about 5×10¹⁴ cm⁻³ to about 5×10¹⁶ cm⁻³, for example).

Further, the SiC-epitaxial growth layer 13 may have a crystal structure of any one of 4H—SiC, 6H—SiC, and 2H—SiC.

As an n-type doping impurity, N (nitrogen), P (phosphorus), As (arsenic), and the like may be applied, for example.

As a p-type doping impurity, B (boron), Al (aluminum), and the like may be applied, for example.

A drain electrode 51 is formed on the back surface ((000-1) C surface) of the SiC composite substrate 10 so as to cover the entire area thereof, and the drain terminal D is connected to the drain electrode 51.

A p-type (impurity density is from about 1×10¹⁶ cm⁻³ to about 1×10¹⁹ cm⁻³, for example) body region 52 is formed in a well shape in the vicinity of the front surface 13b ((0001) Si surface) of the SiC-epitaxial growth layer 13 (surface layer). A portion of the SiC-epitaxial growth layer 13 closer to the SiC composite substrate 10 than the body region 52 is an n-type drain region 53 (13) in which a state after epitaxial growth is maintained without any changes.

At a surface layer of the body region 52, an n+ type source region 54 is formed by being spaced apart from a peripheral edge of the body region 52.

A p+ type (impurity density is from about 1×10¹⁸ cm⁻³ to about 1×10²¹ cm⁻³, for example) body contact region 55 is formed on an inner side of the source region 54. The body contact region 55 passes through the source region 54 in a depth direction and is connected to the body region 52.

A gate insulating film 56 is formed on the front surface 13b of the SiC-epitaxial growth layer 13. The gate insulating film 56 covers a portion of the body region 52 surrounding the source region 54 (peripheral edge of body region 52) and an outer peripheral edge of the source region 54.

A gate electrode 57 made of polysilicon is formed on the gate insulating film 56, for example. The gate electrode 57 faces the peripheral edge of the body region 52 with the gate insulating film 56 therebetween. The gate terminal G is connected to the gate electrode 57.

An interlayer insulating film 58 made of SiO₂ is formed on the SiC-epitaxial growth layer 13. A source electrode 62 is connected to the source region 54 and body contact region 55 through a contact hole 61 formed in the interlayer insulating film 58. The source terminal S is connected to the source electrode 62.

By applying a prescribed voltage (voltage equal to or greater than gate threshold voltage) to the gate electrode 57 while a prescribed potential difference is generated between the source electrode 62 and drain electrode 51 (between source and drain), a channel can be formed in the vicinity of an interface with the gate insulating film 56 in the body region 52 by an electric field from the gate electrode 57. As a result, a current can flow between the source electrode 62 and drain electrode 51, and the planar gate MOSFET 50 can be turned on.

As described above, according to the first embodiment, by separating the SiC single crystal substrate 11 and replacing the substrate with the temporary substrate as the highly heat-resistant graphite substrate 19 before forming the SiC polycrystalline growth layer 16 by means of CVD, unnecessary adhesion of the polycrystalline SiC to the SiC single crystal substrate 11 can be prevented, and the reusability of the SiC single crystal substrate 11 can be maximized, thereby further reducing the cost.

According to the first embodiment, due to the stress layer 14 being constituted by a carbon-based film (polycrystalline diamond film or diamond-like carbon film) or a silicon nitride film, the SiC-epitaxial growth layer 13 is made easy to be detached from the graphene layer 12 by using the film internal stress and thermal stress. This can avoid metal contamination, which becomes a problem when a metal stressor film is used. The formation of the carbon-based film or silicon nitride film has the advantage of good adhesion with a substrate, excellent high heat resistance, and acquisition of a large stress.

According to the first embodiment, by making the graphite substrate 19 one size larger than the SiC single crystal substrate 11, epitaxial growth on one or both sides is possible using an epitaxial growth apparatus such as a vertical batch tubular furnace, and high-throughput and low-cost production can be realized without forcibly increasing a growth rate. Further, the graphite substrate 19 and carbonized adhesive layer 15 can be removed at a low-cost by simply firing in an oxidation furnace or the like.

According to the first embodiment, the remote epitaxial growth of SiC is performed through graphene formed on the SiC single crystal substrate, and the SiC polycrystalline growth layer is directly formed thereon by means of a CVD method, and therefore substrate bonding is unnecessary, and a defect caused by the substrate bonding can be eliminated. In addition, since the epitaxial growth layer is formed through graphene, the separation between the SiC single crystal substrate and epitaxial growth layer becomes easy, a process step becomes simple, and an expensive process such as an ion implantation separation method becomes unnecessary.

According to the first embodiment, after the SiC single crystal substrate is removed, an entire handle substrate with high heat resistance is put in a high-temperature LP-CVD apparatus, and the SiC polycrystalline growth layer is directly grown on the epitaxial growth layer. This eliminates a step of transporting an epitaxial growth layer having a thickness of several μm from the handle substrate to a support substrate, and a step of bonding with the support substrate, and accordingly it is possible to avoid faults such as creases, crystal transitions, and voids caused by thin film transport and bonding.

According to the first embodiment, the graphene layer formed on the SiC single crystal substrate 11 is not transferred, but the epitaxial growth is performed thereon without any changes. This can avoid faults such as creases and cracks caused by the transfer of graphene.

According to the first embodiment, the SiC single crystal substrate 11 is used as a base, and therefore the hexagonal SiC with less decrease in crystallinity can be obtained. In addition, although the SiC single crystal substrate 11 is expensive and removal thereof by means of polishing or etching is difficult, by means of remote epitaxial growth through the graphene layer 12, the obtained SiC-epitaxial growth layer 13, which is a high performance single crystal, can be easily separated, and necessity of removal by means of polishing or etching is eliminated. Since the expensive SiC single crystal substrate 11 can be reused after separation, a large advantage in cost can be obtained.

Although the first embodiment has been described above, the invention can be carried out in other ways. Although not shown in the diagrams, a MOS capacitor can be manufactured using the SiC composite substrate 10, for example. The yield and reliability can be enhanced in manufacturing of the MOS capacitor.

Further, although not shown in the diagrams, a bipolar transistor can be manufactured using the SiC composite substrate 10. In addition, the SiC composite substrate 10 according to the first embodiment can be used for manufacturing a SiC-pn diode, SiCIGBT, SiC complementary MOSFET, and the like. The SiC composite substrate 1 can also be applied to other types of devices such as a light emitting diodes (LED) and a Semiconductor Optical Amplifier (SOA), for example.

The SiC-epitaxial growth layer 13 may have at least one or more types selected from a group of an IV group element semiconductor, a III-V group compound semiconductor, and a II-VI group compound semiconductor.

Further, the SiC composite substrate 10 and SiC-epitaxial growth layer 13 may be made of a material of any one of 4H—SiC, 6H—SiC, and 2H—SiC.

Further, the SiC single crystal substrate 11 and SiC-epitaxial growth layer 13 may have at least one type selected from a group of GaN, BN, AlN, Al₂O₃, Ga₂O₃, diamond, carbon, and graphite as another material system other than SiC.

The semiconductor device having the SiC composite substrate 10 may include any one of a GaN-based, AlN-based, and gallium oxide-based IGBT, diode, MOSFET, and thyristor as a component other than a SiC-based component.

The semiconductor device having the SiC composite substrate 10 may have a structure of any one of 1-in-1 module, 2-in-1 module, 4-in-1 module, 6-in-1 module, 7-in-1 module, 8-in-1 module, 12-in-1 module, and 14-in-1 module.

According to the SiC composite substrate 10, as a substrate material, a low-cost SiC polycrystalline growth layer 16 can be used instead of a high-cost SiC single crystal substrate 11, for example.

### Second Embodiment

Next, a second embodiment will be described. The second embodiment uses a method for remote epitaxial that enables the detachment of a SiC-epitaxial growth layer transferred through a graphene layer by forming the SiC-epitaxial growth layer on a surface of a SiC single crystal substrate as a seed crystal with the graphene layer therebetween.

### Method for Manufacturing Semiconductor Substrate

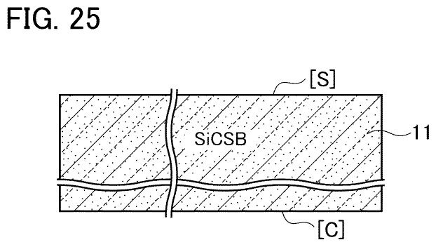

FIG. 25 is a cross-sectional view of a SiC single crystal substrate (SiCSB) 11 as a seed substrate. In the second embodiment, an example will be described in which the SiC single crystal substrate 11 is a 4H—SiC substrate, but the substrate may be either a hexagonal system (4H, 6H) or a cubic system (3C). A thickness of the SiC single crystal substrate 11 may be about 300 μm to 600 μm, for example. In FIG. 25, [C] indicates a C surface of SiC, and [S] indicates a Si surface of SiC. The same applies in the diagrams described below.

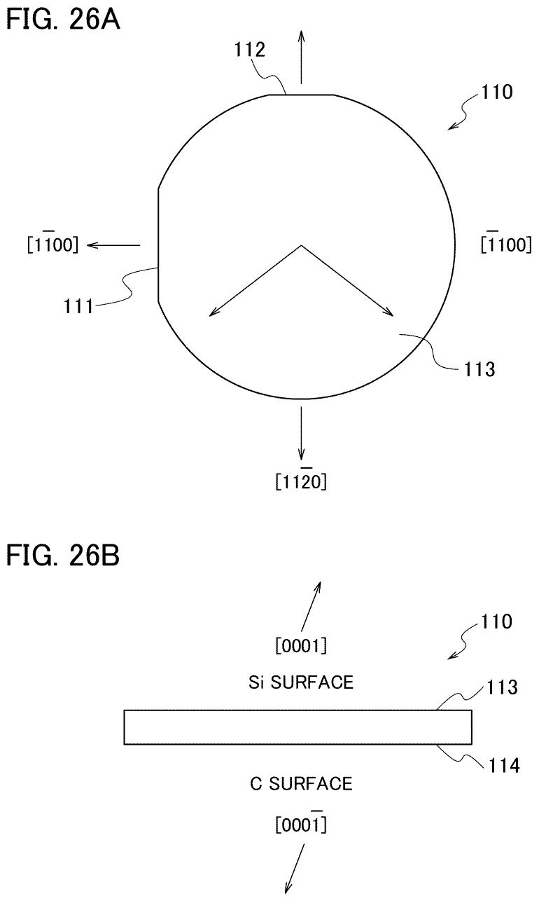

FIGS. 26A and 26B are diagrams for explaining a crystal plane of a SiC wafer 110 applicable as the SiC single crystal substrate 11. A plan view of FIG. 26A shows a Si surface 113 of the SiC wafer 110 to which a primary orientation flat 111 and a secondary orientation flat 112 are formed. In a side view of FIG. 26B, viewed from an orientation of [−1100], a Si surface 113 with an orientation of [0001] is formed on an upper surface, and a C surface 114 with an orientation of [000-1] is formed on a lower surface.

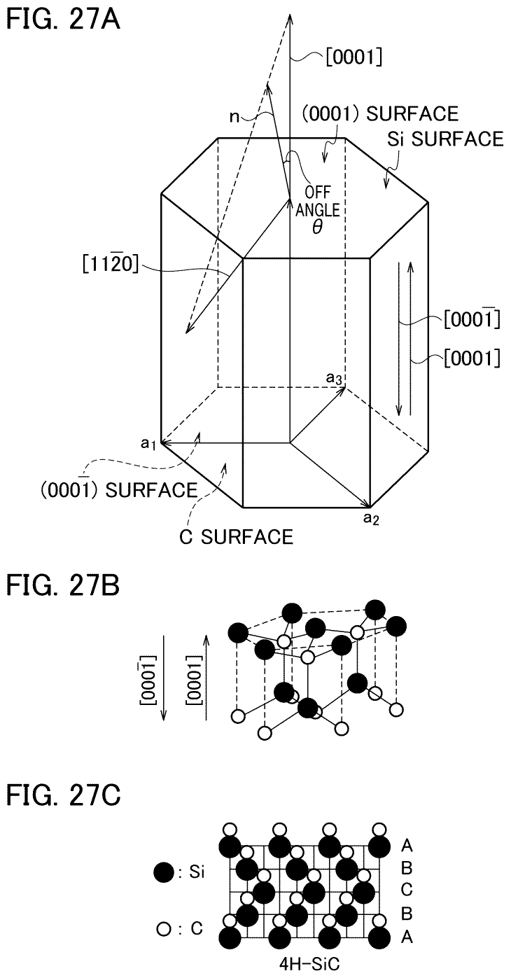

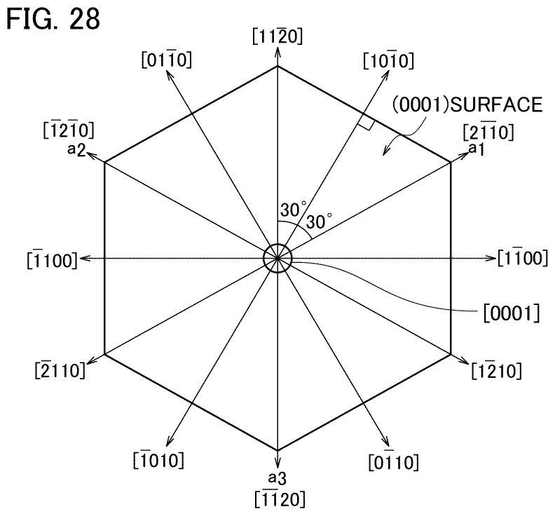

A schematic bird's eye view structure of a unit cell of a 4H—SiC crystal is represented as shown in FIG. 27A, a schematic structure of a two-layer portion of the 4H—SiC crystal is represented as shown in FIG. 27B, and a schematic structure of a four-layer portion of the 4H—SiC crystal is represented as shown in FIG. 27C. Further, a schematic structure of the unit cell of the 4H—SiC crystal structure shown in FIG. 27A viewed from directly above a (0001) surface is represented as shown in FIG. 28.

As shown in FIGS. 27A to 27C, the 4H—SiC crystal structure can be approximated with a hexagonal system, and four C atoms are bonded to one Si atom. The four C atoms are positioned at four vertices of a regular tetrahedron with the Si atom disposed at a center thereof. Regarding the four C atoms, one Si atom is positioned on a axial direction relative to the C atom, and other three C atoms are positioned on a [000-1] axis side relative to the Si atom. In FIG. 27A, an off angle θ is about 4 degrees or less, for example.

The [0001] axis and [000-1] axis are along an axial direction of a hexagonal prism, and a surface (top surface of hexagonal prism) of which normal line is the [0001] axis is a (0001) surface (Si surface). Meanwhile, a surface (bottom surface of hexagonal prism) of which normal line is the [000-1] axis is a (000-1) surface (C surface). Directions perpendicular to the [0001] axis and passing non-adjacent vertices of the hexagonal prism when viewed from directly above the (0001) surface are an a1 axis [Feb. 1, 2010], an a2 axis [−12-10], and an a3 axis [−1-120].

As shown in FIG. 28, a direction passing through a vertex between the a1 and a2 axes is a [11-20] axis, a direction passing through a vertex between the a2 and a3 axes is a [−2110] axis, and a direction passing through a vertex between the a3 and a1 axes is a [1-210] axis. Axes each of which is positioned between two of the above six axes passing through each vertex of the hexagonal prism, is inclined at an angle of 30 degrees relative to the two axes on both sides, and serves as a normal line of each side surface of the hexagonal prism are, a [10-10] axis, a [1-100] axis, a [0-110] axis, a [−1010] axis, a [−1100] axis, and a [01-10] axis, in a clockwise direction sequentially from between the a1 and [11-20] axes. Each surface of which normal lines are these axes (side surface of hexagonal prism) is a crystal plane perpendicular to the (0001) surface and (000-1) surface.

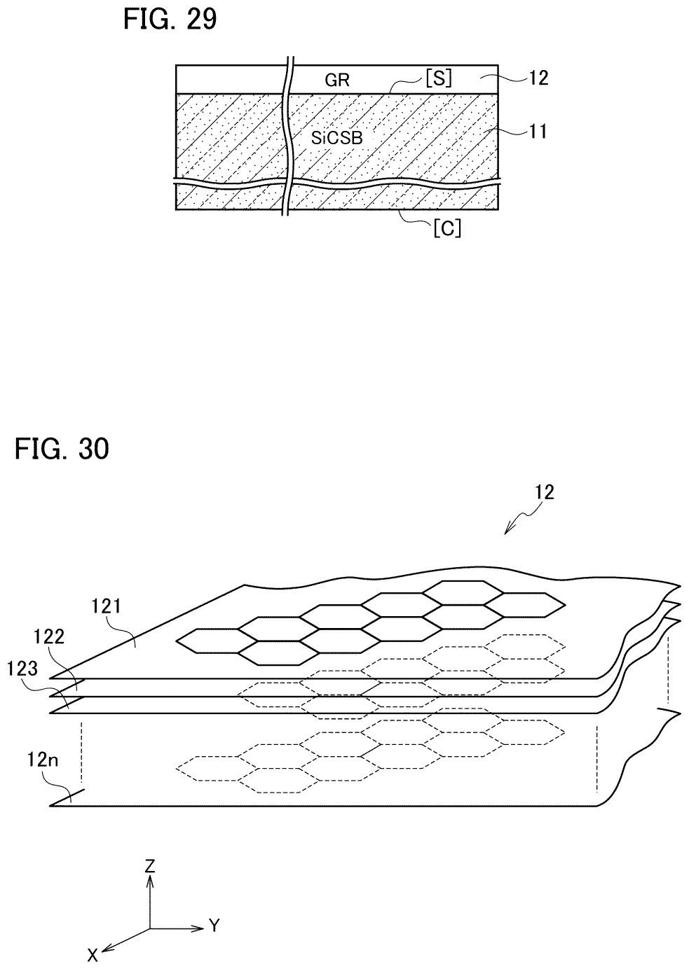

Next, as shown in FIG. 29, a first graphene layer (GR) 12 up to several molecular layers is formed on a (0001) Si surface of the SiC single crystal substrate 11. The first graphene layer 12 can be formed on the Si surface of the SiC single crystal substrate 11 by means of thermal decomposition by annealing the SiC single crystal substrate 11 at about 1700° C. in an atmospheric pressure argon gas atmosphere, for example. Further, the first graphene layer 12 may be stacked on the SiC single crystal substrate 11 by means of CVD.

The first graphene layer 12 is represented as shown in FIG. 30. The first graphene layer 12 has a stacked structure of graphite sheets 121, 122, 123, . . . 12n. The n-layered graphite sheets 121, 122, 123, . . . 12n on each surface have covalent bonds of many hexagonal system carbons (C) in one stacked crystal structure, and the graphite sheets 121, 122, 123, . . . 12n on each surface are bonded by means of van der Waals force. The first graphene layer 12 may be a zeroth layer as a buffer layer or may have a single layer structure.

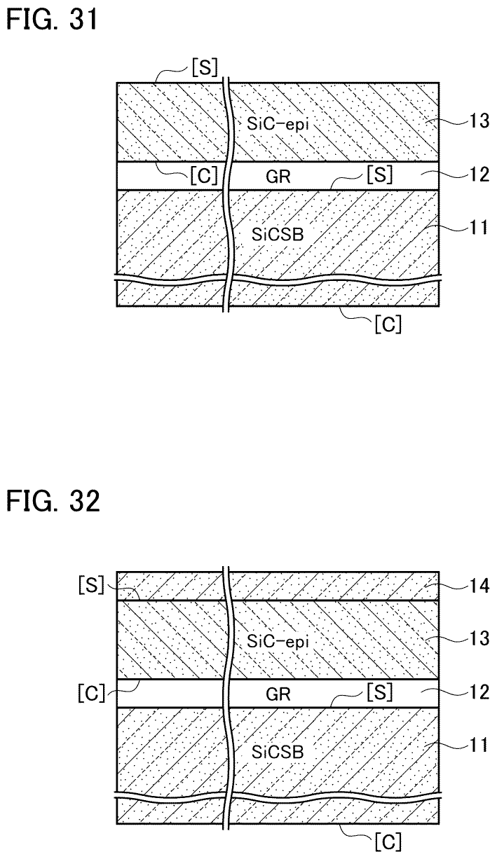

As shown in FIG. 31, a SiC-epitaxial growth layer (SiC-epi) 13 is formed on the first graphene layer 12. The SiC-epitaxial growth layer 13 is formed on the first graphene layer 12 which has been formed on the Si surface of the SiC single crystal substrate 11 by means of a method for remote epitaxial growth. The SiC-epitaxial growth layer 13 is a single crystal SiC thin film. A surface of the SiC-epitaxial growth layer 13 in contact with the first graphene layer 12 becomes the C surface, and the remaining surface of the SiC-epitaxial growth layer 13 becomes the Si surface.

As shown in FIG. 32, a stress layer 14 is formed on the SiC-epitaxial growth layer 13. The stress layer 14 is constituted by a nickel (Ni) thin film. The nickel thin film may be formed by means of vapor deposition or plating. The stress layer 14 generates a stress between the first graphene layer 12 and SiC-epitaxial growth layer 13 by an internal stress or the like thereof in the layer to facilitate detachment between the first graphene layer 12 and SiC-epitaxial growth layer 13.

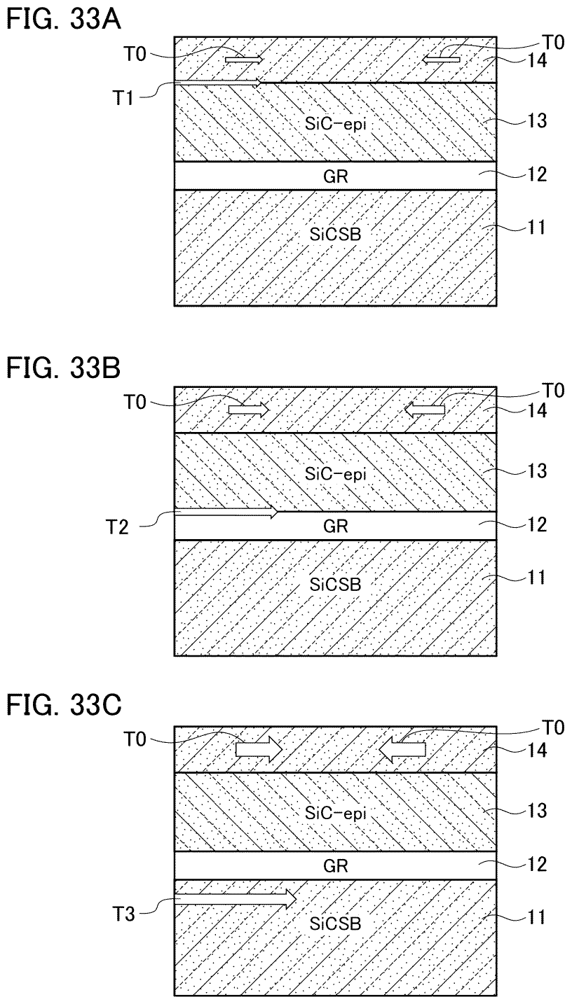

A mechanism by which the stress layer 14 generates a stress will be described with reference to FIGS. 33A to 33C. In examples shown in FIGS. 33A to 33C, an internal stress TO of the stress layer is a tensile stress, and the magnitude of the internal stress TO gradually increases as the process proceeds from FIG. 33A, FIG. 33B, FIG. 33C in this order. In accordance with an increase in the internal stress TO, an aspect proceeds from a detachment at an interface between the stress layer 14 and SiC-epitaxial growth layer 13 shown in FIG. 33A to a detachment at an interface between the SiC-epitaxial growth layer 13 and first graphene layer 12 shown in FIG. 33B, and from the detachment shown in FIG. 33B to the breakage in the SiC single crystal substrate 11 shown in FIG. 33C. The appropriate adjustment of the internal stress TO of the stress layer enables detachment at the interface between the SiC-epitaxial growth layer 13 and first graphene layer 12 as shown in FIG. 33B.

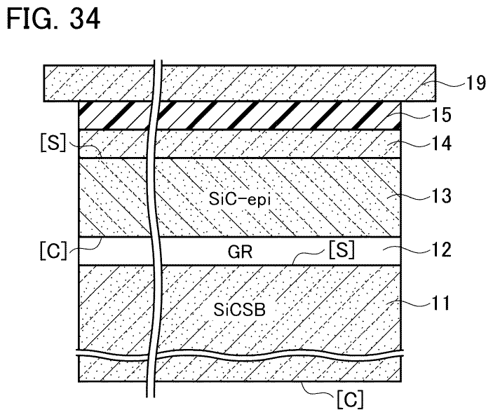

Next, as shown in FIG. 34, an adhesive layer 15 is formed on the stress layer 14, a coated surface of the adhesive layer 15 is stacked and attached on one or both sides of a graphite substrate 19 as a temporary substrate of which external size is one size larger than that of the SiC single crystal substrate 11, and a first composite (11 (SiCSB), 12 (GR), 13 (SiC-epi), 14, 15, and 19) is formed. A carbon adhesive may be used for the adhesive layer 15, for example. The carbon adhesive contains phenolic resin, and can maintain bonding force thereof even at a high temperature due to the adhesive itself being carbonized. The graphite substrate 19 may be in the shape of a circular plate or a rectangular plate, and as the graphite substrate 19 of which external size is one size larger, it is sufficient if the eternal size thereof is 1 mm or more larger than that of the SiC single crystal substrate 11. If a diameter of the SiC single crystal substrate 11 is about 10 cm, the graphite substrate 19 having a diameter of about 11 cm, of which external size is about 10 mm larger than that of the SiC single crystal substrate 11 may be used, for example. If a diameter of the SiC single crystal substrate 11 is about 15 cm, the graphite substrate 19 of which external size has a diameter of about 16 cm may be used, for example.

The adhesive layer 15 is carbonized by heating the first composite in an inert gas atmosphere in a thermal annealing furnace or the like. At this time, an adhesive surface is prevented from being detached when the adhesive layer 15 is carbonized by gradually heating the first composite at a temperature gradient such that gas generated when the carbon adhesive of the adhesive layer 15 is decomposed can be desorbed slowly. The graphite substrate 19 may have a glassy carbon film on a surface thereof. Since adhesion force between the glassy carbon film and the carbon adhesive of the adhesive layer 15 is strong, the SiC-epitaxial growth layer 13 can be easily detached from the first graphene layer 12 and SiC single crystal substrate 11, and a yield can be enhanced. Although FIG. 34 shows an example in which the first composite is formed by attaching the adhesive layer 15 to one side of the graphite substrate 19, the first composite may be formed by attaching the adhesive layer 15 to both sides of the graphite substrate 19.

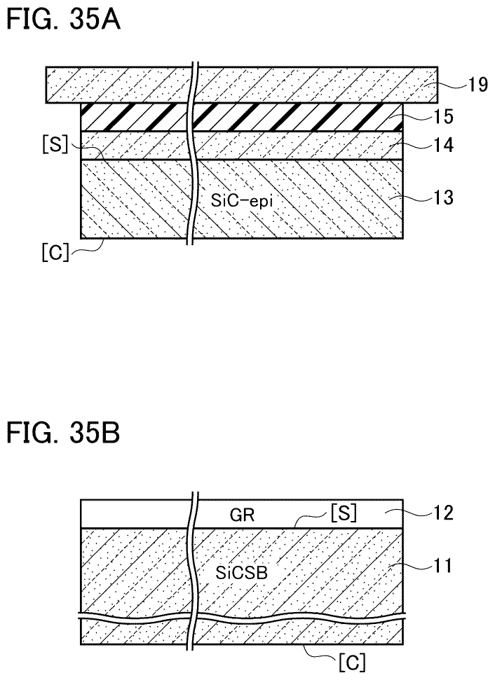

As shown in FIG. 35, after carbonizing the first composite shown in FIG. 34, the SiC-epitaxial growth layer 13 is physically detached and separated from the first graphene layer 12 at an interface thereof on one or both sides of the first composite by using an adhesive detaching tape, debonder equipment, or the like. FIG. 35A is a cross-sectional view of a structure detached on the SiC-epitaxial growth layer 13 side from the first composite shown in FIG. 34, and FIG. 35B is a cross-sectional view of a structure detached on the graphene layer 12 side. The structure detached on the SiC-epitaxial growth layer 13 side shown in FIG. 35A forms a second composite (13 (SiC-epi), 14, 15, and 19). The first graphene layer 12 is bonded by means of van der Waals force, the stress generated by the stress layer 14 is adjusted to have a magnitude that facilitates detachment between the first graphene layer 12 and SiC-epitaxial growth layer 13, and therefore the first graphene layers 12 and SiC-epitaxial growth layer 13 can be easily detached at the interface thereof by applying force in a shear direction.

In the structure detached on the first graphene layer 12 side shown in FIG. 35B, the first graphene layer 12 on the SiC single crystal substrate 11 is removed by means of etching or polishing. In a step of etching the first graphene layer 12, a plasma usher with oxygen plasma can be applied, for example. The Si surface of the SiC single crystal substrate 11 with the first graphene layer 12 thereon being etched with oxygen plasma, is subjected to wet etching with hydrogen fluoride (HF), because a surface thereof is oxidized. Further, in a step of polishing the first graphene layer 12, the first graphene layer 12 is removed by means of Chemical Mechanical Polishing (CMP), for example. An average surface roughness Ra of the Si surface of the SiC single crystal substrate 11 by the wet etching step described above is, for example, about 1 nm or less. As a result, the SiC single crystal substrate 11 can be reused.

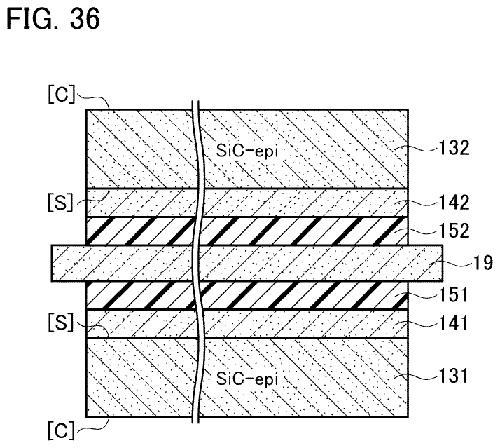

FIG. 36 shows an example in which the detachment structure of FIG. 35A is attached on both sides of the graphite substrate 19 and SiC-epitaxial growth layers 131 and 132 are formed on both sides. In this case, the second composite (131 (SiC-epi), 141, 151, 19, 152, 142, and 132 (SiC-epi)) is heated in a thermal annealing furnace to form carbonized adhesive layers 151 and 152.

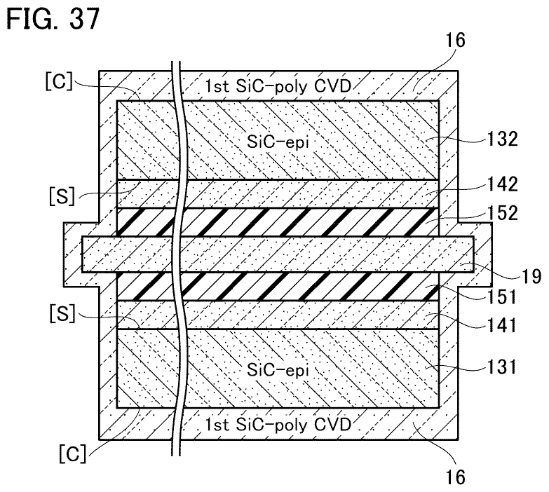

As shown in FIG. 37, first, SiC polycrystalline growth layers 16 are formed on (000-1) C surfaces of the SiC-epitaxial growth layers 131 and 132 formed on one or both sides of the second composite. Each first SiC polycrystalline growth layer 16 can be formed by means of a CVD technique. After the second composite is installed in a CVD furnace, vacuum drawing is performed and the composite is heated to about 1400° C. to 1500° C. Then, SiCl₄ (silicon tetrachloride) gas, CH₄ (methane) gas, and H₂ (hydrogen) gas as material gas is simultaneously flown, the pressure is adjusted, and each first SiC polycrystalline growth layer 16 is deposited, for example. Each first SiC polycrystalline growth layer 16 has a 3C (cubic) structure. The temporary substrate (graphite substrate 19) which is one size larger than the SiC single crystal substrate 11 has the advantage of setting strut marks on a wafer boat outside a substrate effective area when inserted into a wafer boat groove in a vertical batch CVD furnace and aligned.

A thickness of each first SiC polycrystalline growth layer 16 is set to a thickness of a SiC composite substrate to be thinned. When a thickness of an entire wafer that has been thinned is 100 μm, and if a thickness of the SiC-epitaxial growth layer 13 is 10 μm, a bulk thickness of a first polycrystalline SiC bulk layer is 90 μm, for example.

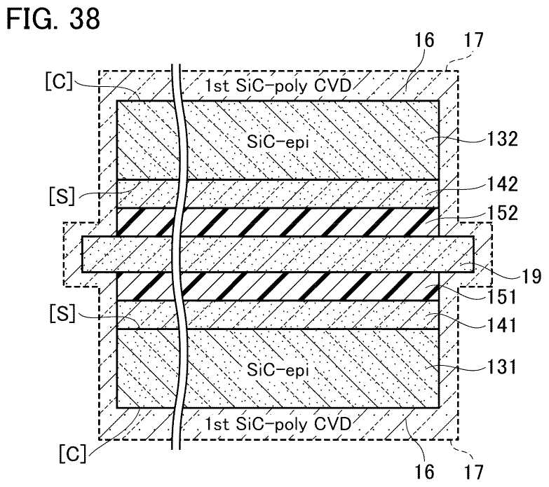

As shown in FIG. 38, second graphene layers (GR) 17 up to several molecular layers are formed on the (000-1) C surfaces of the SiC-epitaxial growth layers 131 and 132 of the second composite, on which the first SiC polycrystalline growth layers 16 are formed. The second graphene layers 17 may be stacked by means of CVD or may be formed by means of a thermal decomposition method. If the layers are formed by means of the thermal decomposition method, the second composite in which the first SiC polycrystalline growth layers 16 are deposited is installed in a thermal annealing furnace, and an atmospheric component is sufficiently removed by performing high vacuum drawing until the pressure is about 1×10⁻⁵ pascals, for example. Thereafter, high purity argon gas of about 6 N is introduced thereto, the pressure is adjusted from 5×10⁻⁵ pascals to 1×10⁺⁵ pascals, then the second composite is heated to a range from 1250° C. to 1750° C., and the second graphene layers 17 are formed on surfaces of the first SiC polycrystalline growth layers 16. Similar to the first graphene layer 12 shown in FIG. 30, each second graphene layer 17 has a stacked structure of graphite sheets, and graphite sheets on each surface are bonded by means of van der Waals force. Each second graphene layer 17 may be a zeroth layer as a buffer layer or may have a single layer structure.

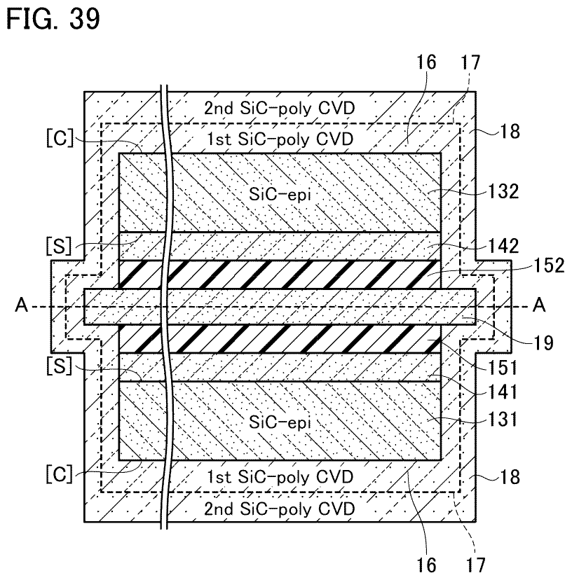

As shown in FIG. 39, a second SiC polycrystalline growth layer 18 is further formed on the (000-1) C surfaces of the SiC-epitaxial growth layers 131 and 132 of the second composite, on which the first SiC polycrystalline growth layers 16 and second graphene layers 17 are stacked. Similar to the first SiC polycrystalline growth layers 16, the second SiC polycrystalline growth layer 18 can also be formed by means of a CVD technique. If the layer is formed by means of the CVD technique, after the second composite in which the first SiC polycrystalline growth layers 16 and the second graphene layers 17 are stacked is installed in a CVD furnace, sufficient vacuum drawing is performed, and the composite is heated to about 1400° C. to 1500° C. Then, SiCl₄ (silicon tetrachloride) gas, CH₄ (methane) gas, and H₂ (hydrogen) gas as material gas is simultaneously flown, the pressure is adjusted, and the second SiC polycrystalline growth layer 18 is deposited, for example. At this time, a film thickness to be deposited is set according to a thickness of a final form of the SiC composite substrate 10. If a thickness of the entire SiC composite substrate 10 is 350 μm, a thickness of the SiC-epitaxial growth layer 13 may be set to 10 μm, and if a deposited film thickness of each first SiC polycrystalline growth layer 16 is 90 μm, a deposited film thickness of the second SiC polycrystalline growth layer 18 may be set to 250 μm, for example.

By depositing the first SiC polycrystalline growth layers 16, the second graphene layers 17, and the second SiC polycrystalline growth layer 18 in the second composite, a third composite (18 (2nd SiC-poly CVD), 17, 16 (1st SiC-poly CVD), 131 (SiC-epi), 141, 151, 19, 152, 142, 132 (SiC-epi), 16 (1st SiC-poly CVD), 17, and 18 (2nd SiC-poly CVD)) is formed.

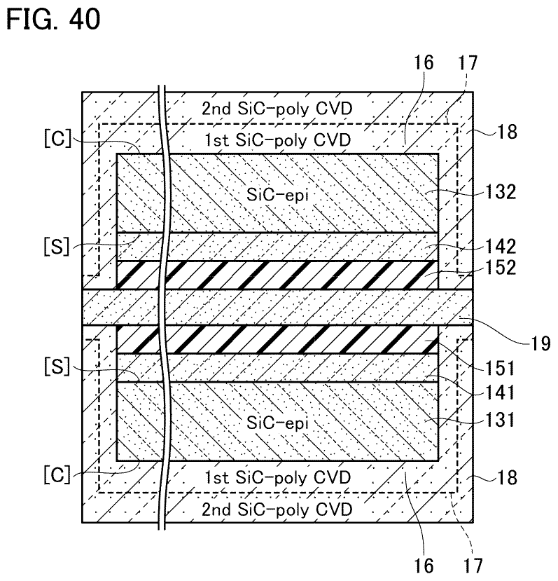

Unnecessary portions of the second SiC polycrystalline growth layer 18, the second graphene layers 17, the first SiC polycrystalline growth layers 16, and the graphite substrate 19 as the temporary substrate, which protrude from an outer periphery of the third composite are removed by grinding performed by an outer periphery grinding machine to expose the temporary substrate (graphite substrate 19) as shown in FIG. 40.

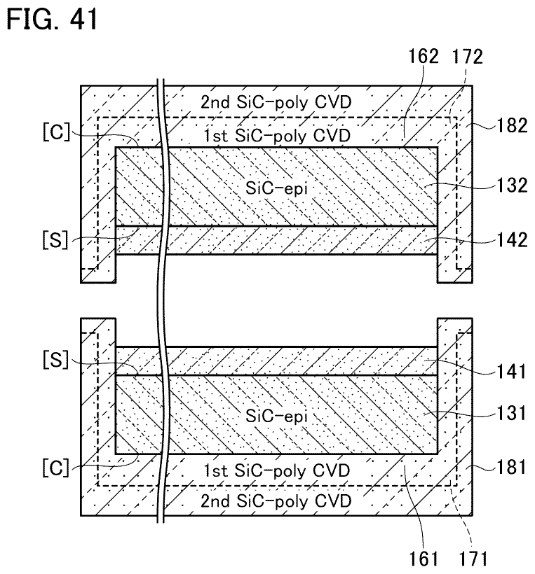

The third composite of which outer periphery is ground shown in FIG. 40 is heated to about 900° C. to 1000° C. in an atmospheric furnace where the composite can be heated in an air atmosphere while flowing atmospheric air thereto and the graphite substrate 19 and the carbonized adhesive layers 151 and 152 inside the third composite are completely removed by means of combustion as shown in FIG. 41. Then, the composite is taken out as a fourth composite (181 (2nd SiC-poly CVD), 171, 161 (1st SiC-poly CVD), 131 (SiC-epi), 141, 142, 132 (SiC-epi), 162 (1st SiC-poly CVD), 172, and 182 (2nd SiC-poly CVD)).

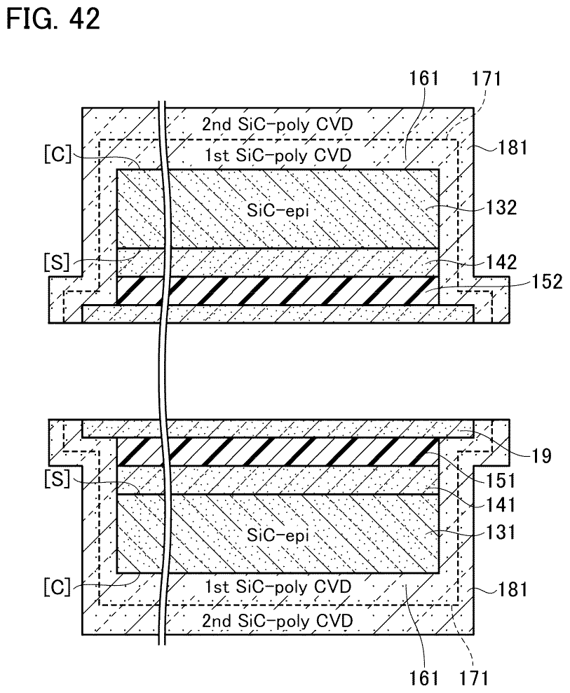

Instead of removing the unnecessary portions of the second SiC polycrystalline growth layer 18, the second graphene layers 17, the first SiC polycrystalline growth layers 16, and the graphite substrate 19, which protrude from an outer periphery of the third composite using an outer periphery grinding machine, the temporary substrate (graphite substrate 19) may be cut into two pieces at a plane parallel to a main plane of the graphite substrate 19 shown in line A-A in FIG. 39, the third composite may be separated vertically, and cut surfaces of the temporary substrate (graphite substrate 19) may be exposed as shown in FIG. 42. A wire saw or a diamond wire saw may be used as the separation technique, for example. In this case also, the graphite substrate 19 and the carbonized adhesive layers 151 and 152 inside the third composite can be removed by means of oxidation combustion and the composite can be taken out as the fourth composites as shown in FIG. 41.

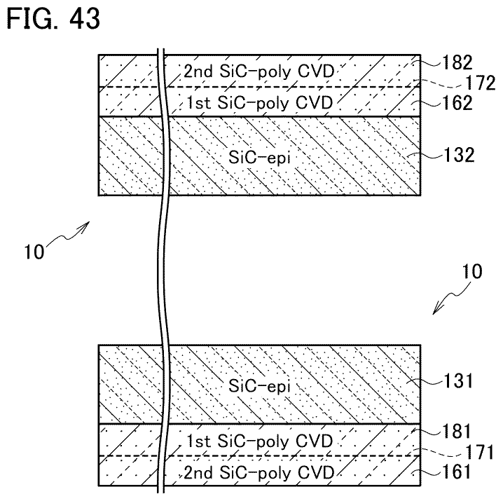

The second SiC polycrystalline growth layers 181 and 182, second graphene layers 171 and 172, and first SiC polycrystalline growth layers 161 and 162 at the outer periphery of the fourth composite are removed by grinding and polishing them using a beveling machine, and the stress layers 141 and 142 are removed by etching or polishing. Accordingly, it is possible to obtain a SiC composite substrate 10 formed by stacking the second SiC polycrystalline growth layer 181, second graphene layer 171, first SiC polycrystalline growth layer 161, and SiC-epitaxial growth layer 131, and a SiC composite substrate 10 formed by stacking the SiC-epitaxial growth layer 132, first SiC polycrystalline growth layer 162, second graphene layer 172, and second SiC polycrystalline growth layer 182 as shown in FIG. 43. Further, the SiC composite substrates 10 are processed to have the required size and surface state.

### Modified Example

A modified example of the method for manufacturing a semiconductor substrate of the second embodiment will be described. In the manufacturing method of the modified example, steps from a first step to a step of forming a stacked body formed by stacking the stress layer 14 on the SiC-epitaxial growth layer 13 as shown in FIG. 32 are the same as those of the second embodiment described above, but the modified example and second embodiment differ in a step of fitting and fixing the stacked body in the graphite substrate 19 having a spot facing hole formed on one side thereof, and thereafter. The step of fitting the stacked body in the spot facing hole in the graphite substrate 19 and thereafter, which differ from the steps in the second embodiment will be described below. Since structures and the like of each layer formed in the modified example are the same as those of the second embodiment, a description of components that are common to components in the second embodiment may be omitted.

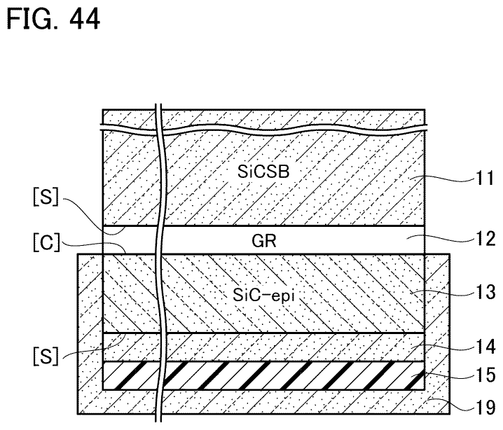

As shown in FIG. 44, the stacked body having the adhesive layer 15 formed on the stress layer 14 is fitted in the spot facing hole formed in the graphite substrate 19 as a temporary substrate of which external size is one size larger than the SiC single crystal substrate 11, a coated surface of the adhesive layer 15 is stacked and attached on a bottom surface of the spot facing hole, and a fifth composite (19, 15, 14, 13 (SiC-epi), 12 (GR), and 11 (SiCSB)) is formed. In the fifth composite, the adhesive layer 15, stress layer 14, and SiC-epitaxial growth layer 13 are located in the spot facing hole formed in the graphite substrate 19, and the first graphene layer 12 and SiC single crystal substrate 11 are located outside a surface of the graphite substrate 19. As in the second embodiment, a carbon adhesive is used for the adhesive layer 15. Then, the fifth composite is heated in a thermal annealing furnace or the like to carbonize the adhesive layer 15 thereof. As in the second embodiment, the graphite substrate 19 may have a glassy carbon film on a surface thereof.

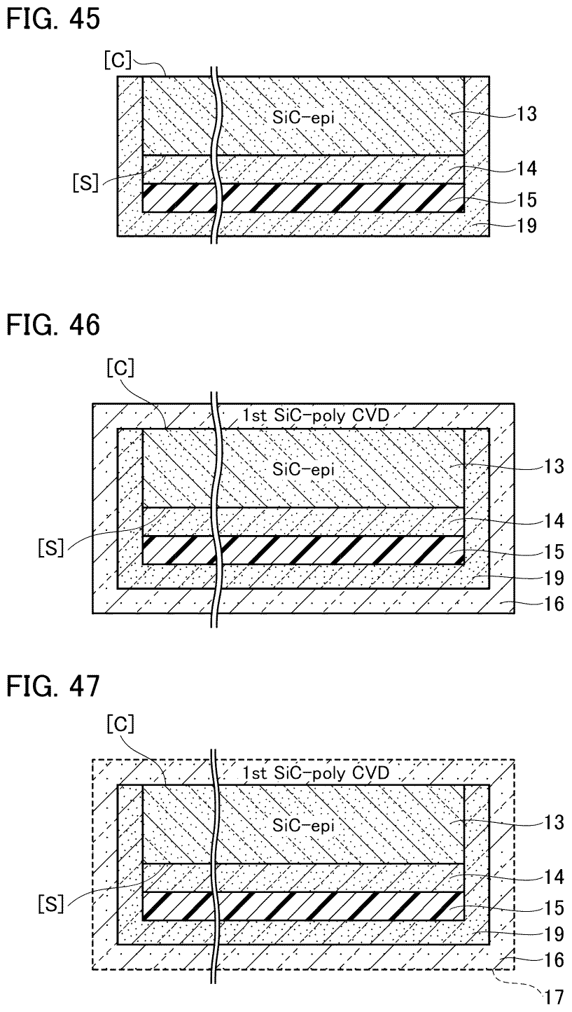

After the adhesive layer 15 of the fifth composite of FIG. 44 is carbonized, the SiC single crystal substrate 11 and first graphene layer 12 are detached and removed using an adhesive detaching tape, debonder equipment, or the like, and a sixth composite (19, 15, 14, and 13 (SiC-epi)) is formed, as shown in FIG. 45. The first graphene layer 12 is bonded by means of van der Waals force, the stress generated by the stress layer 14 is adjusted to have a magnitude that facilitates detachment between the first graphene layer 12 and SiC-epitaxial growth layer 13, and therefore the first graphene layers 12 and SiC-epitaxial growth layer 13 can be easily detached at the interface thereof by applying force in a shear direction.

As shown in FIG. 46, the first SiC polycrystalline growth layer 16 is formed on a (000-1) C surface of the SiC-epitaxial growth layer 13 fitted in the spot facing hole of the sixth composite. The first SiC polycrystalline growth layer 16 can be formed by means of a CVD technique, for example. The first SiC polycrystalline growth layer 16 has a 3C (cubic) structure.

As shown in FIG. 47, a second graphene layer (GR) 17 up to several molecular layers is formed on the (000-1) C surface of the SiC-epitaxial growth layer 13 of the sixth composite in which the first SiC polycrystalline growth layer 16 is formed. The second graphene layer 17 may be stacked by means of CVD or may be formed by means of thermal decomposition.

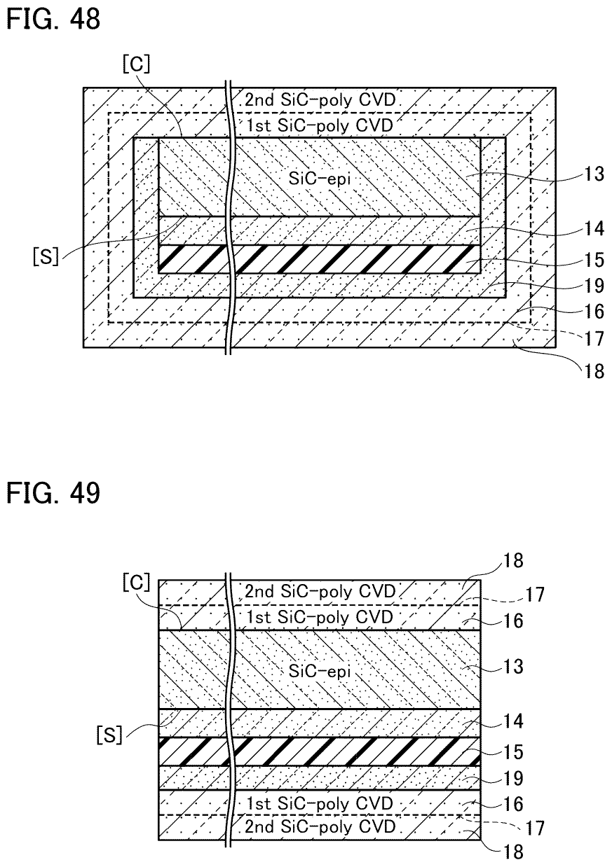

As shown in FIG. 48, a second SiC polycrystalline growth layer 18 is further formed on the (000-1) C surface of the SiC-epitaxial growth layer 13 of the sixth composite in which the first SiC polycrystalline growth layer 16 and second graphene layer 17 are stacked. Similar to the first SiC polycrystalline growth layer 16, the second SiC polycrystalline growth layer 18 can also be formed by means of a CVD technique. Similar to the first SiC polycrystalline growth layer 16, the second SiC polycrystalline growth layer 18 has a 3C (cubic) structure.

The second SiC polycrystalline growth layer 18, second graphene layer 17, and first SiC polycrystalline growth layer 16 at an outer periphery of the sixth composite are removed by grinding and polishing, as shown in FIG. 49. Further, the graphite substrate 19 and adhesive layer 15 are completely removed by means of combustion. When the stress layer 14 is removed by etching or polishing, a SiC composite substrate can be obtained in which the SiC-epitaxial growth layer 13, first SiC polycrystalline growth layer 161, first SiC polycrystalline growth layer 162, and second graphene layer 171 are stacked. A stacked body of the first SiC polycrystalline growth layer 16, second graphene layer 17, and second SiC polycrystalline growth layer 18 separated by removal of the graphite substrate 19 and adhesive layer 15 has the same shape and size as the SiC composite substrate 10, and therefore can be used as a dummy substrate.

### Semiconductor Substrate

The SiC composite substrate 10 which is the semiconductor substrate according to the second embodiment will be described below. The SiC composite substrate 10 is fabricated by performing the method for manufacturing a semiconductor substrate according to the second embodiment described above.

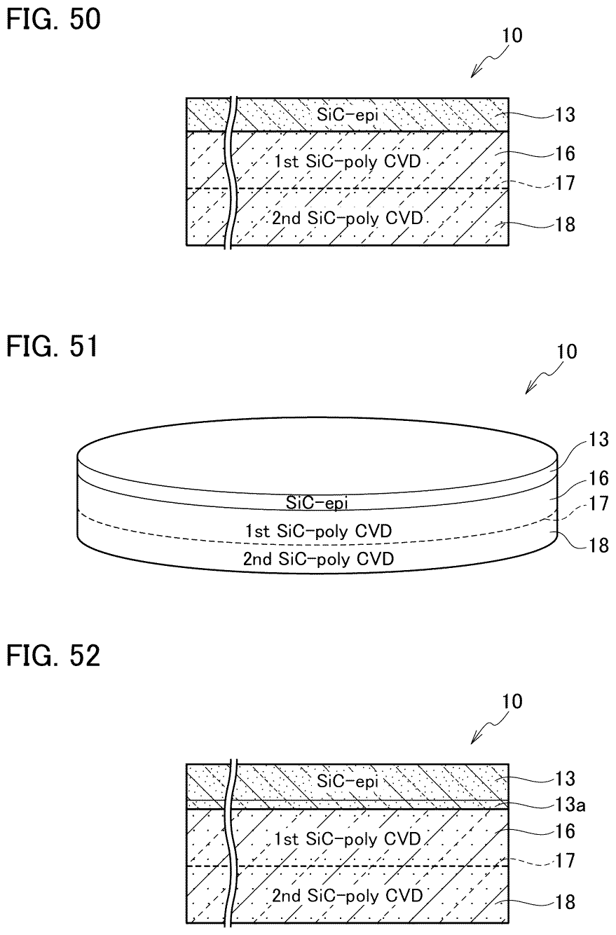

As shown in FIG. 50, the SiC composite substrate 10 is formed by stacking the second SiC polycrystalline growth layer (2nd SiC-poly CVD) 18, second graphene layer 17, first SiC polycrystalline growth layer (1st SiC-poly CVD) 16, and SiC-epitaxial growth layer (SiC-epi) 13. FIG. 51 is a schematic bird's eye view structure of the SiC composite substrate (wafer) 10. A surface of the SiC-epitaxial growth layer 13 of the SiC composite substrate 10 may be a Si surface of a [0001] orientation of the 4H—SiC, and a surface of the SiC-epitaxial growth layer 13 in contact with the first SiC polycrystalline growth layer 16 may be a C surface of a [000-1] orientation of the 4H—SiC. As shown in FIG. 30, the second graphene layer 17 has a single layer structure or a multi-layer stacked structure of graphene, and this facilitates the detachment between the second graphene layer 17 and second SiC polycrystalline growth layer 18.

In the SiC-epitaxial growth layer 13, a highly doped layer 13a may be formed toward the C surface of the SiC-epitaxial growth layer 13 in contact with the first SiC polycrystalline growth layer 16 as shown in FIG. 52. By means of the highly doped layer 13a, it is possible to suppress the spread of a depletion layer in the SiC-epitaxial growth layer 13 and easily form an ohmic contact with the first SiC polycrystalline growth layer 16 formed on the C surface of the SiC-epitaxial growth layer 13.

The highly doped layer 13a can be formed using a high dose ion implantation technique, for example. The highly doped layer 13a is formed by an ion implantation of phosphorus (P) at a high dose in a case of an n-type semiconductor, for example. If the layer is formed by P ion implantation, the crystallinity of the C surface implanted with P ions of the SiC-epitaxial growth layer 13 is affected, but the Si surface to be a device surface is already formed, and the crystallinity of the Si surface is preserved.

The highly doped layer 13a may be formed by forming a highly nitrogen (N) doped epitaxial growth layer at an initial stage when the SiC-epitaxial growth layer (SiC-epi) 13 shown in FIG. 31 is formed. In the highly nitrogen (N) doped epitaxial growth layer, although there is an influence on crystallinity due to mismatch of lattice constants, since the layer is formed by autodoping at an initial stage of epitaxial growth, steps are easy.

### Semiconductor Device

A semiconductor device can be provided, which is formed by forming a structure of a part of a semiconductor element, such as a main part of various SiC-based semiconductor elements on the Si surface of the SiC-epitaxial growth layer 13 serving as a device surface, of the SiC composite substrate 10, which is the semiconductor substrate according to the second embodiment. This kind of semiconductor device can be formed as a semiconductor element by forming an electrode or the like on a surface of the first SiC polycrystalline growth layer 16 after removing the second SiC polycrystalline growth layer 18 and second graphene layer 17 as described later. As an example of this kind of semiconductor device, a semiconductor device will be described, which constitutes a main part of a SiC-SBD, a SiC trench gate (T: Trench) TMOSFET, and a SiC planar gate MOSFET.

### SiC-SBD

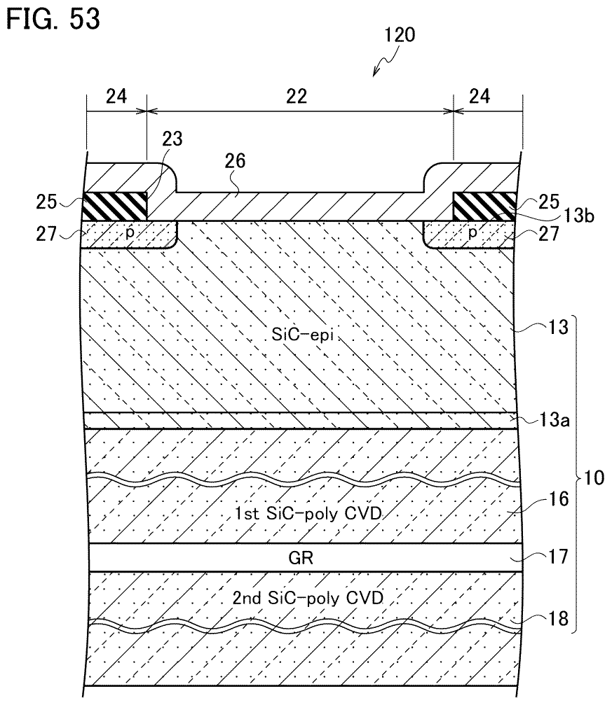

A semiconductor device 120 having a SiC-SBD structure which is obtained by forming a structure of a main part of the SiC-SBD on the SiC composite substrate 10 includes the SiC composite substrate 10 which is constituted by the second SiC polycrystalline growth layer (2nd SiC-poly CVD) 18, second graphene layer (GR) 17, first SiC polycrystalline growth layer (1st SiC-poly CVD) 16, and SiC-epitaxial growth layer (SiC-epi) 13, as shown in FIG. 53. The highly doped layer 13a may be interposed between the first SiC polycrystalline growth layer 16 and SiC-epitaxial growth layer 13. By means of the highly doped layer 13a, it is possible to suppress the spread of a depletion layer in the SiC-epitaxial growth layer 13, and easily form an ohmic contact with the first SiC polycrystalline growth layer 16 formed on the C surface of the SiC-epitaxial growth layer 13. The SiC-epitaxial growth layer 13 serves as a drift layer, the highly doped layer 13a serves as a buffer layer, and the first SiC polycrystalline growth layer 16 serves as a substrate layer.

The first SiC polycrystalline growth layer 16 is doped in an n+ type (impurity density is from about 1×10¹⁸ cm⁻³ to about 1×10²¹ cm⁻³, for example), and the SiC-epitaxial growth layer 13 is doped in an n-type (impurity density is from about 5×10¹⁴ cm⁻³ to about 5×10¹⁶ cm⁻³, for example). The highly doped layer 13a is doped at a higher concentration than the SiC-epitaxial growth layer 13.

Further, the SiC-epitaxial growth layer 13 may have a crystal structure of any one of 4H—SiC, 6H—SiC, and 2H—SiC.

As an n-type doping impurity, N (nitrogen), P (phosphorus), As (arsenic), and the like may be applied, for example.

As a p-type doping impurity, B (boron), Al (aluminum), and the like may be applied, for example.

Further, a contact hole 23 is formed in a front surface 100 (for example, (0001) Si surface) of the SiC-epitaxial growth layer 13, the contact hole 23 being for exposing a part of the SiC-epitaxial growth layer 13 as an active region 22, and a field insulating film 25 is formed in a field region 24 surrounding the active region 22.

The field insulating film 25 is made of SiO₂ (silicon oxide), but may be made of other insulating material such as silicon nitride (SiN). An anode electrode 26 is formed on the field insulating film 25.

A p-type Junction Termination Extension (JTE) structure 27 is formed in the vicinity of the front surface 13b of the SiC-epitaxial growth layer 13 (surface layer) so as to be contacted with the anode electrode 26. The JTE structure 27 is formed along an outline of the contact hole 23 of the field insulating film 25 so as to extend from the outside to inside of the contact hole 23.

### SiC-TMOSFET

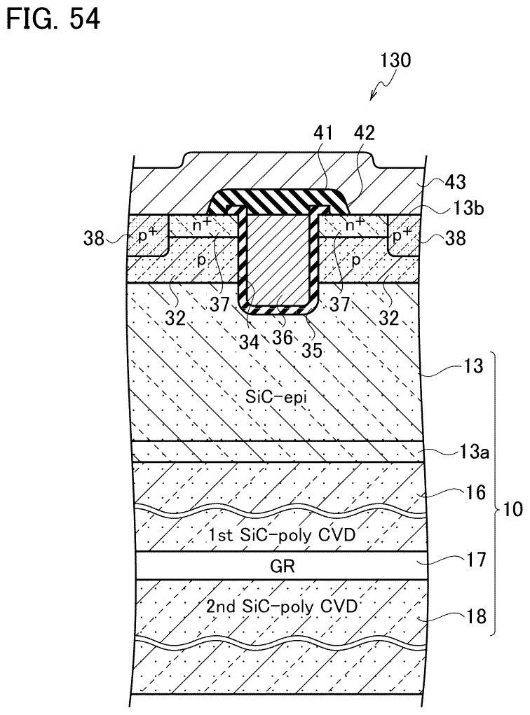

A semiconductor device 130 having a trench gate TMOSFET structure, which is obtained by forming a main part of the trench gate TMOSFET on the SiC composite substrate 10 includes the SiC composite substrate 10 which is constituted by the second SiC polycrystalline growth layer (2nd SiC-poly CVD) 18, second graphene layer (GR) 17, first SiC polycrystalline growth layer (1st SiC-poly CVD) 16, and SiC-epitaxial growth layer (SiC-epi) 13, as shown in FIG. 54. The highly doped layer 13a may be interposed between the first SiC polycrystalline growth layer 16 and SiC-epitaxial growth layer 13. By means of the highly doped layer 13a, it is possible to suppress the spread of a depletion layer in the SiC-epitaxial growth layer 13, and easily form an ohmic contact with the first SiC polycrystalline growth layer 16 formed on the C surface of the SiC-epitaxial growth layer 13. The SiC-epitaxial growth layer 13 serves as a drift layer, the highly doped layer 13a serves as a buffer layer, and the first SiC polycrystalline growth layer 16 serves as a substrate layer.

The first SiC polycrystalline growth layer 16 is doped in an n+ type (impurity density is from about 1×10¹⁸ cm⁻³ to about 1×10²¹ cm⁻³, for example), and the SiC-epitaxial growth layer 13 is doped in an n-type (impurity density is from about 5×10¹⁴ cm⁻³ to about 5×10¹⁶ cm⁻³, for example). The highly doped layer 13a is doped at a higher concentration than the SiC-epitaxial growth layer 13.

Further, the SiC-epitaxial growth layer 13 may have a crystal structure of any one of 4H—SiC, 6H—SiC, and 2H—SiC.

As an n-type doping impurity, N (nitrogen), P (phosphorus), As (arsenic), and the like may be applied, for example.

As a p-type doping impurity, B (boron), Al (aluminum), and the like may be applied, for example.

A p-type (impurity density is from about 1×10¹⁶ cm⁻³ to about 1×10¹⁹ cm⁻³, for example) body region 32 is formed in the vicinity of the front surface 13b ((0001) Si surface) of the SiC-epitaxial growth layer 13 (surface layer). A portion of the SiC-epitaxial growth layer 13 which is closer to the first SiC polycrystalline growth layer 16 than the body region 32 is an n-type drain region 33 (13) in which a state of the SiC-epitaxial growth layer 13 is maintained without any changes.

A gate trench 34 is formed in the SiC-epitaxial growth layer 13. The gate trench 34 passes through the body region 32 from the front surface 13b of the SiC-epitaxial growth layer 13, and a deepest part thereof reaches the drain region 33 (13).

A gate insulating film 35 is formed on an inner surface of the gate trench 34 and the front surface 13b of the SiC-epitaxial growth layer 13 so as to cover the entire area of the inner surface of the gate trench 45. A gate electrode 36 is buried in the gate trench 34 by filling an inner side of the gate insulating film 35 with polysilicon, for example.

An n+ type source region 37 forming a part of a side surface of the gate trench 34 is formed at the surface layer of the body region 32.

Further, a p+ type (impurity density is from about 1×10¹⁸ cm⁻³ to about 1×10²¹ cm⁻³, for example) body contact region 38 is formed in the SiC-epitaxial growth layer 13, the body contact region 38 passing through the source region 37 from the front surface 13b and being connected to the body region 32.

An interlayer insulating film 41 made of SiO₂ is formed at the SiC-epitaxial growth layer 13. A source electrode 43 is connected to the source region 37 and body contact region 38 through a contact hole 42 formed in the interlayer insulating film 41.

### SiC Planar Gate MOSFET

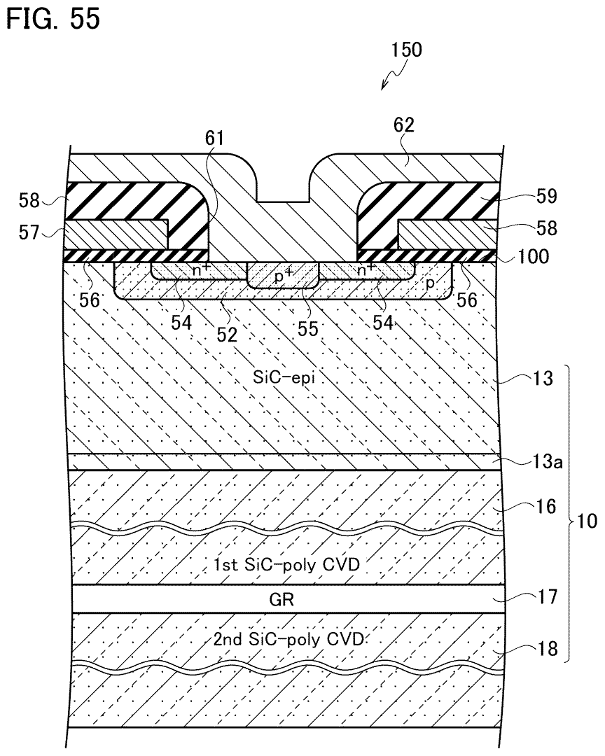

A semiconductor device 150 having a planar gate MOSFET structure, which is obtained by forming a structure of a main part of the planar gate MOSFET on the SiC composite substrate 10 includes the SiC composite substrate 10 which is constituted by the second SiC polycrystalline growth layer (2nd SiC-poly CVD) 18, second graphene layer (GR) 17, first SiC polycrystalline growth layer (1st SiC-poly CVD) 16, and SiC-epitaxial growth layer (SiC-epi) 13, as shown in FIG. 55. The highly doped layer 13a may be interposed between the first SiC polycrystalline growth layer 16 and SiC-epitaxial growth layer 13. By means of the highly doped layer 13a, it is possible to suppress the spread of a depletion layer in the SiC-epitaxial growth layer 13, and easily form an ohmic contact with the first SiC polycrystalline growth layer 16 formed on the C surface of the SiC-epitaxial growth layer 13. The SiC-epitaxial growth layer 13 serves as a drift layer, the highly doped layer 13a serves as a buffer layer, and the first SiC polycrystalline growth layer 16 serves as a substrate layer.

The first SiC polycrystalline growth layer 16 is doped in an n+ type (impurity density is from about 1×10¹⁸ cm⁻³ to about 1×10²¹ cm⁻³, for example), and the SiC-epitaxial growth layer 13 is doped in an n-type (impurity density is from about 5×10¹⁴ cm⁻³ to about 5×10¹⁶ cm⁻³, for example).

Further, the SiC-epitaxial growth layer 13 may have a crystal structure of any one of 4H—SiC, 6H—SiC, and 2H—SiC.

As an n-type doping impurity, N (nitrogen), P (phosphorus), As (arsenic), and the like may be applied, for example.

As a p-type doping impurity, B (boron), Al (aluminum), and the like may be applied, for example.

A p-type (impurity density is from about 1×10¹⁶ cm⁻³ to about 1×10¹⁹ cm⁻³, for example) body region 52 is formed in a well shape in the vicinity of the front surface 100 ((0001) Si surface) of the SiC-epitaxial growth layer 13 (surface layer). A portion of the SiC-epitaxial growth layer 13 closer to the SiC composite substrate 10 than the body region 52 is an n-type drain region 53 (13) in which a state after epitaxial growth is maintained without any changes.

At a surface layer of the body region 52, an n+ type source region 54 is formed by being spaced apart from a peripheral edge of the body region 52.

A p+ type (impurity density is from about 1×10¹⁸ cm⁻³ to about 1×10²¹ cm⁻³, for example) body contact region 55 is formed on an inner side of the source region 54. The body contact region 55 passes through the source region 54 in a depth direction and is connected to the body region 52.

A gate insulating film 56 is formed on the front surface 100 of the SiC-epitaxial growth layer 13. The gate insulating film 56 covers a portion of the body region 52 surrounding the source region 54 (peripheral edge of body region 52) and an outer peripheral edge of the source region 54.

A gate electrode 57 made of polysilicon is formed on the gate insulating film 56, for example. The gate electrode 57 faces the peripheral edge of the body region 52 with the gate insulating film 56 therebetween.

An interlayer insulating film 58 made of SiO₂ is formed on the SiC-epitaxial growth layer 13. A source electrode 62 is connected to the source region 54 and body contact region 55 through a contact hole 61 formed in the interlayer insulating film 58.

### Removal of Second SiC Polycrystalline Growth Layer and Second Graphene Layer

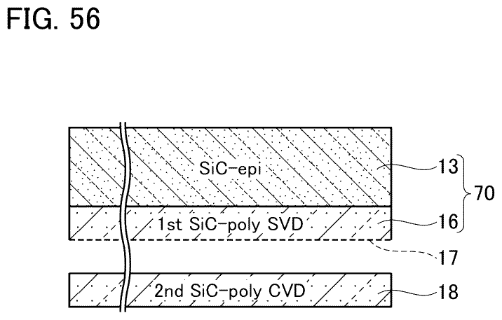

The second SiC polycrystalline growth layer 18 can be removed from the SiC composite substrate 10 by detaching the second graphene layer 17 and second SiC polycrystalline growth layer 18 of the SiC composite substrate 10 at an interface thereof, as shown in FIG. 56. The second graphene layer 17 can be detached because the second graphene layer 17 has a stacked structure of graphite sheets, and graphite sheets on each surface are bonded by means of van der Waals force, as shown in FIG. 30. After the second SiC polycrystalline growth layer 18 is removed, the second graphene layer 17 is removed by etching or polishing, and accordingly it is possible to obtain a thinned SiC composite substrate 70 in which the first SiC polycrystalline growth layer 16 and SiC-epitaxial growth layer 13 are stacked.

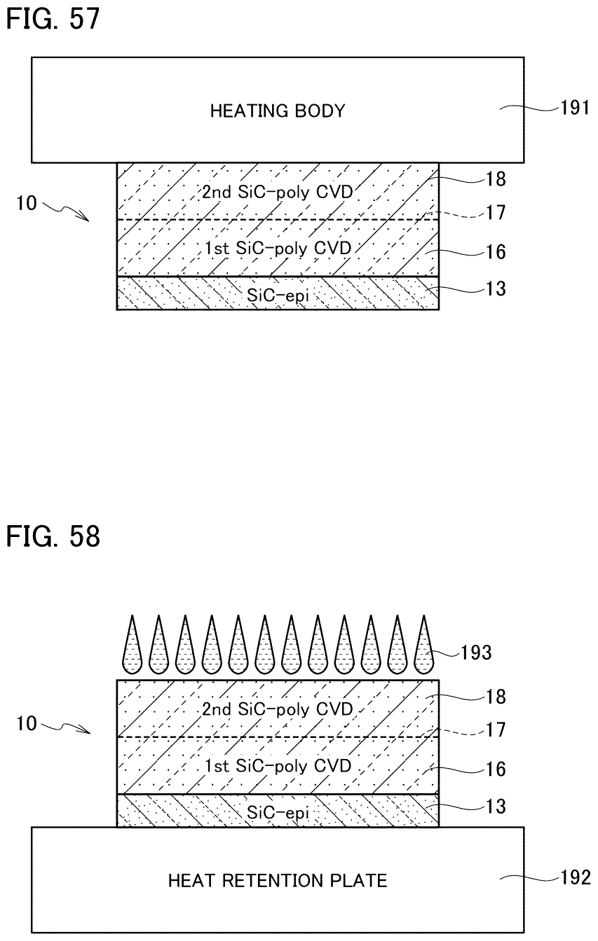

In order to detach the second graphene layer and second SiC polycrystalline growth layer, a starting point of a crack is formed between the second graphene layer and second SiC polycrystalline growth layer. As shown in FIG. 57, a heating body 191 such as a hot plate is brought into contact with a surface of the second SiC polycrystalline growth layer 18 of the SiC composite substrate 10. Then, the heating body 191 rapidly heats the surface of the second SiC polycrystalline growth layer 18, a stress concentration due to thermal stress is generated at an interface between the second graphene layer 17 and the second SiC polycrystalline growth layer 18 and at an end of the SiC composite substrate 10, and accordingly a starting point of a crack can be generated. Instead of the heating body 191 such as a hot plate, the second SiC polycrystalline growth layer 18 may be heated by being irradiated with a light beam of a halogen lamp or the like.

As shown in FIG. 58, the surface of the second SiC polycrystalline growth layer 18 of the SiC composite substrate 10 may be cooled by a coolant 193 such as liquid nitrogen, and a starting point of a crack may be generated by the concentration of the thermal stress generated by the rapid cooling at the interface between the second graphene layer 17 and the second SiC polycrystalline growth layer 18 at the end of the SiC composite substrate 10. At this time, a heat retention plate 192 may be brought into contact with the surface of the SiC-epitaxial growth layer 13 of the SiC composite substrate 10 to keep the surface of the SiC-epitaxial growth layer 13 warm, and a temperature gradient may be ensured in the SiC composite substrate 10.

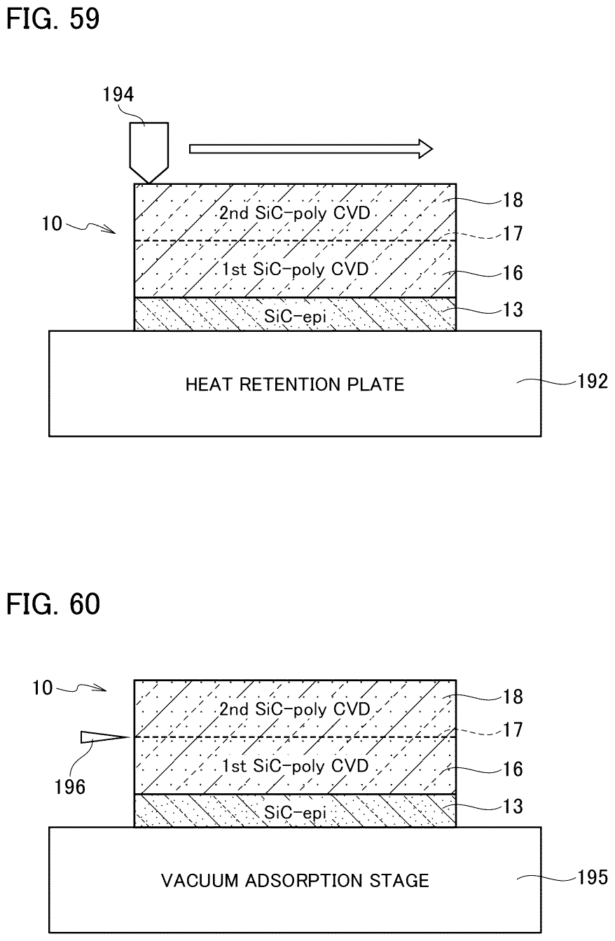

In the SiC composite substrate 10 in which a starting point of a crack is formed at the interface between the second graphene layer 17 and second SiC polycrystalline growth layer 18 at an end surface, the surface of the second SiC polycrystalline growth layer 18 is scanned with an ultrasonic oscillator 194 as shown in FIG. 59. A heating region due to a focus of converted ultrasonic waves moves along the interface between the second graphene layer 17 and second SiC polycrystalline growth layer 18, and due to thermal stress caused by heating, the crack develops from the starting point thereof along the interface between the second graphene layer 17 and second SiC polycrystalline growth layer 18. At this time, the oscillation energy of the ultrasonic oscillator may be set to have a minimum magnitude such that the crack develops to suppress the occurrence of defects at the interface and the warping of the substrate. Further, the heat retention plate 192 may be brought into contact with the surface of the SiC-epitaxial growth layer 13 of the SiC composite substrate 10 to keep the SiC-epitaxial growth layer 13 warm, and a temperature gradient may be ensured in the SiC composite substrate 10. The heating region may be moved to the interface between the second graphene layer 17 and the second SiC polycrystalline growth layer 18 by scanning the surface of the second SiC polycrystalline growth layer 18 of the SiC composite substrate 10 with a laser light instead of using the ultrasonic oscillator 194.

In the SiC composite substrate 10 in which the starting point of the crack is formed at the interface between the second graphene layer 17 and the second SiC polycrystalline growth layer 18 at the end surface, the crack may mechanically develop from the starting point thereof along the interface between the second graphene layer 17 and the second SiC polycrystalline growth layer 18 by pushing a cleavage blade 196 into the starting point of the crack at the end surface, as shown in FIG. 60. At this time, a vacuum adsorption stage 195 may be placed on the surface of the SiC-epitaxial growth layer 13 of the SiC composite substrate 10 and may adsorb the surface to fix the SiC composite substrate 10.

### Semiconductor Element

As described above, the semiconductor device according to the second embodiment is obtained by forming the structure of the main part of the SiC-based semiconductor element on the Si surface of the SiC-epitaxial growth layer 13 of the SiC composite substrate 10. Therefore, after the thinned SiC composite substrate 70 is obtained by removing the second SiC polycrystalline growth layer 18 and second graphene layer 17 from the SiC composite substrate 10 constituting the semiconductor device as described above, the surface of the first SiC polycrystalline growth layer 16 is processed such as formation of an electrode thereon, and accordingly a semiconductor element can be obtained. In the following, the SiC-SBD, SiC trench gate TMOSFET, and SiC planar gate MOSFET which have been cited as an example of the semiconductor device will be described.

### SiC-SBD

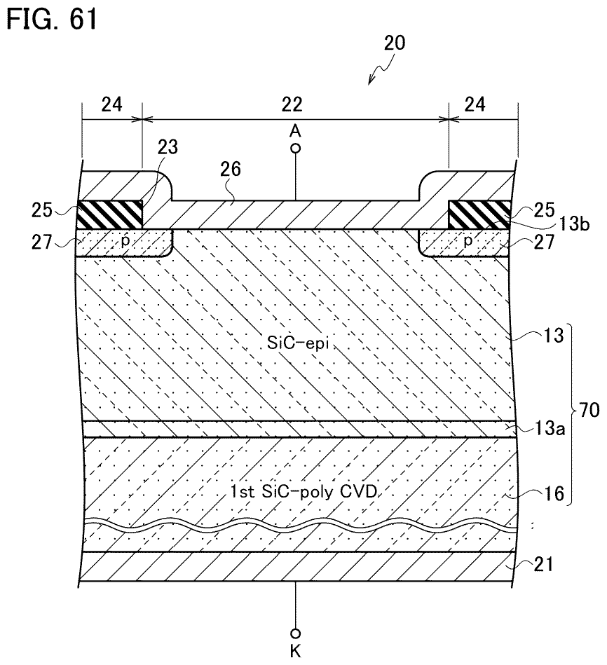

FIG. 61 shows the SiC-SBD of the semiconductor element. The second SiC polycrystalline growth layer 18 and second graphene layer 17 are removed from the SiC composite substrate 10 constituting the semiconductor device 120 having the SiC-SBD structure shown in FIG. 53 to form the thinned SiC composite substrate 70. A cathode electrode 21 is formed on a back surface ((000-1) C surface) of the first SiC polycrystalline growth layer 16 of the thinned SiC composite substrate 70 so as to cover the entire area thereof, and the cathode electrode 21 is connected to a cathode terminal K. Further, an anode electrode 26 is connected to an anode terminal A. In this way, a SiC-SBD 20 as shown in FIG. 61 can be formed.

### SiC-TMOSFET

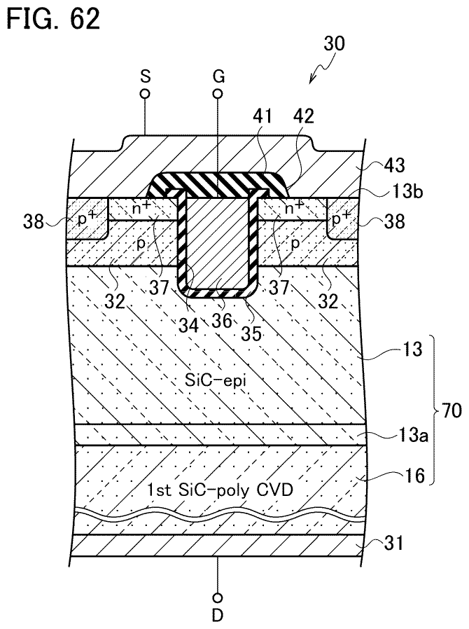

FIG. 62 shows a SiC-TMOSFET 30. The second SiC polycrystalline growth layer 18 and second graphene layer 17 are removed from the SiC composite substrate 10 constituting the semiconductor device 130 having the SiC-TMOSFET structure shown in FIG. 54 to form the thinned SiC composite substrate 70. A drain electrode 31 is formed on the back surface ((000-1) C surface) of the first SiC polycrystalline growth layer 16 of the thinned SiC composite substrate 70 so as to cover the entire area thereof, and the drain electrode 31 is connected to a drain terminal D. Further, a gate electrode 36 is connected to a gate terminal G, and a source electrode 43 is connected to a source terminal S, respectively. In this way, the SiC-TMOSFET 30 as shown in FIG. 62 can be formed.

In the SiC-TMOSFET 30, by applying a prescribed voltage (voltage equal to or greater than gate threshold voltage) to the gate electrode 36 while a prescribed potential difference is generated between the source electrode 43 and drain electrode 31 (between source and drain), a channel can be formed in the vicinity of an interface with the gate insulating film 35 in the body region 32 by an electric field from the gate electrode 36. As a result, a current can flow between the source electrode 43 and the drain electrode 31, and the SiC-TMOSFET 30 can be turned on.

### SiC Planar Gate MOSFET

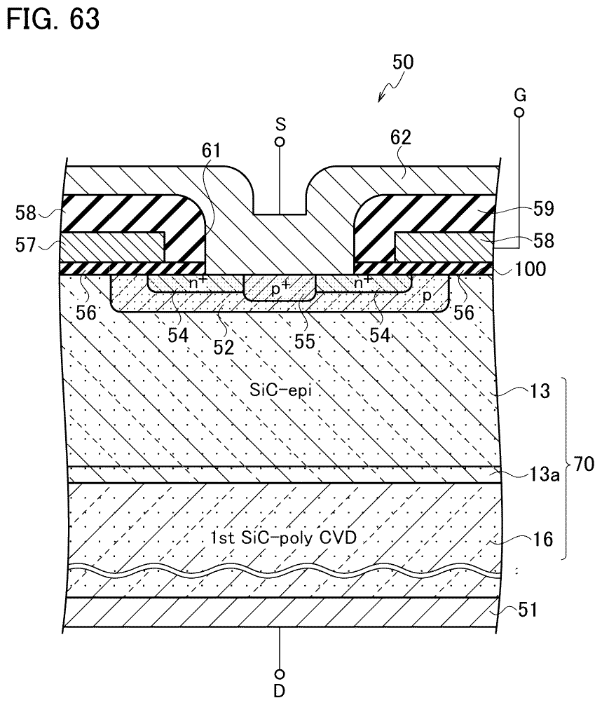

FIG. 63 shows a SiC planar gate MOSFET 50. The second SiC polycrystalline growth layer 18 and second graphene layer 17 are removed from the SiC composite substrate 10 constituting the semiconductor device 150 shown in FIG. 55 to form the thinned SiC composite substrate 70. A drain electrode 51 is formed on the back surface ((000-1) C surface) of the first SiC polycrystalline growth layer 16 of the thinned SiC composite substrate 70 so as to cover the entire area thereof. Further, the drain electrode 51 is connected to a drain terminal D and a gate electrode 57 is connected to a gate terminal G, respectively. In this way, the SiC planar gate MOSFET 50 as shown in FIG. 63 can be formed.

In the SiC planar gate MOSFET 50, by applying a prescribed voltage (voltage equal to or greater than gate threshold voltage) to the gate electrode 57 while a prescribed potential difference is generated between the source electrode 62 and drain electrode 51 (between source and drain), a channel can be formed in the vicinity of an interface with the gate insulating film 56 in the body region 52 by an electric field from the gate electrode 57. As a result, a current can flow between the source electrode 62 and the drain electrode 51, and the SiC planar gate MOSFET 50 can be turned on.

As described above, according to the second embodiment, a starting point where the second graphene layer 17 and the second SiC polycrystalline growth layer 18 are detached is formed at the interface between the second graphene layer 17 and the second SiC polycrystalline growth layer 18 at the end surface of the SiC composite substrate 10, then, by performing mechanical and/or thermal operations to propagate the crack along the interface, the crack can be extended in the entire interface of the SiC composite substrate 10, and this can facilitate detachment between the second graphene layer 17 and second SiC polycrystalline growth layer 18.

Further, in the thinned SiC composite substrate 70 in which the second SiC polycrystalline growth layer 18 is removed by detaching the second graphene layer 17 and second SiC polycrystalline growth layer 18, a surface of the first SiC polycrystalline growth layer 16 on which the second graphene layer 17 is stacked is maintained to have the surface roughness at the time of film formation without any changes, and if special planarization processing such as polishing is not required, the process can proceed to a next step without any changes. In this case, graphene remaining on the surface may be removed by oxygen plasma or the like. If a surface is thinned by means of other techniques and methods, the thinned surface is inevitably roughened, and therefore planarization processing such as polishing is required to a large extent. However, in the thinning operation according to the second embodiment, polishing after thinning is not required, a processing loss of the expensive single crystal SiC layer does not occur at all, and this can further reduce the total cost of the SiC composite substrate. Further, the detached second SiC polycrystalline growth layer 18 can be reused for a dummy substrate or the like without any changes, and this is economical. Similarly, a stacked body of the first SiC polycrystalline growth layer 16, second graphene layer 17, and second SiC polycrystalline growth layer 18 generated in the modified example can be reused as a dummy substrate.

Furthermore, according to the second embodiment, by separating the SiC single crystal substrate 11 and replacing the substrate with the graphite substrate 19 as the highly heat-resistant temporary substrate before forming the first SiC polycrystalline growth layer 16 by means of a CVD method, unnecessary adhesion of the polycrystalline SiC to the SiC single crystal substrate 11 can be prevented, the reusability of the SiC single crystal substrate 11 can be enhanced, and the cost can be reduced.

According to the second embodiment, by using the graphite substrate 19 as the highly heat-resistant temporary substrate which is one size larger than the SiC single crystal substrate 11, epitaxial growth on one or both sides is possible using an epitaxial growth apparatus such as a vertical batch tubular furnace, and high-throughput and low-cost production can be realized without increasing a growth rate.

According to the second embodiment, by carbonizing a highly heat-resistant substrate such as the graphite substrate 19 and the adhesive layer, separation can be performed at a low cost by simply firing a semiconductor substrate structure formed on both sides of the graphite substrate 19 in an oxidation furnace or the like.

According to the second embodiment, the remote epitaxial growth of SiC is performed through graphene formed on the SiC single crystal substrate 11, the first SiC polycrystalline growth layer 16 or the like is directly formed thereon by means of a CVD method, and therefore substrate bonding is unnecessary, and a defect caused by the substrate bonding can be eliminated. In addition, since the epitaxial growth layer is formed through the first graphene layer 12, the separation between the SiC single crystal substrate 11 and SiC epitaxial growth layer 13 becomes easy, and a process step becomes simple.

According to the second embodiment, after the SiC single crystal substrate is removed, the entire graphite substrate 19 as a handle substrate with high heat resistance is put in a high-temperature LP-CVD apparatus, and the first SiC polycrystalline growth layer 16 or the like is directly grown on the SiC epitaxial growth layer 13. This eliminates a step of transporting an epitaxial growth layer having a thickness of several μm from the handle substrate to a support substrate, and a step of bonding with the support substrate, and accordingly it is possible to avoid faults such as creases, crystal transitions, and voids caused by thin film transport and bonding.

According to the second embodiment, the first graphene layer 12 formed on the SiC single crystal substrate 11 is not transferred, but the epitaxial growth is performed thereon without any changes. This can avoid faults such as creases and cracks caused by the transfer of graphene.

According to the second embodiment, the SiC single crystal substrate 11 is used as a base, and therefore the hexagonal SiC with less decrease in crystallinity can be obtained. In addition, although the SiC single crystal substrate 11 is expensive and removal thereof by means of polishing or etching is difficult, by means of remote epitaxial growth through the first graphene layer 12, the obtained high performance single crystal layer can be easily separated, and necessity of removal by means of polishing or etching is eliminated. Since the expensive SiC single crystal substrate 11 can be reused after separation, a large advantage in cost can be obtained.

Although the second embodiment has been described above, the invention can be carried out in other ways. Although not shown in the diagrams, a MOS capacitor can be manufactured using the SiC composite substrate 10, for example. The yield and reliability can be enhanced in the manufacturing of the MOS capacitor.

Further, although not shown in the diagrams, a bipolar transistor can be manufactured using the SiC composite substrate 10. In addition, the SiC composite substrate 10 according to the second embodiment can be used for manufacturing a SiC-pn diode, SiCIGBT, SiC complementary MOSFET, and the like. A semiconductor composite substrate 1 can also be applied to other types of devices such as a light emitting diodes (LED) and a Semiconductor Optical Amplifier (SOA), for example.

The SiC-epitaxial growth layer 13 may have at least one or more types selected from a group of an IV group element semiconductor, a III-V group compound semiconductor, and a II-VI group compound semiconductor.

Further, the SiC single crystal substrate 11 and the SiC-epitaxial growth layer 13 may be made of a material of any one of 4H—SiC, 6H—SiC, and 2H—SiC.

Further, the SiC single crystal substrate 11 and the SiC-epitaxial growth layer 13 may have at least one type selected from a group of GaN, BN, AlN, Al₂O₃, Ga₂O₃, diamond, carbon, and graphite as another material system other than SiC.

The semiconductor device having the SiC composite substrate 10 may include any one of a GaN-based, AlN-based, and gallium oxide-based IGBT, diode, MOSFET, and thyristor as a component other than a SiC-based component.

The semiconductor device having the SiC composite substrate 10 may have a structure of any one of 1-in-1 module, 2-in-1 module, 4-in-1 module, 6-in-1 module, 7-in-1 module, 8-in-1 module, 12-in-1 module, and 14-in-1 module.

The SiC composite substrate 10 uses, for a Si surface serving as a device surface, the low-cost SiC-epitaxial growth layer 13 on the first SiC polycrystalline growth layer 16 and second SiC polycrystalline growth layer 18 instead of using the high-cost SiC single crystal substrate 11.

### Third Embodiment

Next, a third embodiment will be described. In the third embodiment, a hydrogen ion implantation separation method is used, which enables detachment of a surface thinning layer by implanting hydrogen ions to a SiC single crystal substrate to form an embrittlement layer. Since the third embodiment is the same as the second embodiment except that the hydrogen ion implantation separation method is used in the method for manufacturing a semiconductor substrate, only the method for manufacturing a semiconductor substrate will be described in the third embodiment below. Similar to the second embodiment, a SiC composite substrate 10 fabricated by performing a method for manufacturing a semiconductor of the third embodiment can be applied to a semiconductor device and a semiconductor element. For simplification, in the description of the third embodiment below, the same members as those of the second embodiment are denoted with the same reference numerals, and the description thereof may be omitted.

### Method for Manufacturing Semiconductor Substrate

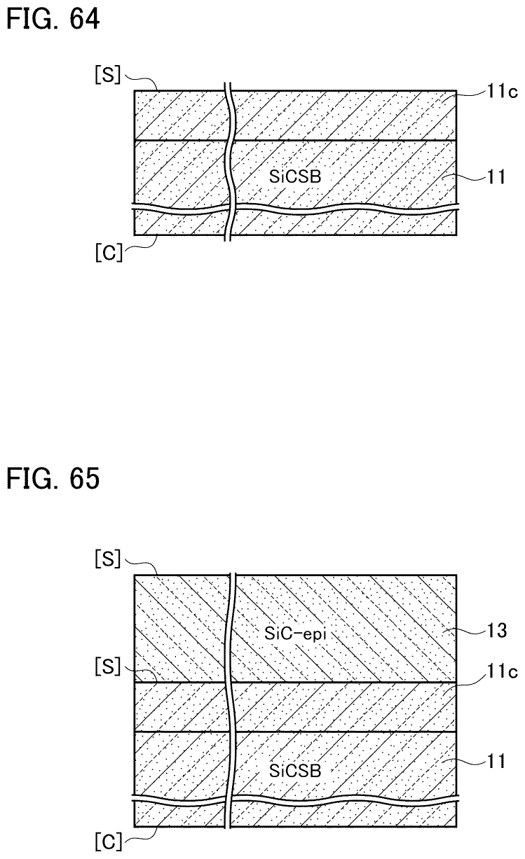

Hydrogen ions are implanted to a Si surface of a SiC single crystal substrate (SiCSB) 11 shown in FIG. 25 to perform an ion implantation separation method and a hydrogen ion implantation layer 11c having a specified depth (for example, about 1 μm) is formed. FIG. 64 shows the SiC single crystal substrate 11 on which the hydrogen ion implantation layer 11c is formed. As ion implantation conditions, an acceleration energy may be about 100 keV, for example, and a dosage may be about 2.0×10¹⁷/cm², for example. Subsequently, the hydrogen ion implantation layer 11c is treated at a high temperature and the hydrogen ion implantation layer 11c is embrittled. The embrittlement thermal annealing is necessary, which is for generating hydrogen microbubbles after the hydrogen ion implantation and facilitating the rupture of the hydrogen ion implantation layer 11c.

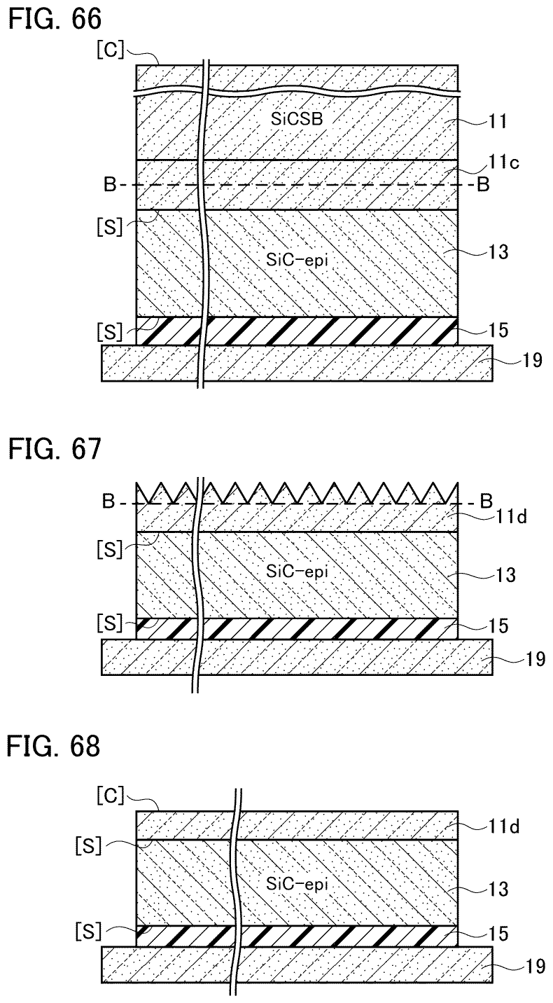

As shown in FIG. 65, a SiC-epitaxial growth layer 13 is formed on a Si surface of the hydrogen ion implantation layer 11c by means of a CVD method. Then, as shown in FIG. 66, a graphite substrate 19 as a temporary substrate is attached on a Si surface of the SiC-epitaxial growth layer 13 with an adhesive layer 15 using a carbon adhesive therebetween, they are heated in a thermal annealing furnace or the like, and the adhesive layer 15 is carbonized.

The hydrogen ion implantation layer 11c subjected to an embrittlement treatment is separated into two parts by a detachment surface shown in line B-B of FIG. 66, and the SiC single crystal substrate 11 is removed. As shown in FIG. 67, one part of the separated hydrogen ion implantation layer 11c in contact with the SiC-epitaxial growth layer 13 forms a thinned SiC single crystal layer 11d in which the SiC single crystal substrate 11 is thinned. Meanwhile, an uneven structure formed by detachment on a Si surface of a main body of the SiC single crystal substrate 11 on the other part of the separated hydrogen ion implantation layer 11c is smoothed by performing a mechanical polishing method, a mechanochemical polishing method, or the like. By performing the above steps, an average surface roughness Ra of the Si surface of the SiC single crystal substrate 11 is about 1 nm or less, for example. As a result, the SiC single crystal substrate 11 can be reused.

As shown in FIG. 68, the uneven structure of the detachment surface of the stacked body of the thinned SiC single crystal layer 11d and SiC-epitaxial growth layer 13 adhered to the graphite substrate 19 is smoothed by performing a mechanical polishing method, a mechanochemical polishing method, or the like. The structure shown in FIG. 68 forms a seventh composite (19, 15, 13 (SiC-epi), and 11d).

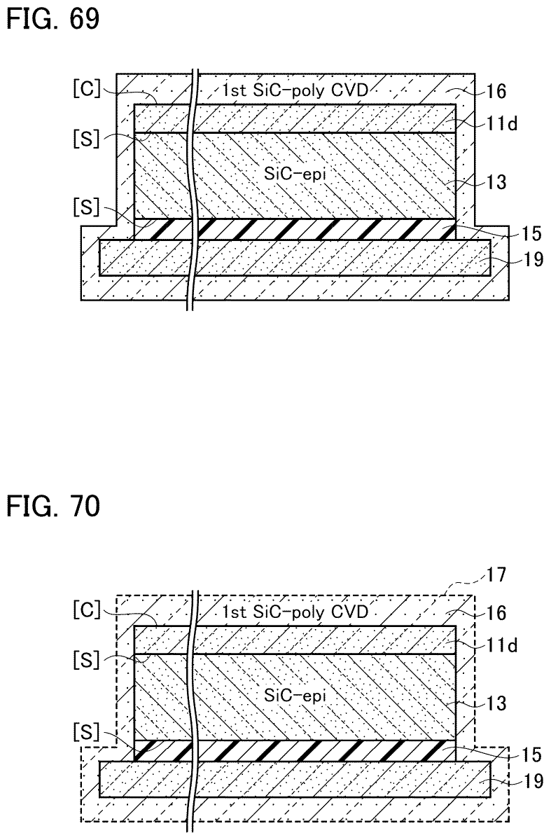

As shown in FIG. 69, a first SiC polycrystalline growth layer 16 is formed on a C surface of the thinned SiC single crystal layer 11d of the seventh composite by means of a CVD technique. As shown in FIG. 70, a second graphene layer (GR) 17 is formed on the C surface of the thinned SiC single crystal layer 11d of the seventh composite, on which the first SiC polycrystalline growth layer 16 is formed. As shown in FIG. 71, a second SiC polycrystalline growth layer 18 is further formed on the C surface of the thinned SiC single crystal layer 11d of the seventh composite in which the first SiC polycrystalline growth layer 16 and second graphene layer 17 are stacked.

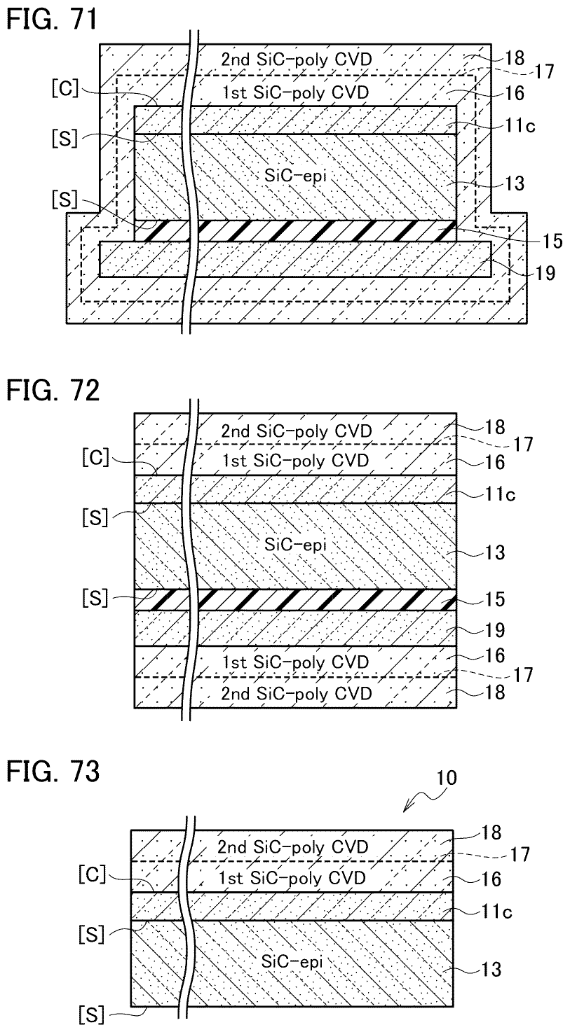

The second SiC polycrystalline growth layer 18, second graphene layer 17, and first SiC polycrystalline growth layer 16 at the outer periphery of the seventh composite in which the first SiC polycrystalline growth layer 16, second graphene layer 17, and second SiC polycrystalline growth layer 18 are stacked shown in FIG. 71 are removed by grinding and polishing, as shown in FIG. 72. The structure shown in FIG. 72 forms an eighth composite (18 (2nd SiC-poly SVD), 17 (GR), 16 (1st SiC-poly SVD), 19, 15, 13 (SiC-epi), 11c, 16 (1st SiC-poly SVD), 17 (GR), and 18 (2nd SiC-poly SVD)).

The graphite substrate 19 and carbonized adhesive layer 15 inside the eighth composite are removed by means of oxidation combustion as shown in FIG. 73, and accordingly it is possible to obtain a SiC composite substrate 10 in which the SiC-epitaxial growth layer 13, thinned SiC single crystal layer 11c, first SiC polycrystalline growth layer 16, second graphene layer 17, and second SiC polycrystalline growth layer 18 are stacked. The SiC composite substrate 10 of the second embodiment is similar to the SiC composite substrate 10 of the second embodiment except that the thinned SiC single crystal layer 11d is interposed between the SiC-epitaxial growth layer 13 and first SiC polycrystalline growth layer.

Since the SiC-epitaxial growth layer 13 has the same crystal structure as the SiC single crystal substrate 11, the SiC composite substrate 10 of the third embodiment shown in FIG. 73 has the same structure as the SiC composite substrate 10 of the second embodiment. By oxidizing and combusting the graphite substrate 19 and adhesive layer 15, a stacked body of the second SiC polycrystalline growth layer 18, second graphene layer 17, and first SiC polycrystalline growth layer 16 is obtained. The stacked body has the same shape and size as the SiC composite substrate 10, and therefore can be used as a dummy substrate.

As described above, by performing the method for manufacturing a semiconductor substrate of the third embodiment, the SiC composite substrate 10 similar to that of the second embodiment can be fabricated. Therefore, the same effect as in the second embodiment can be obtained in the third embodiment also. Further, in the third embodiment, the epitaxial growth is directly performed on the Si surface of the SiC single crystal substrate 11 without a graphene layer therebetween, and therefore a SiC-epitaxial growth layer 13 having a favorable crystal structure can be formed. In addition, according to the third embodiment, a dummy substrate can be fabricated at the same time as the SiC composite substrate 10.

### Other Embodiments

Although several embodiments have been described above, the discussion and drawings forming part of this disclosure are illustrative and should not be construed as limiting the invention. Various alternative embodiments, examples, and operational techniques will be apparent to those skilled in the art from this disclosure. In this way, the embodiments herein include various embodiments and the like not described herein.

### (Appendix 1)

A method for manufacturing a SiC composite substrate 10 which is a semiconductor substrate, the method including:
a step of forming a graphene layer 12 on a Si surface of a SiC single crystal substrate 11;
a step of forming a SiC-epitaxial growth layer 13 on the graphene layer 12;
a step of forming a stress layer 14 on the SiC-epitaxial growth layer 13;
a step of attaching a graphite substrate 19 as a temporary substrate on the stress layer 14;
a step of detaching the graphene layer 12 and the SiC-epitaxial growth layer 13;
a step of forming a SiC polycrystalline growth layer 16 on a C surface of the SiC-epitaxial growth layer 13 from which the graphene layer 12 is detached; and
a step of removing the graphite substrate 19, in which the stress layer 14 generates a stress that facilitates detachment between the graphene layer 12 and the SiC-epitaxial growth layer 13. This facilitates detachment between the graphene layer 12 and the SiC-epitaxial growth layer 13.

### (Appendix 2)

The method for manufacturing a semiconductor substrate according to Appendix 1, in which
the stress layer 14 generates a stress between the graphene layer 12 and the SiC-epitaxial growth layer 13 that approximates an adhesion energy between the graphene layer 12 and the SiC-epitaxial growth layer 13. This enables detachment between the graphene layer 12 and the SiC-epitaxial growth layer 13 at an interface thereof.

### (Appendix 3)

The method for manufacturing a semiconductor substrate according to Appendix 2, in which
the stress layer 14 generates a stress for detaching the graphene layer 12 and the SiC-epitaxial growth layer 13, the stress depending on a stacked structure of the SiC single crystal substrate 11, the graphene layer 12, the SiC-epitaxial growth layer 13, the stress layer 14, and the graphite substrate 19. The magnitude of the generated stress can be adjusted.

### (Appendix 4)

The method for manufacturing a semiconductor substrate according to any one of Appendixes 1 to 3, in which
the stress layer 14 includes a carbon film or a silicon nitride film. Since metal is not contained, it is possible to avoid metal contamination.

### (Appendix 5)

The method for manufacturing a semiconductor substrate according to Appendix 4, in which
the carbon film includes a polycrystalline diamond film or a diamond-like carbon film. The film can be formed relatively easily and can withstand high heat.

### (Appendix 6)

The method for manufacturing a semiconductor substrate according to any one of Appendixes 1 to 3, further including:
a step of removing the stress layer 14 by means of combustion or grinding. The stress layer 14 can be easily removed.

### (Appendix 7)

The method for manufacturing a semiconductor substrate according to Appendix 1, in which
the graphite substrate 19 as the temporary substrate is made of graphite. The graphite substrate 19 as the temporary substrate can be removed by means of combustion.

### (Appendix 8)

The method for manufacturing a semiconductor substrate according to Appendix 7, in which
the graphite substrate 19 has an external size that is larger than an external size of the SiC single crystal substrate 11. When inserted into a wafer boat groove in a vertical batch CVD furnace and aligned, a strut mark on a wafer boat can be set outside a substrate effective area.

### (Appendix 9)

The method for manufacturing a semiconductor substrate according to Appendix 7, in which
the graphite substrate 19 includes a glassy carbon film formed on a surface thereof. Since adhesion force between the glassy carbon film and a carbon adhesive of an adhesive layer 15 is strong, the graphene layer 12 and the SiC-epitaxial growth layer 13 can be easily detached.

### (Appendix 10)

The method for manufacturing a semiconductor substrate according to any one of Appendixes 7 to 9, in which
in the step of removing the graphite substrate 19, the graphite substrate 19 is removed by means of combustion. The graphite substrate 19 can be removed by combustion in an air atmosphere or the like.

### (Appendix 11)

The method for manufacturing a semiconductor substrate according to Appendix 1, in which
in the step of attaching the graphite substrate 19 on the stress layer 14, the stress layer 14 and the graphite substrate 19 are attached with an adhesive layer using a carbon adhesive therebetween. The carbon adhesive can maintain bonding force thereof even at a high temperature due to the adhesive itself being carbonized.

### (Appendix 12)

The method for manufacturing a semiconductor substrate according to Appendix, 11 further including:
a step of removing an adhesive layer 15 by means of combustion. The adhesive layer 15 can be removed by means of combustion in an air atmosphere or the like together with the graphite substrate 19.

### (Appendix 13)

The method for manufacturing a semiconductor substrate according to Appendix 1, further including:
a step of removing a portion of the SiC polycrystalline growth layer 16 and a portion of the graphite substrate 19, that protrude to an outer periphery of a composite including the graphite substrate 19, the stress layer 14, and the SiC-epitaxial growth layer 13 by means of grinding, and exposing an outer periphery of the graphite substrate 19 in the step of forming the SiC polycrystalline growth layer 16 before the step of removing the graphite substrate 19. The removal of the graphite substrate 19 by means of combustion is enabled.

### (Appendix 14)

The method for manufacturing a semiconductor substrate according to Appendix 1, further including:
a step of cutting the graphite substrate 19 into two pieces at a plane parallel to a main plane of the graphite substrate 19 together with the SiC polycrystalline growth layer 16 protruding to an outer periphery of the graphite substrate 19, and exposing a cut surface of the graphite substrate 19 in the step of forming the SiC polycrystalline growth layer 16 before the step of removing the graphite substrate 19. This enables removal of the graphite substrate 19 by means of combustion.

### (Appendix 15)

The method for manufacturing a semiconductor substrate according to Appendix 1, further including:
a step of forming a highly doped layer 13a having an impurity concentration that is higher than an impurity concentration of the SiC-epitaxial growth layer 13 on the C surface of the SiC-epitaxial growth layer 13 in contact with the SiC polycrystalline growth layer 16. By means of the highly doped layer 13a, it is possible to suppress the spread of a depletion layer in the SiC-epitaxial growth layer 13 and easily form an ohmic contact with the SiC polycrystalline growth layer 16 formed on the C surface of the SiC-epitaxial growth layer 13.

### (Appendix 16)

The method for manufacturing a semiconductor substrate according to Appendix 15, in which
the step of forming the highly doped layer 13a includes an ion implantation step or an autodoping step of epitaxial growth. The highly doped layer 13a can be formed easily.

### (Appendix 17)

A SiC composite substrate 10 that is a semiconductor substrate, including:
a SiC single crystal substrate 11;
a graphene layer 12 disposed on a Si surface of the SiC single crystal substrate 11;
a SiC-epitaxial growth layer 13 disposed on the SiC single crystal substrate 11 with the graphene layer 12 therebetween; and
a stress layer 14 disposed on a Si surface of the SiC-epitaxial growth layer 13, in which
the stress layer 14 generates a stress that facilitates detachment between the graphene layer 12 and the SiC-epitaxial growth layer 13. This facilitates detachment between the graphene layer 12 and the SiC-epitaxial growth layer 13.

### (Appendix 18)

The semiconductor substrate according to Appendix 17, in which
the stress layer 14 generates a stress between the graphene layer 12 and the SiC-epitaxial growth layer 13 that approximates an adhesion energy between the graphene layer 12 and the SiC-epitaxial growth layer 13. This enables detachment between the graphene layer 12 and the SiC-epitaxial growth layer 13 at an interface thereof.

### (Appendix 19)

The semiconductor substrate according to Appendix 17 or 18, in which
the stress layer 14 includes a carbon film or a silicon nitride film. Since metal is not contained, it is possible to avoid metal contamination.

### (Appendix 20)

The semiconductor substrate according to Appendix 19, in which
the carbon film includes a polycrystalline diamond film or a diamond-like carbon film. The film can be formed relatively easily and can withstand high heat.

### (Appendix 21)

The semiconductor substrate according to Appendix 17, further including:
a graphite substrate 19 disposed on the stress layer 14. The stress layer 14 may be fixed to the graphite substrate 19.

### (Appendix 22)

The semiconductor substrate according to Appendix 21, in which
the graphite substrate 19 as a temporary substrate is made of graphite. The graphite substrate 19 as the temporary substrate can be removed by means of combustion.

### (Appendix 23)

The semiconductor substrate according to Appendix 22, in which
the stress layer 14 and the graphite substrate 19 are attached with an adhesive layer 15 using a carbon adhesive therebetween. Since the carbon adhesive has strong adhesion force, the graphene layer 12 and the SiC-epitaxial growth layer 13 can be easily detached.

### (Appendix 24)

The semiconductor substrate according to Appendix 22, in which
the graphite substrate 19 includes a glassy carbon film formed on a surface thereof. Since adhesion force between the glassy carbon film and a carbon adhesive of an adhesive layer 15 is strong, the graphene layer 12 and the SiC-epitaxial growth layer 13 can be easily detached.

### (Appendix 25)

The semiconductor substrate according to any one of Appendixes 22 to 24, in which
the graphite substrate 19 has an external size that is larger than an external size of the SiC single crystal substrate. When inserted into a wafer boat groove in a vertical batch CVD furnace and aligned, a strut mark on a wafer boat can be set outside a substrate effective area.

### (Appendix 26)

The semiconductor substrate according to Appendix 17, further including:
a SiC polycrystalline growth layer 16 disposed on a C surface of the SiC-epitaxial growth layer 13. The SiC polycrystalline growth layer 16 can be easily formed by means of CVD.

### (Appendix 27)

The semiconductor substrate according to Appendix 26, in which
the SiC-epitaxial growth layer 13 further includes a highly doped layer 13a having an impurity concentration which is higher than an impurity concentration of the SiC-epitaxial growth layer 13, that is formed on a surface of the SiC-epitaxial growth layer 13 in contact with the SiC polycrystalline growth layer 16. By means of the highly doped layer 13a, it is possible to suppress the spread of a depletion layer in the SiC-epitaxial growth layer 13 and easily form an ohmic contact with the SiC polycrystalline growth layer 16 formed on the C surface of the SiC-epitaxial growth layer 13.

### (Appendix 28)

The semiconductor substrate according to Appendix 17, in which
the graphene layer 12 has a single layer structure or a multi-layer stacked structure of graphene. Detachment in the graphene layer 12 is enabled.

### (Appendix 29)

A method for manufacturing a SiC composite substrate 10 which is a semiconductor substrate, the method including:
a step of forming a SiC-epitaxial growth layer 13 on a Si surface of a SiC single crystal substrate 11;
a step of attaching a graphite substrate 19 as a temporary substrate on a Si surface of the SiC-epitaxial growth layer 13;
a step of removing the SiC-epitaxial growth layer 13 from the SiC single crystal substrate 11;
a step of forming a first SiC polycrystalline growth layer 16 on a C surface of the SiC-epitaxial growth layer 13 to which the graphite substrate 19 is attached;
a step of forming a second graphene layer 17 as a graphene layer on the first SiC polycrystalline growth layer 16;
a step of forming a second SiC polycrystalline growth layer 18 on the second graphene layer 17; and
a step of removing the graphite substrate 19. This enables detachment between the second graphene layer 17 and the second SiC polycrystalline growth layer 18.

### (Appendix 30)

The method for manufacturing a semiconductor substrate according to Appendix 29, further including:
a step of forming a first graphene layer 12 as another graphene layer on the Si surface of the SiC single crystal substrate 11, in which
in the step of forming the SiC-epitaxial growth layer 13, the SiC-epitaxial growth layer 13 is formed on the Si surface of the SiC single crystal substrate 11 with the first graphene layer 12 therebetween. This enables detachment between the first graphene layer 12 and the SiC-epitaxial growth layer 13.

### (Appendix 31)

The method for manufacturing a semiconductor substrate according to Appendix 30, in which
in the step of removing the SiC-epitaxial growth layer 13 from the SiC single crystal substrate 11, the SiC-epitaxial growth layer 13 is detached from the first graphene layer 12. The first graphene layer can be detached because graphite sheets are bonded by means of van der Waals force.

### (Appendix 32)

The method for manufacturing a semiconductor substrate according to Appendix 31, further including:
a step of forming a stress layer 14 on the Si surface of the SiC-epitaxial growth layer 13, the stress layer 14 generating a stress for detaching the SiC-epitaxial growth layer 13 from the first graphene layer 12, in which
in the step of attaching the graphite substrate 19 on the Si surface of the SiC-epitaxial growth layer 13, the graphite substrate 19 is attached on the Si surface of the SiC-epitaxial growth layer 13 with the stress layer 14 therebetween. A stacked body including the SiC-epitaxial growth layer 13 and the SiC single crystal substrate 11 can be fixed by the graphite substrate 19.

### (Appendix 33)

The method for manufacturing a semiconductor substrate according to Appendix 29, further including:
a step of forming a hydrogen ion implantation layer 11c having a prescribed depth from the Si surface of the SiC single crystal substrate 11, in which
in the step of removing the SiC-epitaxial growth layer 13 from the SiC single crystal substrate 11, the hydrogen ion implantation layer 11c is embrittled, and the SiC-epitaxial growth layer 13 is detached together with a thinned SiC single crystal layer 11d separated from the SiC single crystal substrate 11 by separation of the hydrogen ion implantation layer 11c. The hydrogen ion implantation layer 11c of the SiC single crystal substrate 11 is embrittled to enable the separation.

### (Appendix 34)

The method for manufacturing a semiconductor substrate according to Appendix 33, further including:
a step of polishing a C surface of the thinned SiC single crystal layer 11d detached together with the SiC-epitaxial growth layer 13. It is possible to smooth an uneven structure formed by separation of the hydrogen ion implantation layer 11c.

### (Appendix 35)

The method for manufacturing a semiconductor substrate according to Appendix 29, in which
the graphite substrate 19 as the temporary substrate is made of graphite. The graphite substrate 19 as the temporary substrate can be removed by means of combustion.

### (Appendix 36)

The method for manufacturing a semiconductor substrate according to Appendix 35, in which
the graphite substrate 19 has an external size that is larger than an external size of the SiC single crystal substrate 11. When inserted into a wafer boat groove in a vertical batch CVD furnace and aligned, a strut mark on a wafer boat can be set outside a substrate effective area.

### (Appendix 37)

The method for manufacturing a semiconductor substrate according to Appendix 35, in which
the graphite substrate 19 includes a glassy carbon film formed on a surface thereof. Since adhesion force between the glassy carbon film and a carbon adhesive of an adhesive layer 15 is strong, the first graphene layer 12 and the SiC-epitaxial growth layer 13 can be reliably detached.

### (Appendix 38)

The method for manufacturing a semiconductor substrate according to any one of Appendixes 35 to 37, in which
in the step of removing the graphite substrate 19, the graphite substrate 19 is removed by means of combustion. The graphite substrate 19 can be removed by combustion in an air atmosphere or the like.

### (Appendix 39)

The method for manufacturing a semiconductor substrate according to Appendix 38, in which
in the step of attaching the graphite substrate 19 on the C surface of the SiC-epitaxial growth layer 13, the SiC-epitaxial growth layer 13 and the graphite substrate 19 are attached with the adhesive layer using the carbon adhesive therebetween. Since the carbon adhesive has strong adhesion force, the first graphene layer 12 and the SiC-epitaxial growth layer 13 can be reliably detached.

### (Appendix 40)

The method for manufacturing a semiconductor substrate according to Appendix 39, in which
in the step of removing the graphite substrate 19, the adhesive layer 15 is removed by means of combustion together with the graphite substrate 19. The adhesive layer 15 can be removed by means of combustion in an air atmosphere or the like together with the graphite substrate 19.

### (Appendix 41)

The method for manufacturing a semiconductor substrate according to Appendix 29, further including:
a step of forming a highly doped layer 13a having an impurity concentration that is higher than an impurity concentration of the SiC-epitaxial growth layer 13 on the C surface of the SiC-epitaxial growth layer 13 in contact with the first SiC polycrystalline growth layer 16. By means of the highly doped layer 13a, it is possible to suppress the spread of a depletion layer in the SiC-epitaxial growth layer 13 and easily form an ohmic contact with the first SiC polycrystalline growth layer 16 formed on the C surface of the SiC-epitaxial growth layer 13.

### (Appendix 42)

The method for manufacturing a semiconductor substrate according to Appendix 41, in which
the step of forming the highly doped layer 13a includes an ion implantation step or an autodoping step of epitaxial growth. The highly doped layer 13a can be reliably formed.

### (Appendix 43)

A method for manufacturing a semiconductor device including the method for manufacturing a semiconductor substrate according to Appendix 29, the method further including:
a step of forming at least a part of a structure constituting a semiconductor element, on the C surface of the SiC-epitaxial growth layer 13 of the SiC composite substrate 10. By detaching the second SiC polycrystalline growth layer 18, the SiC composite substrate 10 can be easily thinned.

### (Appendix 44)

The method for manufacturing a semiconductor device according to Appendix 43, in which
the semiconductor element includes at least one of a SiC Schottky barrier diode, a SiC-MOSFET, a SiC bipolar transistor, a SiC diode, a SiC thyristor, and a SiC insulated gate bipolar transistor. It is possible to provide various useful SiC-based semiconductor elements.

### (Appendix 45)

The method for manufacturing a semiconductor device according to Appendix 43, further including:
a step of detaching a second SiC polycrystalline growth layer 18 from a graphene layer in the SiC composite substrate 10 in which the structure constituting the semiconductor element is formed. Thinning of the SiC composite substrate 10 can be achieved by detaching the second SiC polycrystalline growth layer 18 without performing grinding.

### (Appendix 46)

The method for manufacturing a semiconductor device according to Appendix 45, in which
the step of detaching the second SiC polycrystalline growth layer 18 from a second graphene layer 17 further includes a step of heating a Si surface of the second SiC polycrystalline growth layer 18. The surface can be easily heated using a hot plate.

### (Appendix 47)

The method for manufacturing a semiconductor device according to Appendix 45, in which
the step of detaching the second SiC polycrystalline growth layer 18 from a second graphene layer 17 further includes a step of cooling a Si surface of the second SiC polycrystalline growth layer 18. The surface can be easily cooled using liquid nitrogen or the like.

### (Appendix 48)

The method for manufacturing a semiconductor device according to Appendix 45, in which
the step of detaching the second SiC polycrystalline growth layer 18 from a second graphene layer 17 further includes a step of scanning a Si surface of the second SiC polycrystalline growth layer 18 with an ultrasonic oscillator. By adjusting a focus of ultrasonic waves emitted by the ultrasonic oscillator, a position at which a crack occurs can be controlled.

### (Appendix 49)

The method for manufacturing a semiconductor device according to Appendix 45, in which
the step of detaching the second SiC polycrystalline growth layer 18 from a second graphene layer 17 further includes a step of pushing a cleavage blade 106 between the second graphene layer 17 and the second SiC polycrystalline growth layer 18 to generate cleavage. The generation of mechanical cleavage using the cleavage blade 106 can be reliably controlled.

### (Appendix 50)

A SiC composite substrate 10 which is a semiconductor substrate, including:
a SiC-epitaxial growth layer 13;
a first SiC polycrystalline growth layer 16 disposed on a Si surface of the SiC-epitaxial growth layer 13;
a second graphene layer 17 disposed on the first SiC polycrystalline growth layer 16; and
a second SiC polycrystalline growth layer 18 disposed on the second graphene layer 17. The SiC composite substrate 10 can be easily thinned by detaching the second SiC polycrystalline growth layer 18.

### (Appendix 51)

The SiC composite substrate 10 according to Appendix 50, in which
the second graphene layer 17 has a single layer structure or a multi-layer stacked structure of graphene. The second graphene layer 17 can be detached because graphite sheets are bonded by means of van der Waals force.

### (Appendix 52)

The SiC composite substrate 10 according to Appendix 50, in which
the SiC-epitaxial growth layer 13 further include a highly doped layer 13a having an impurity concentration which is higher than an impurity concentration of the SiC-epitaxial growth layer 13, that is formed on a C surface of the SiC-epitaxial growth layer 13. By means of the highly doped layer 13a, it is possible to suppress the spread of a depletion layer in the SiC-epitaxial growth layer 13 and easily form an ohmic contact with the first SiC polycrystalline growth layer 16 formed on the C surface of the SiC-epitaxial growth layer 13.

### (Appendix 53)

A semiconductor device having a structure constituting a semiconductor element, which is formed on a C surface of the SiC-epitaxial growth layer 13 of the SiC composite substrate 10 according to Appendix 50. Since the SiC composite substrate 10 can be easily thinned, the semiconductor element can be fabricate easily.

### (Appendix 54)

The SiC composite substrate 10 according to Appendix 50, in which
the semiconductor element includes at least one of a SiC Schottky barrier diode, a SiC-MOSFET, a SiC bipolar transistor, a SiC diode, a SiC thyristor, and a SiC insulated gate bipolar transistor. It is possible to provide various useful SiC-based semiconductor elements.

### INDUSTRIAL APPLICABILITY

The present disclosure can be applied to various semiconductor module technologies, such as IGBT modules, diode modules, and MOS modules (SiC, GaN, AlN, and gallium oxide), and the present disclosure can be applied to a wide range of application fields, such as power modules for inverter circuits that drive electric motors used as power sources for electric vehicles (including hybrid vehicles), electric trains, industrial robots, and the like, and power modules for inverter circuits that convert power generated by solar cells, wind power generators, and other power generators (especially private power generators) into power for commercial power sources.

What is claimed is:

1. A method for manufacturing a semiconductor substrate, comprising:
a step of forming a graphene layer on a Si surface of a SiC single crystal substrate;
a step of forming a SiC-epitaxial growth layer on the graphene layer;
a step of forming a stress layer on the SiC-epitaxial growth layer;
a step of attaching a temporary substrate on the stress layer;
a step of detaching the graphene layer and the SiC-epitaxial growth layer;
a step of forming a SiC polycrystalline growth layer on a C surface of the SiC-epitaxial growth layer from which the graphene layer is detached; and
a step of removing the temporary substrate, wherein the stress layer generates a stress that facilitates detachment between the graphene layer and the SiC-epitaxial growth layer.

2. The method for manufacturing a semiconductor substrate according to claim 1, wherein
the stress layer generates a stress between the graphene layer and the SiC-epitaxial growth layer that approximates an adhesion energy between the graphene layer and the SiC-epitaxial growth layer.

3. The method for manufacturing a semiconductor substrate according to claim 2, wherein
the stress layer generates a stress for detaching the graphene layer and the SiC-epitaxial growth layer, the stress depending on a stacked structure of the SiC single crystal substrate, the graphene layer, the SiC-epitaxial growth layer, the stress layer, and the temporary substrate.

4. The method for manufacturing a semiconductor substrate according to claim 1, wherein
the stress layer includes a carbon film or a silicon nitride film.

5. The method for manufacturing a semiconductor substrate according to claim 4, wherein
the carbon film includes a polycrystalline diamond film or a diamond-like carbon film.

6. The method for manufacturing a semiconductor substrate according to claim 1, further comprising:
a step of removing the stress layer by means of combustion or grinding.

7. The method for manufacturing a semiconductor substrate according to claim 1, wherein
the temporary substrate is made of graphite.

8. The method for manufacturing a semiconductor substrate according to claim 7, wherein
the temporary substrate has an external size that is larger than an external size of the SiC single crystal substrate.

9. The method for manufacturing a semiconductor substrate according to claim 7, wherein
the temporary substrate includes a glassy carbon film formed on a surface thereof.

10. The method for manufacturing a semiconductor substrate according to claim 7, wherein
in the step of removing the temporary substrate, the temporary substrate is removed by means of combustion.

11. The method for manufacturing a semiconductor substrate according to claim 1, wherein
in the step of attaching the temporary substrate on the stress layer, the stress layer and the temporary substrate are attached with an adhesive layer using a carbon adhesive therebetween.

12. The method for manufacturing a semiconductor substrate according to claim 11, further comprising:
a step of removing the adhesive layer by means of combustion.

13. The method for manufacturing a semiconductor substrate according to claim 1, further comprising:
a step of removing a portion of the SiC polycrystalline growth layer and a portion of the temporary substrate, that protrude to an outer periphery of a composite including the temporary substrate, the stress layer, and the SiC-epitaxial growth layer by means of grinding, and exposing an outer periphery of the temporary substrate in the step of forming the SiC polycrystalline growth layer before the step of removing the temporary substrate.

14. The method for manufacturing a semiconductor substrate according to claim 1, further comprising:
a step of cutting the temporary substrate into two pieces at a plane parallel to a main plane of the temporary substrate together with the SiC polycrystalline growth layer protruding to an outer periphery of the temporary substrate, and exposing a cut surface of the temporary substrate in the step of forming the SiC polycrystalline growth layer before the step of removing the temporary substrate.

15. The method for manufacturing a semiconductor substrate according to claim 1, further comprising:
a step of forming a highly doped layer having an impurity concentration that is higher than an impurity concentration of the SiC-epitaxial growth layer on the C surface of the SiC-epitaxial growth layer in contact with the SiC polycrystalline growth layer.

16. The method for manufacturing a semiconductor substrate according to claim 15, wherein
the step of forming the highly doped layer includes an ion implantation step or an autodoping step of epitaxial growth.

17. A semiconductor substrate comprising:
a SiC single crystal substrate;
a graphene layer disposed on a Si surface of the SiC single crystal substrate;
a SiC-epitaxial growth layer disposed on the SiC single crystal substrate with the graphene layer therebetween; and
a stress layer disposed on a Si surface of the SiC-epitaxial growth layer, wherein
the stress layer generates a stress that facilitates detachment between the graphene layer and the SiC-epitaxial growth layer.

18. A method for manufacturing a semiconductor substrate, comprising:
a step of forming a SiC-epitaxial growth layer on a Si surface of a SiC single crystal substrate;
a step of attaching a temporary substrate on a Si surface of the SiC-epitaxial growth layer;
a step of removing the SiC-epitaxial growth layer from the SiC single crystal substrate;
a step of forming a first SiC polycrystalline growth layer on a C surface of the SiC-epitaxial growth layer to which the temporary substrate is attached;
a step of forming a graphene layer on the first SiC polycrystalline growth layer;
a step of forming a second SiC polycrystalline growth layer on the graphene layer; and
a step of removing the temporary substrate.

19. The method for manufacturing a semiconductor substrate according to claim 18, further comprising:
a step of forming another graphene layer on the Si surface of the SiC single crystal substrate, wherein
in the step of forming the SiC-epitaxial growth layer, the SiC-epitaxial growth layer is formed on the Si surface of the SiC single crystal substrate with the other graphene layer therebetween.

20. The method for manufacturing a semiconductor substrate according to claim 19, wherein
in the step of removing the SiC-epitaxial growth layer from the SiC single crystal substrate, the SiC-epitaxial growth layer is detached from the other graphene layer.

21. The method for manufacturing a semiconductor substrate according to claim 20, further comprising:
a step of forming a stress layer on the Si surface of the SiC-epitaxial growth layer, the stress layer generating a stress for detaching the SiC-epitaxial growth layer from the other graphene layer, wherein
in the step of attaching the temporary substrate on the Si surface of the SiC-epitaxial growth layer, the temporary substrate is attached on the Si surface of the SiC-epitaxial growth layer with the stress layer therebetween.

22. The method for manufacturing a semiconductor substrate according to claim 18, further comprising:
a step of forming a hydrogen ion implantation layer having a prescribed depth from the Si surface of the SiC single crystal substrate, wherein
in the step of removing the SiC-epitaxial growth layer from the SiC single crystal substrate, the hydrogen ion implantation layer is embrittled, and the SiC-epitaxial growth layer is detached together with a thinned SiC single crystal layer separated from the SiC single crystal substrate by separation of the hydrogen ion implantation layer.

23. The method for manufacturing a semiconductor substrate according to claim 22, further comprising:
a step of polishing a C surface of the thinned SiC single crystal layer detached together with the SiC-epitaxial growth layer.

24. The method for manufacturing a semiconductor substrate according to claim 18, wherein
the temporary substrate is made of graphite.

25. The method for manufacturing a semiconductor substrate according to claim 24, wherein
the temporary substrate has an external size that is larger than an external size of the SiC single crystal substrate.

26. The method for manufacturing a semiconductor substrate according to claim 24, wherein
the temporary substrate includes a glassy carbon film formed on a surface thereof.

27. The method for manufacturing a semiconductor substrate according to claim 24, wherein
in the step of removing the temporary substrate, the temporary substrate is removed by means of combustion.

28. The method for manufacturing a semiconductor substrate according to claim 27, wherein
in the step of attaching the temporary substrate on the C surface of the SiC-epitaxial growth layer, the SiC-epitaxial growth layer and the temporary substrate are attached with an adhesive layer using a carbon adhesive therebetween.

29. The method for manufacturing a semiconductor substrate according to claim 28, wherein
in the step of removing the temporary substrate, the adhesive layer is removed by means of combustion together with the temporary substrate.

30. The method for manufacturing a semiconductor substrate according to claim 18, further comprising:
a step of forming a highly doped layer having an impurity concentration that is higher than an impurity concentration of the SiC-epitaxial growth layer on the C surface of the SiC-epitaxial growth layer in contact with the first SiC polycrystalline growth layer.

31. The method for manufacturing a semiconductor substrate according to claim 30, wherein
the step of forming the highly doped layer includes an ion implantation step or an autodoping step of epitaxial growth.

32. A method for manufacturing a semiconductor device including the method for manufacturing a semiconductor substrate according to claim 18, the method further comprising:
a step of forming at least a part of a structure constituting a semiconductor element, on the C surface of the SiC-epitaxial growth layer of the semiconductor substrate.

33. The method for manufacturing a semiconductor device according to claim 32, wherein
the semiconductor element includes at least one of a SiC Schottky barrier diode, a SiC-MOSFET, a SiC bipolar transistor, a SiC diode, a SiC thyristor, and a SiC insulated gate bipolar transistor.

34. The method for manufacturing a semiconductor device according to claim 32, further comprising:
a step of detaching the second SiC polycrystalline growth layer from the graphene layer in the semiconductor substrate in which the structure constituting the semiconductor element is formed.

35. The method for manufacturing a semiconductor device according to claim 34, wherein
the step of detaching the second SiC polycrystalline growth layer from the graphene layer further includes a step of heating a Si surface of the second SiC polycrystalline growth layer.

36. The method for manufacturing a semiconductor device according to claim 34, wherein
the step of detaching the second SiC polycrystalline growth layer from the graphene layer further includes a step of cooling a Si surface of the second SiC polycrystalline growth layer.

37. The method for manufacturing a semiconductor device according to claim 34, wherein
the step of detaching the second SiC polycrystalline growth layer from the graphene layer further includes a step of scanning a Si surface of the second SiC polycrystalline growth layer with an ultrasonic oscillator.

38. The method for manufacturing a semiconductor device according to claim 34, wherein
the step of detaching the second SiC polycrystalline growth layer from the graphene layer further includes a step of pushing a cleavage blade between the graphene layer and the second SiC polycrystalline growth layer to generate cleavage.

39. A semiconductor substrate comprising:
a SiC-epitaxial growth layer;
a first SiC polycrystalline growth layer disposed on a Si surface of the SiC-epitaxial growth layer;
a graphene layer disposed on the first SiC polycrystalline growth layer; and
a second SiC polycrystalline growth layer disposed on the graphene layer.

40. The semiconductor substrate according to claim 39, wherein
the graphene layer has a single layer structure or a multi-layer stacked structure of graphene.

41. The semiconductor substrate according to claim 39, wherein
the SiC-epitaxial growth layer further includes a highly doped layer having an impurity concentration that is higher than an impurity concentration of the SiC-epitaxial growth layer, that is formed on a C surface of the SiC-epitaxial growth layer.

42. A semiconductor device having a structure constituting a semiconductor element, which is formed on a C surface of the SiC-epitaxial growth layer of the semiconductor substrate according to claim 39.

43. The semiconductor device according to claim 42, wherein
the semiconductor element includes at least one of a SiC Schottky barrier diode, a SiC-MOSFET, a SiC bipolar transistor, a SiC diode, a SiC thyristor, and a SiC insulated gate bipolar transistor.
